(19) United States
(12) Patent Application Publication
(10) Pub. No.: US 2026/0089919 A1
(43) Pub. Date: Mar. 26, 2026

(54) SEMICONDUCTOR DEVICE, SEMICONDUCTOR STORAGE DEVICE, AND METHOD FOR MANUFACTURING THE SAME

(71) Applicant: Kioxia Corporation, Tokyo (JP)

(72) Inventors: Takuya KIKUCHI, Yokkaichi Mie (JP); Kazuhiro MATSUO, Kuwana Mie (JP); Yusuke KASAHARA, Yokkaichi Mie (JP)

(21) Appl. No.: 19/076,925

(22) Filed: Mar. 11, 2025

(30) Foreign Application Priority Data
Sep. 20, 2024 (JP) 2024-164437

(51) Int. Cl. H10B 12/00

(52) U.S. Cl. CPC H10B 12/33; H10B 12/05

(57) ABSTRACT

A semiconductor device includes an upper electrode, a lower electrode, an oxide semiconductor including a first portion connected to the upper electrode, a connection portion, a second portion that is connected to a lower end portion of the first portion through the connection portion, has a diameter larger than that of the lower end portion of the first portion, and connected to the lower electrode, a gate insulating film surrounding a side surface of the first portion and has an outer diameter smaller than that of the second portion, a first insulating layer through which the first portion penetrates, a gate electrode which is provided below the first insulating layer and faces the first portion via the gate insulating film, the first portion penetrating through the gate electrode, and a second insulating layer provided below the gate electrode, wherein the connection portion is surrounded by the second insulating layer.

### CROSS-REFERENCE TO RELATED APPLICATION(S)

This application is based upon and claims the benefit of priority from Japanese Patent Application No. 2024-164437, filed Sep. 20, 2024, the entire contents of which are incorporated herein by reference.

### FIELD

Embodiments described herein relate generally to a semiconductor device, a semiconductor storage device, and a method for manufacturing the same.

### BACKGROUND

In some type of semiconductor devices, an oxide semiconductor is surrounded by an insulating film and an electrode is provided to face the oxide semiconductor via the insulating film.

### BRIEF DESCRIPTION OF THE DRAWINGS

FIG. 1 is a circuit diagram showing an example of a circuit configuration of a memory cell array according to a first embodiment.

FIG. 2 is a schematic sectional view showing an example of a structure of a semiconductor storage device according to the first embodiment.

FIGS. 3-8 are schematic diagrams showing a manufacturing process for a semiconductor device according to a first example of the first embodiment.

FIGS. 9-10 are schematic diagrams showing a manufacturing process for a semiconductor device according to a second example of the first embodiment.

FIGS. 11-12 are schematic diagrams showing a manufacturing process for a semiconductor device according to a third example of the first embodiment.

FIGS. 13-14 are schematic diagrams showing a manufacturing process for a semiconductor device according to a fourth example of the first embodiment.

FIGS. 15-20 are schematic diagrams showing a manufacturing process for a semiconductor device according to a fifth example of the first embodiment.

FIGS. 21-22 are schematic diagrams showing a manufacturing process for a semiconductor device according to a sixth example of the first embodiment.

FIGS. 23-24 are schematic diagrams showing a manufacturing process for a semiconductor device according to a seventh example of the first embodiment.

FIGS. 25-27 are schematic diagrams showing a manufacturing process for a semiconductor device according to an eighth example of the first embodiment.

FIGS. 28-30 are schematic diagrams showing a manufacturing process for a semiconductor device according to a ninth example of the first embodiment.

FIGS. 31-36 are schematic diagrams showing a manufacturing process for a semiconductor device according to a tenth example of the first embodiment.

FIGS. 37-39 are schematic diagrams showing a manufacturing process for a semiconductor device according to an eleventh example of the first embodiment.

FIGS. 40-42 are schematic diagrams showing a manufacturing process for a semiconductor device according to a twelfth example of the first embodiment.

FIGS. 43-46 are schematic diagrams showing a manufacturing process for a semiconductor device according to a thirteenth example of the first embodiment.

FIGS. 47-48 are schematic diagrams showing a manufacturing process for a semiconductor device according to a comparison example.

FIGS. 49-55 are schematic diagrams showing a manufacturing process for a semiconductor device according to a first example of a second embodiment.

FIGS. 56-57 diagrams showing examples of a process for causing a self-assembled monolayer to be selectively adsorbed onto a lower electrode when a sacrificial gate insulating film and the lower electrode are exposed.

FIG. 58 is a diagram showing an effect of an extended insulating film.

FIGS. 59-66 are schematic diagrams showing a manufacturing process for a semiconductor device according to a second example of the second embodiment.

FIG. 67 is a diagram showing an example of a process for causing a self-assembled monolayer to be selectively adsorbed onto a stopper film when a sacrificial gate insulating film and the stopper film are exposed.

FIG. 68 is a schematic diagram showing a manufacturing process for a semiconductor device according to a third example of the second embodiment.

FIGS. 69-75 are schematic diagrams showing the manufacturing process for the semiconductor device according to the third example of the second embodiment.

FIGS. 76-79 are schematic diagram showings a manufacturing process for a semiconductor device according to a fourth example of the second embodiment.

FIGS. 80-90 are schematic diagrams showing a manufacturing process for a semiconductor device according to a fifth example of the second embodiment.

FIG. 91 is a diagram showing an example of a process for selectively removing the self-assembled monolayer adsorbed onto the sacrificial gate insulating film when the self-assembled monolayer is adsorbed onto the sacrificial gate insulating film and the stopper film.

FIG. 92 is a diagram showing an example of a process for causing a self-assembled monolayer to be selectively adsorbed onto a gate insulating film when the gate insulating film and a stopper film are exposed.

FIG. 93 is a sectional view taken along a cutting-plane line XCIII-XCIII shown in FIG. 75.

FIG. 94 is a diagram showing a modification of the cross section shown in FIG. 93.

### DETAILED DESCRIPTION

When an insulating film is damaged during a manufacturing process of a semiconductor device, the breakdown voltage of the insulating film may decrease.

Embodiments provide a semiconductor device, a semiconductor storage device, and a method for manufacturing the same, that are capable of preventing the decrease in breakdown voltage of the insulating film.

In general, according to one embodiment, a semiconductor device comprises: an upper electrode; a lower electrode; an oxide semiconductor including a first portion connected to the upper electrode, a connection portion, and a second portion that is connected to a lower end portion of the first portion through the connection portion, has a diameter larger than a diameter of the lower end portion of the first portion, and is connected to the lower electrode; a gate insulating film surrounding a side surface of the first portion and has an outer diameter smaller than the diameter of the second portion; a first insulating layer through which the first portion penetrates; a gate electrode that is provided below the first insulating layer and faces the first portion via the gate insulating film, the first portion penetrating through the gate electrode; and a second insulating layer that is provided below the gate electrode, wherein the connection portion is surrounded by the second insulating layer.

According to another embodiment, a semiconductor device comprises: an upper electrode; an oxide semiconductor that has an upper end connected to the upper electrode and a lower end and extends in an up-down direction; a gate insulating film provided on a side surface of the oxide semiconductor; a gate electrode facing the side surface of the oxide semiconductor via the gate insulating film; and a first layer that is provided below the gate electrode and connected to the gate insulating film, wherein the gate insulating film includes an extended insulating portion extending downward in the first layer.

According to another embodiment, a semiconductor storage device comprises: the semiconductor device; and a capacitor that is electrically connected to the upper electrode through the oxide semiconductor, wherein the capacitor includes a first capacitor electrode, a second capacitor electrode, and a dielectric film provided between the first capacitor electrode and the second capacitor electrode.

According to another embodiment, a method for manufacturing a semiconductor device comprises: forming a hole portion that penetrates through a first insulating layer, a gate electrode provided below the first insulating layer, and a second insulating layer provided below the gate electrode to expose a first layer provided below the second insulating layer; forming a gate insulating film covering the hole portion; forming a protection film covering the gate insulating film; removing a part of the protection film covering the first layer; removing a part of the gate insulating film covering the first layer; removing the protection film; and forming a semiconductor inside the hole portion.

According to another embodiment, a method for manufacturing a semiconductor device comprises: forming a hole portion that penetrates through a first insulating layer, a gate electrode provided below the first insulating layer, and a second insulating layer provided below the gate electrode to expose a first layer provided below the second insulating layer; forming a sacrificial film covering the hole portion; removing a part of the sacrificial film covering the first layer to expose an upper surface of the first layer; forming a monolayer on the exposed upper surface of the first layer, the monolayer not covering a surface of an inner surface of the hole portion; removing the sacrificial film; forming a gate insulating film on the surface of the inner surface of the hole portion; removing the monolayer; and forming a semiconductor inside the hole portion.

According to another embodiment, a method for manufacturing a semiconductor device comprises: forming a hole portion that penetrates through a first insulating layer, a gate electrode provided below the first insulating layer, and a second insulating layer provided below the gate electrode to expose a first layer provided below the second insulating layer; forming a gate insulating film covering the hole portion; forming a sacrificial film covering the gate insulating film below the hole portion; forming a monolayer covering a part of the gate insulating film that is left uncovered by the sacrificial film in the hole portion; removing the sacrificial film to expose a part of the gate insulating film that has been covered by the sacrificial film; removing a part of the gate insulating film covering the first layer in the hole portion to expose the first layer; removing the monolayer; and forming a semiconductor inside the hole portion.

Embodiments of the present disclosure will be hereinafter described with reference to the accompanying drawings. In order to facilitate understanding of the description, the same components in the respective drawings are denoted by the same reference symbols as much as possible, and duplicated descriptions will be omitted.

### First Embodiment

A configuration of a semiconductor storage device according to a first embodiment will be described. In each drawing, an X-axis, a Y-axis, and a Z-axis may be shown. The X-axis, the Y-axis, and the Z-axis define a right-handed three-dimensional Cartesian coordinate system. Hereinafter, a direction of an arrow of the X-axis may be referred to as an X-axis + direction, and a direction opposite to the direction of the arrow may be referred to as an X-axis − direction, and the same applies to the other axes. Note that a Z-axis + direction and a Z-axis − direction may be referred to as “up” and “down”, respectively. Furthermore, planes perpendicular to the X-axis, Y-axis, or Z-axis may be referred to as a YZ-plane, a ZX-plane, or an XY-plane, respectively. Furthermore, the Z-axis direction may be referred to as an “up-down direction”. “Up”, “down”, and “up-down direction” are terms that indicate a relative positional relationship within the drawing, and they are not terms that define orientations based on a vertical direction.

Furthermore, unless description is made specifically, the dimensions, etc., of the components shown in each drawing may be shown differently from the actual dimensions in order to facilitate understanding of the description.

In the present specification, “connection” includes not only physical connection, but also electrical connection, and unless description is made specifically, it includes not only direct connection, but also indirect connection.

In the present specification, “formed above an object” includes not only “formed above an object in contact with the object”, but also “formed above an object via another object” unless description is made specifically. The same applies to “formed below an object”, etc.

A semiconductor storage device 101 according to the first embodiment is an oxide semiconductor-random access memory (OS-RAM), and includes a memory cell array.

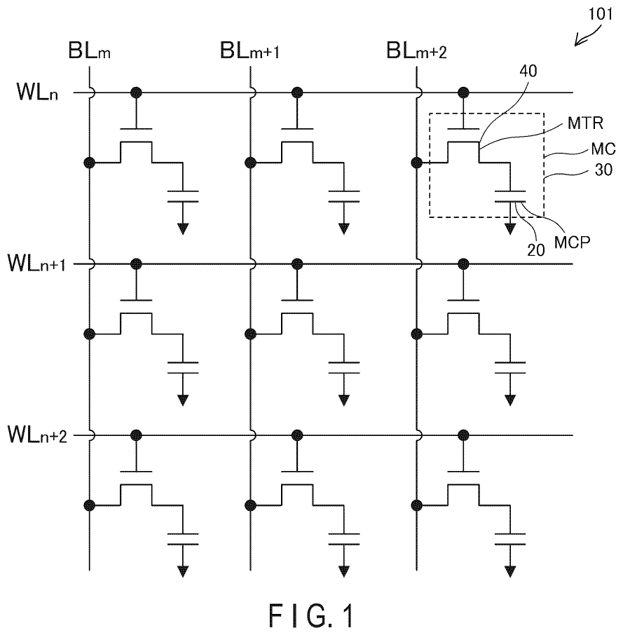

As shown in FIG. 1, the memory cell array includes a plurality of memory cells MC, a plurality of word-lines WL, and a plurality of bit-lines BL.

In FIG. 1, word-lines WLₙ, WLₙ₊₁, and WLₙ₊₂ are shown as examples of the plurality of word-lines WL (where n represents a positive integer). Furthermore, in FIG. 1, bit-lines BLₘ, BLₘ₊₁, and BLₘ₊₂ are shown as examples of the bit-lines BL (where m represents a positive integer). Note that the number of the plurality of memory cells MC is not limited to the number shown in FIG. 1.

The plurality of memory cells MC is arranged, for example, in a matrix form to form a memory cell array. The memory cell MC includes a memory transistor MTR which is a field effect transistor (FET), and a memory capacitor MCP.

A series of memory cells MC arranged along a line direction are connected to a word-line WL (for example, word-line WLₙ) corresponding to a line to which the memory cells MC belong (for example, n-th line). A series of memory cells MC arranged along a column direction are connected to a bit-line BL (for example, bit-line BLₘ₊₂) corresponding to a column to which the memory cells MC belong (for example, (m+2)-th column).

In more detail, the gate of the memory transistor MTR included in the memory cell MC is connected to the word-line WL corresponding to the line to which the memory cell MC belongs. One of the source and the drain of the memory transistor MTR is connected to the bit-line BL corresponding to the column to which the memory cell MC belongs.

One electrode of the memory capacitor MCP included in the memory cell MC is connected to the other of the source or the drain of the memory transistor MTR included in the memory cell MC. The other electrode of the memory cell MC is connected to a power supply line (not shown) for supplying a specific potential.

The memory cell MC is configured to be capable of storing data by accumulating charges in the memory capacitor MCP with current flowing through the corresponding bit-line BL due to switching of the memory transistor MTR based on the potential of the corresponding word-line WL.

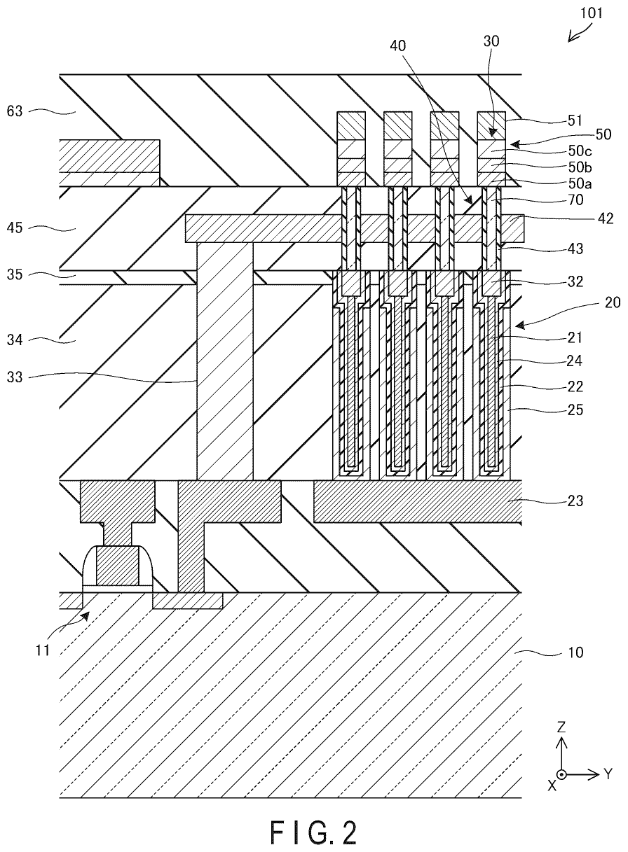

As shown in FIG. 2, the semiconductor storage device 101 includes a semiconductor substrate 10, a circuit 11 (an example of a “semiconductor circuit”), a capacitor 20, a semiconductor device 30, a conductor 33, and insulating layers 34, 35, and 63.

The capacitor 20 includes a conductor 21, an insulating film 22 (an example of a “dielectric film”), a conductor 23, a capacitor electrode 24 (an example of a “first capacitor electrode”), and a capacitor electrode 25 (an example of a “second capacitor electrode”).

The semiconductor device 30 includes a field effect transistor 40 (an example of a “semiconductor element”), an upper electrode 50 provided above the field effect transistor 40, and a lower electrode 32 (an example of a “first layer”) provided below the field effect transistor 40.

The field effect transistor 40 includes an oxide semiconductor layer 70 (an example of an “oxide semiconductor”), a gate insulating film 43, a conductive layer 42 (an example of a “gate electrode”), and an insulating layer 45. The field effect transistor 40 corresponds to the memory transistor MTR of the memory cell MC (see FIG. 1).

The oxide semiconductor layer 70 is formed in the insulating layer 45, and has an upper end 70a and a lower end 70b. The oxide semiconductor layer 70 is a columnar body extending in the up-down direction. The oxide semiconductor layer 70 forms a channel of the field effect transistor 40. The oxide semiconductor layer 70 has an amorphous structure.

The oxide semiconductor layer 70 is a semiconductor in which oxygen deficiencies serve as donors. The oxide semiconductor layer 70 contains at least one of indium (In), gallium (Ga), zinc (Zn), tin (Sn), aluminum (Al), iridium (Ir), ruthenium (Ru) and titanium (Ti), and oxygen.

In the present embodiment, the oxide semiconductor layer 70 contains indium, zinc, and gallium as metal elements. In particular, the oxide semiconductor layer 70 is an oxide of indium, gallium, and zinc, that is, IGZO (InGaZnO). The oxide semiconductor layer 70 may be another type of oxide semiconductor.

The conductive layer 42 faces the oxide semiconductor layer 70 via the gate insulating film 43. In particular, the conductive layer 42 functions as a gate electrode of the field effect transistor 40, and surrounds the oxide semiconductor layer 70 between the upper end 70a and the lower end 70b of the oxide semiconductor layer 70 via the gate insulating film 43. The conductive layer 42 contains, for example, tungsten (W).

The conductive layer 42 includes a plurality of electrodes that extend approximately in parallel to the Y-axis and are repeatedly arranged in the X-axis direction. These electrodes correspond to the word-lines WL (see FIG. 1).

The gate insulating film 43 contains, for example, silicon and oxygen. Specifically, the gate insulating film 43 contains silicon oxide. The gate insulating film 43 may be contain another material, for example, silicon nitride, or may be formed of two layers of a silicon oxide film and a silicon nitride film. The gate insulating film 43 is formed so as to cover the entire side surface of the oxide semiconductor layer 70.

The upper electrode 50 is formed in the Z-axis + direction with respect to the oxide semiconductor layer 70, and is connected to the upper end 70a of the oxide semiconductor layer 70. The upper electrode 50 contains a metal oxide layer 50a, a barrier metal layer 50b, and a metal film 50c.

The metal film 50c contains tungsten. The metal oxide layer 50a is formed between the metal film 50c and the upper end 70a of the oxide semiconductor layer 70, and contains a metal oxide. The metal oxide contains, for example, indium and tin as metal elements. In the present embodiment, the metal oxide layer 50a contains indium-tin-oxide (ITO).

The barrier metal layer 50b contains titanium and nitrogen, and is formed between the metal oxide layer 50a and the metal film 50c. In the present embodiment, the barrier metal layer 50b contains, for example, titanium nitride (TiN).

The lower electrode 32 is connected to the lower end 70b of the oxide semiconductor layer 70. The lower electrode 32 includes a metal oxide. Specifically, the lower electrode 32 includes, for example, indium and tin as metal elements. In the present embodiment, the metal oxide layer 50a is formed of indium-tin-oxide (ITO).

The metal oxide layer 50a and the lower electrode 32 are not limited to ITO, and may be configured to include at least one element of indium, tin, zinc, cadmium, gold, silver, platinum, lead, copper, nickel, tungsten, and iron.

The circuit 11 includes peripheral circuits such as a decoder for selecting a specific memory cell MC from among the plurality of memory cells MC, i.e., the capacitors 20 and the field effect transistors 40, of the semiconductor storage device 101, a sense amplifier connected to the bit-lines BL, and a register including an SRAM. The circuit 11 may include a CMOS circuit having field effect transistors, such as a P-channel field effect transistor (Pch-FET) and an N-channel field effect transistor (Nch-FET) which are formed by a CMOS process.

The field effect transistor of the circuit 11 can be formed using a semiconductor substrate 10 such as a single crystal silicon substrate. The Pch-FET and Nch-FET are so-called horizontal field effect transistors that have a channel region, a source region, and a drain region in the semiconductor substrate 10, and have a channel for causing carriers to flow in the X-axis direction or the Y-axis direction approximately parallel to the surface of the semiconductor substrate 10 in a region close to the surface of the semiconductor substrate 10. The semiconductor substrate 10 may have a P-type or N-type conductivity. For convenience, FIG. 2 illustrates an example of a field effect transistor of the circuit 11.

The capacitor 20 is a memory capacitor MCP included in the memory cell MC (see FIG. 1). Although four capacitors 20 are illustrated in FIG. 2, the number of capacitors 20 is not limited to four.

In the present embodiment, the capacitor 20 is provided above the semiconductor substrate 10. The capacitor electrode 24 of the capacitor 20 is connected to the conductor 21 and the lower electrode 32. The capacitor electrode 25 faces the capacitor electrode 24. The insulating film 22 is provided between the capacitor electrode 24 and the capacitor electrode 25.

The capacitor 20 is a three-dimensional capacitor such as a pillar-type capacitor. Note that other capacitors each having a configuration capable of storing electric charges may be used as the capacitor of the present embodiment.

The conductor 21 is shaped so as to abut against the lower end face of the lower electrode 32 and extend downward from the end portion. The capacitor electrode 24 is formed to cover the lower electrode 32 and the conductor 21. The insulating film 22 is formed to cover the capacitor electrode 24. The capacitor electrode 25 has a lower end that surrounds a lower part of the insulating film 22 and abuts against the upper end face of the conductor 23.

The conductor 21 may include a material such as amorphous silicon. The insulating film 22 may include a material such as hafnium oxide. The conductor 23 and the capacitor electrodes 24 and 25 may contain a material such as tungsten (W) and titanium nitride (TiN).

The conductor 33 includes a wiring that electrically connects the circuit 11 and the semiconductor device 30. The conductor 33 may include a via wiring, and has a via wiring that extends in the Z-axis direction as shown in FIG. 2, for example, and connects the word-line WL and the circuit 11 provided on the semiconductor substrate 10. The conductor 33 includes, for example, copper.

The insulating layer 34 is provided between the plurality of capacitors 20. The insulating layer 34 includes, for example, a silicon oxide film containing silicon and oxygen.

The insulating layer 35 is provided above the insulating layer 34. The insulating layer 35 is, for example, a silicon nitride film containing silicon and nitrogen.

The semiconductor device 30 is provided above the capacitor 20. The field effect transistor 40 in the semiconductor device 30 corresponds to the memory transistor MTR of the memory cell MC (see FIG. 1).

In the semiconductor device 30, the field effect transistor 40 is provided above the lower electrode 32. In detail, the oxide semiconductor layer 70 of the field effect transistor 40 is located in a direction away from the semiconductor substrate 10, i.e., above the lower electrode 32.

The upper electrode 50 is located in a direction away from the semiconductor substrate 10, i.e., above the oxide semiconductor layer 70. With this configuration, the field effect transistor 40 is a so-called vertical transistor having a channel extending in the Z-axis direction (up-down direction) that is approximately perpendicular to the surface of the semiconductor substrate 10.

### [Method for Manufacturing Semiconductor Device]

A first example of a method for manufacturing the semiconductor device 30 according to the first embodiment (hereinafter, may be referred to as a first example of the first embodiment) will be hereinafter described.

### (First Example of First Embodiment)

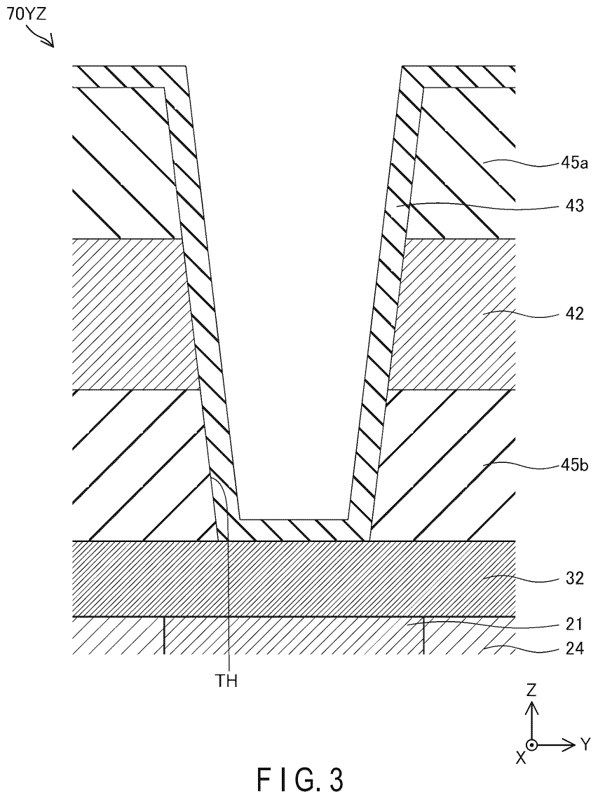

FIG. 3 to FIG. 8 are sectional views of a semiconductor device 30 according to the first example of the first embodiment. The sectional views are views of a cross-section 70YZ that is parallel to the YZ plane and included in the transistor hole TH.

First, as shown in FIG. 3, the insulating layer 45 includes insulating films 45a (an example of a “first insulating layer”) and 45b (an example of a “second insulating layer”). The insulating films 45a and 45b and the conductive layer 42 are formed on the semiconductor substrate 10. The conductive layer 42 is provided below the insulating film 45a. The insulating film 45b is provided below the conductive layer 42.

By etching the insulating films 45a and 45b and the conductive layer 42, a transistor hole TH (an example of a “hole portion”) is formed so as to penetrate through the insulating films 45a and 45b and the conductive layer 42 in the up-down direction and expose the lower electrode 32. In this example, the upper surface of the lower electrode 32 serves as a bottom portion of the transistor hole TH. Then, a gate insulating film 43 is formed to cover the transistor hole TH. In detail, the gate insulating film 43 is formed by, for example, atomic layer deposition (hereinafter, may be referred to as ALD) so as to cover the upper surface of the insulating film 45a and the inside of the transistor hole TH.

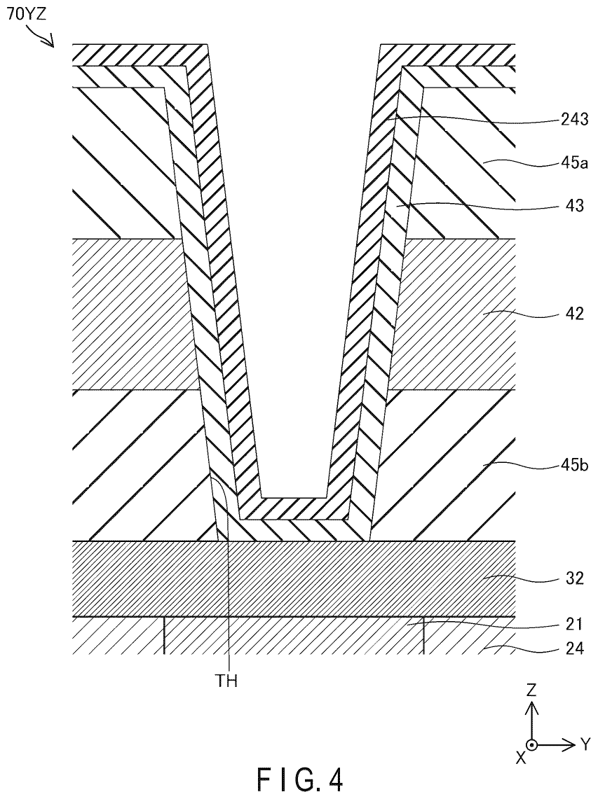

Next, as shown in FIG. 4, gate protection film forming processing is performed. In this example, a gate protection film 243 that covers the gate insulating film 43 is formed. Specifically, the gate protection film 243 is formed by ALD so as to cover the upper surface of the gate insulating film 43. In this example, the gate protection film 243 includes silicon nitride (SIN). The gate protection film 243 may include titanium oxide (TiO), titanium nitride (TiN), aluminum oxide (Al₂O₃), gallium oxide (GaO), or zinc oxide (ZnO).

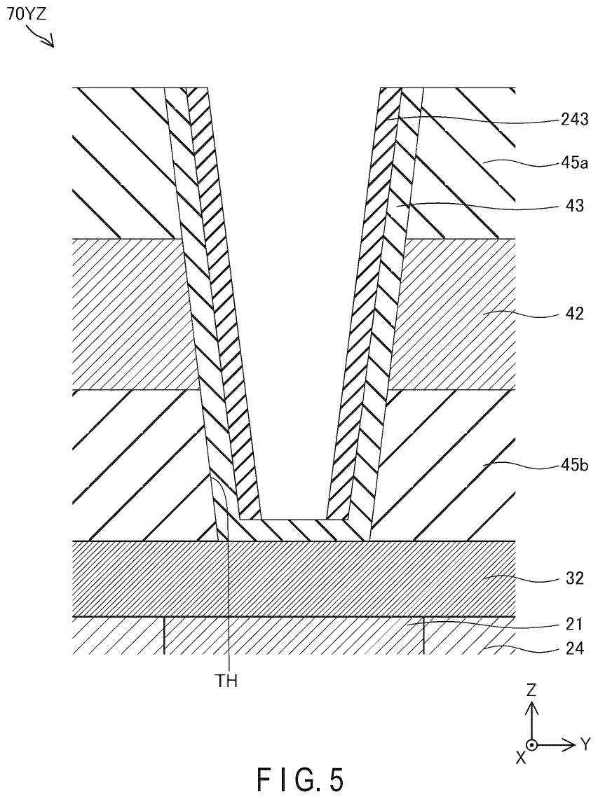

Next, as shown in FIG. 5, gate protection film etch-back processing is performed. In this example, a part of the gate protection film 243 that covers the lower electrode 32 is removed by etching using gas ion collisions. In more detail, a part of the gate insulating film 43 and a part of the gate protection film 243 are removed by reactive ion etching (hereinafter, may be referred to as RIE). As a result, the upper surface of the insulating film 45a is exposed. Furthermore, a part of the gate protection film 243 covering the lower electrode 32 is removed inside the transistor hole TH where the etching rate is reduced, while a part of the gate protection film 243 covering the lower electrode 32 remains, and the upper surface of the gate insulating film 43 is exposed. Note that the gate protection film 243 covering the side surface of the transistor hole TH may be partially removed or damaged by the RIE.

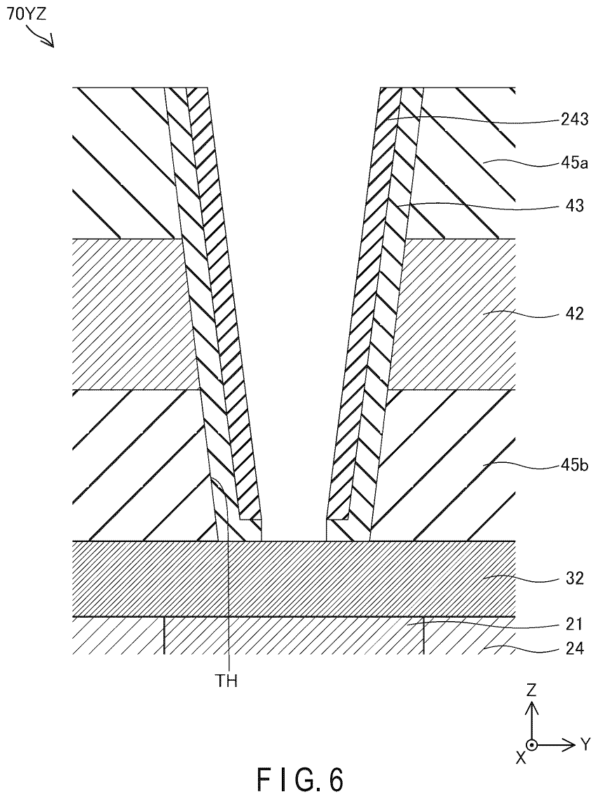

Next, as shown in FIG. 6, bottom punching processing is performed. In this example, a part of the gate insulating film 43 covering the lower electrode 32 that is exposed through the gate protection film 243 is removed by wet etching or RIE. As a result, the upper surface of the lower electrode 32 is exposed at the bottom portion of the transistor hole TH. In the case of wet etching, a hydrofluoric acid solution (hereinafter may be referred to as an HF solution) or a buffered hydrofluoric acid solution (hereinafter may be referred to as a BHF solution) is used as an etching solution. A BHF solution is a mixture of ammonium fluoride (NH4F) and HF. Alkaline chemicals other than NH4F mixed with HF may also be used.

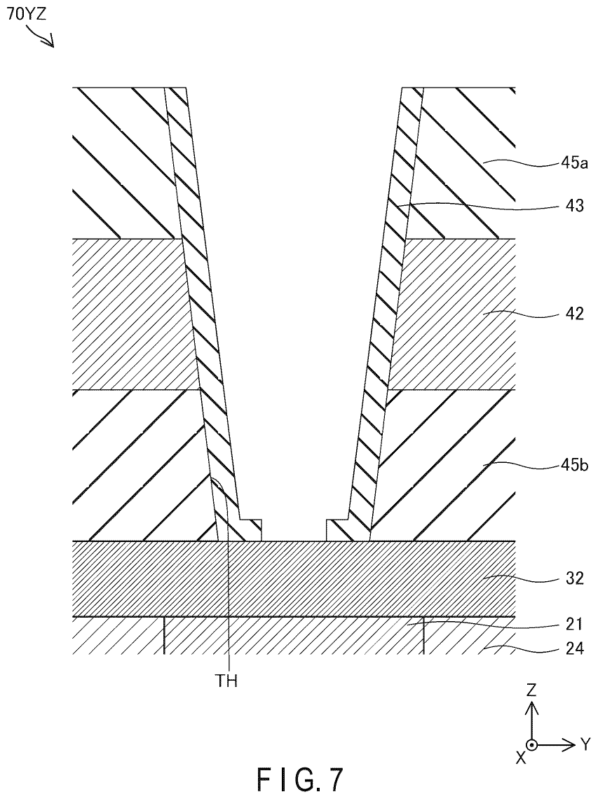

Next, as shown in FIG. 7, gate protection film peeling processing is performed. In this example, the gate protection film 243 is removed by wet etching. This exposes the gate insulating film 43 inside the transistor hole TH.

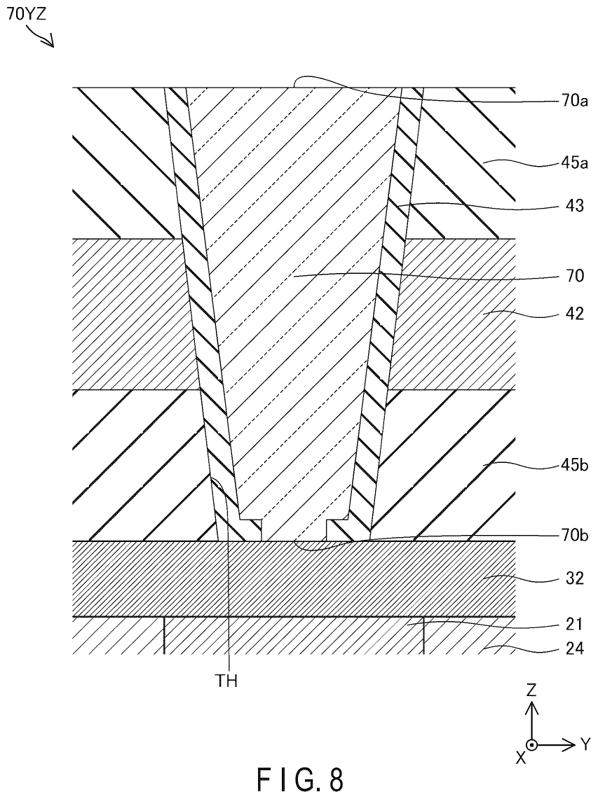

Next, as shown in FIG. 8, oxide semiconductor layer forming processing is performed. In this example, the oxide semiconductor layer 70 is formed on the upper surface of the insulating film 45a and inside the transistor hole TH. The oxide semiconductor layer 70 comes into contact with the upper surface of the lower electrode 32 exposed at the bottom portion of the transistor hole TH. As a result, the transistor hole TH is buried with the oxide semiconductor layer 70. Then, the oxide semiconductor layer 70 deposited above the insulating film 45a is chemically mechanically polished, so that the upper surface of the insulating film 45a is exposed. At this time, the surface of the upper end 70a of the oxide semiconductor layer 70 is positionally aligned in the Z-axis direction with the upper surface of the insulating film 45a. The conductive layer 42 surrounds the oxide semiconductor layer 70 via the gate insulating film 43.

A second example of the method for manufacturing the semiconductor device 30 according to the first embodiment (hereinafter, may be referred to as a second example of the first embodiment) will be hereinafter described.

### (Second Example of First Embodiment)

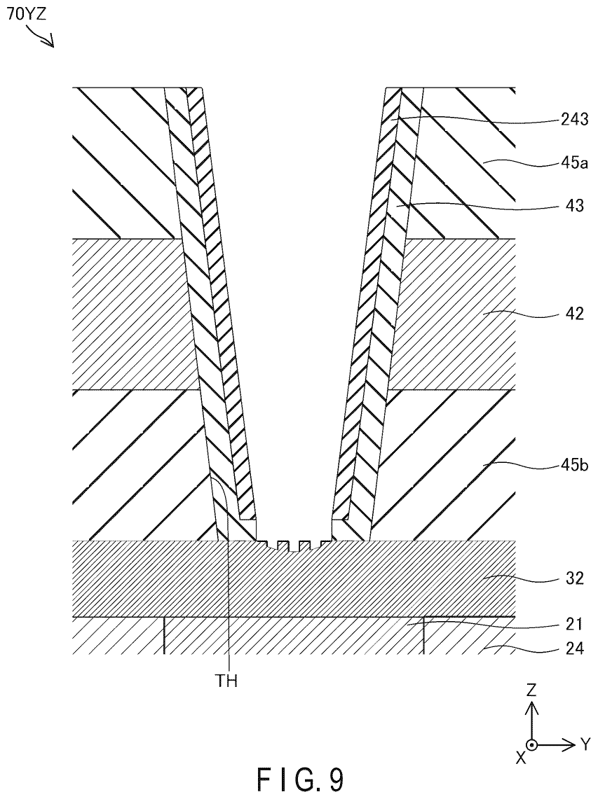

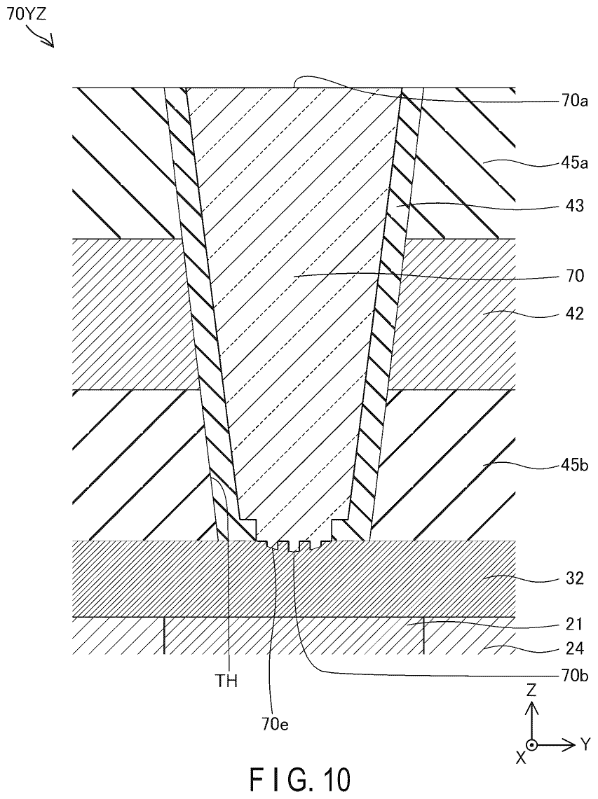

FIG. 9 and FIG. 10 are sectional views of a semiconductor device 30 according to a second example of the first embodiment. The sectional views are views of the cross-section 70YZ that is parallel to the YZ plane and included in the transistor hole TH.

As shown in FIG. 9 and FIG. 10, the second example of the first embodiment of the manufacturing method differs from the first example of the first embodiment of the manufacturing method shown in FIG. 3 to FIG. 8 in that the time of the bottom punching processing is longer.

As shown in FIG. 9, in this example, the bottom punching processing is performed by wet etching. Since the processing time of the wet etching is longer than that shown in FIG. 6, a part of the lower electrode 32 is also removed by wet etching. For example, when the ITO included in the lower electrode 32 is crystalline, the HF solution or BHF solution infiltrates into the grain interface, and the grain boundary in the lower electrode 32 expands.

The gate protection film peeling processing subsequent to the bottom punching processing is the same as the processing shown in FIG. 7, thus a detailed description thereon will be omitted.

Next, as shown in FIG. 10, oxide semiconductor layer forming processing is performed. In this example, the oxide semiconductor layer 70 includes an extension 70e extending downward from the upper end portion of the lower electrode 32. The extension 70e is formed by forming the oxide semiconductor layer 70 at the grain boundary that spreads in the lower electrode 32. The lower end 70b of the oxide semiconductor layer 70 is located inside the lower electrode 32. A plurality of extensions 70e may be provided inside the lower electrode 32.

A third example of the manufacturing method of the semiconductor device 30 according to the first embodiment (hereinafter, may be referred to as a third example of the first embodiment) will be hereinafter described.

### (Third Example of First Embodiment)

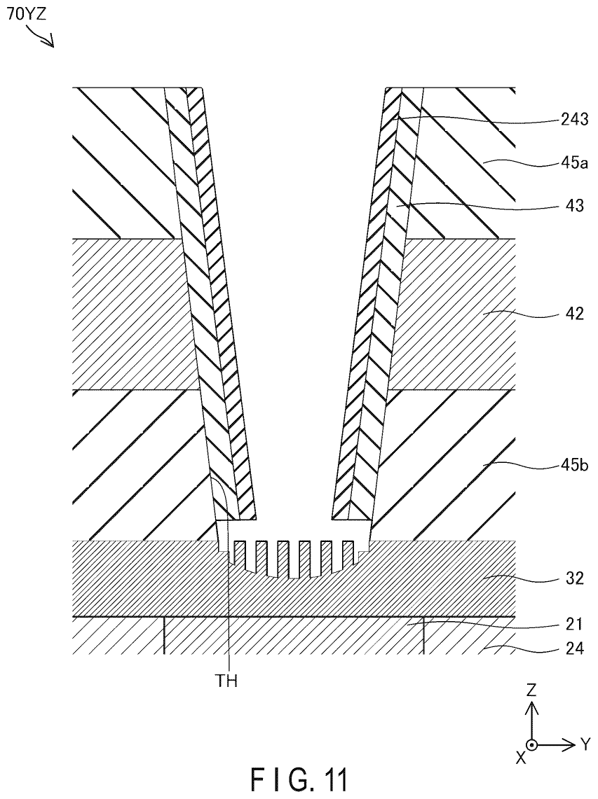

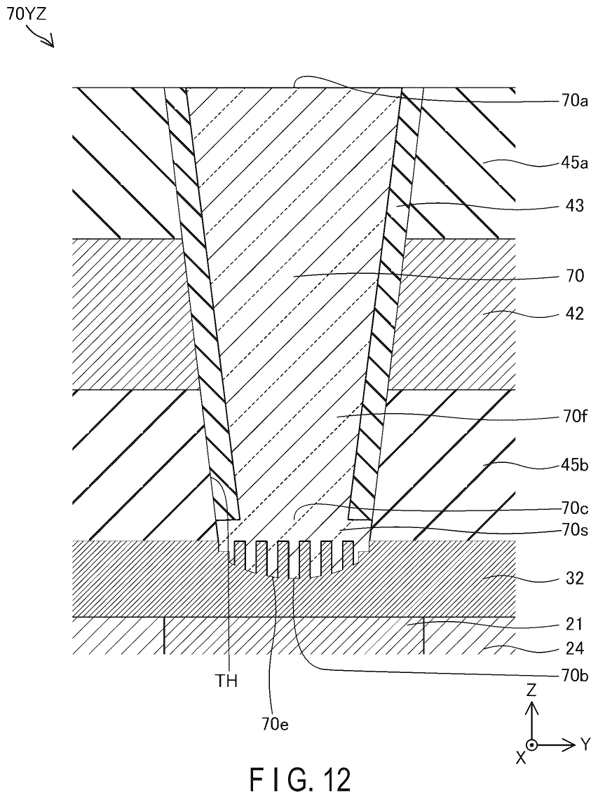

FIG. 11 and FIG. 12 are sectional views of a semiconductor device 30 according to a third example of the first embodiment. The sectional views are views of the cross-section 70YZ that is parallel to the YZ plane and included in the transistor hole TH.

As shown in FIG. 11 and FIG. 12, the third example of the first embodiment of the manufacturing method differs from the second example of the first embodiment of the manufacturing method shown in FIG. 9 and FIG. 10 in that the processing time for the bottom punching processing is longer.

As shown in FIG. 11, in this example, since the processing time for wet etching is longer than that shown in FIG. 9, the grain boundary in the lower electrode 32 extends downward more than that shown in FIG. 9. Furthermore, since a lower part of the gate insulating film 43 is also removed, the bottom portion of the transistor hole TH extends along the XY plane. Furthermore, the thickness of the gate protection film 243 is reduced by wet etching.

Since the gate protection film peeling processing subsequent to the bottom punching processing is the same as the processing shown in FIG. 7, detailed description thereon is omitted.

Next, as shown in FIG. 12, oxide semiconductor layer forming processing is performed. In this example, the oxide semiconductor layer 70 includes a first portion 70f and a second portion 70s.

The first portion 70f is connected to the upper electrode 50 (see FIG. 2). The gate insulating film 43 surrounds the side surface of the first portion 70f. The conductive layer 42 faces the first portion 70f via the gate insulating film 43. The first portion 70f penetrates through the insulating film 45a and the conductive layer 42.

The second portion 70s is connected to the lower end portion of the first portion 70f. The second portion 70s has a diameter larger than the diameter of the lower end portion of the first portion 70f. In detail, when the second portion 70s is viewed along the up-down direction, the maximum diameter of the second portion 70s is larger than the diameter of the lower end portion of the first portion 70f. The second portion 70s is connected to the lower electrode 32. In this specification, the “diameter” may also refer to the length in a direction intersecting the up-down direction (for example, the X-axis direction or the Y-axis direction).

A connection portion 70c between the first portion 70f and the second portion 70s is provided in the insulating film 45b. In detail, the position of the connection portion 70c in the Z-axis direction is set between the position of the upper end portion of the insulating film 45b in the Z-axis direction and the position of the lower end portion of the insulating film 45b in the Z-axis direction.

The lower end portion of the gate insulating film 43 has an outer diameter which is equal to or less than the diameter of the second portion 70s of the oxide semiconductor layer 70. In detail, when the second portion 70s is viewed in the up-down direction, the outer diameter of the lower end portion of the gate insulating film 43 is equal to or less than the maximum diameter of the second portion 70s.

The lower end 70b of the oxide semiconductor layer 70 is located at a lower position inside the lower electrode 32 than that in the case shown in FIG. 9. Furthermore, since the oxide semiconductor layer 70 is formed at the bottom portion of the transistor hole TH that is widened along the XY plane, the contact area between the oxide semiconductor layer 70 and the lower electrode 32 is increased. This makes it possible to reduce the contact resistance between the oxide semiconductor layer 70 and the lower electrode 32.

A fourth example of the method for manufacturing the semiconductor device 30 according to the first embodiment (hereinafter, may be referred to as a fourth example of the first embodiment) will be hereinafter described.

### (Fourth Example of First Embodiment)

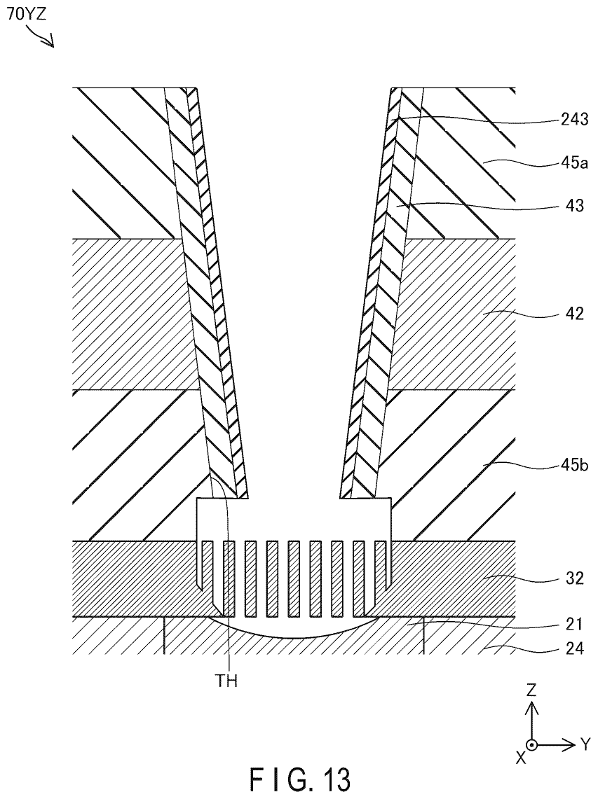

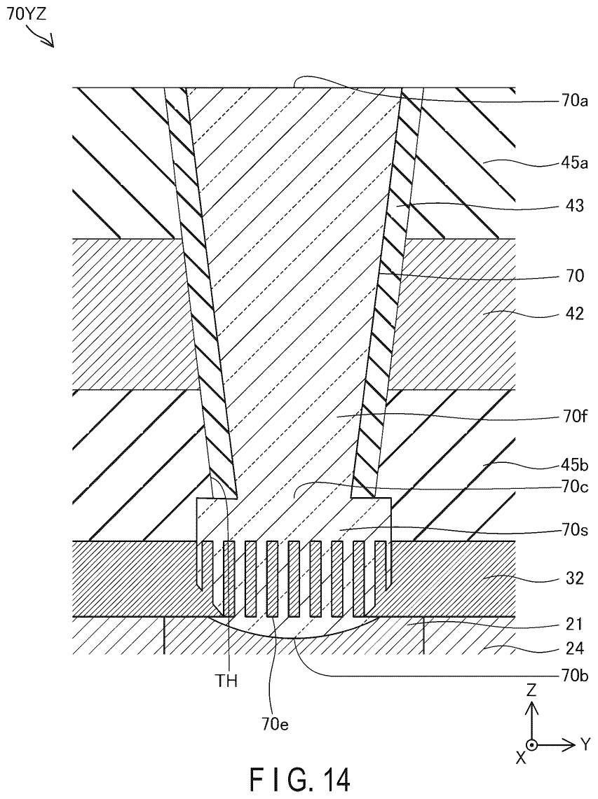

FIG. 13 and FIG. 14 are sectional views of a semiconductor device 30 according to a fourth example of the first embodiment. The sectional views are views of the cross-section 70YZ that is parallel to the YZ plane and included in the transistor hole TH.

As shown in FIG. 13 and FIG. 14, the fourth example of the first embodiment of the manufacturing method differs from the third example of the first embodiment of the manufacturing method shown in FIG. 11 and FIG. 12 in that the processing time for the bottom punching processing is longer.

As shown in FIG. 13, in this example, since the processing time for wet etching is longer than that in the case shown in FIG. 11, the grain boundary in the lower electrode 32 spreads to penetrate through the lower electrode 32 in the up-down direction. Furthermore, a part of the conductor 21 is also removed. Furthermore, the bottom portion of the transistor hole TH spreads along the XY plane more greatly than that in the case shown in FIG. 11. Furthermore, the wet etching makes a thickness of the gate protection film 243 smaller than that in the case shown in FIG. 11.

Sinc the gate protection film peeling processing subsequent to the bottom punching processing is the same as the processing shown in FIG. 7, detailed description thereon will be omitted.

Next, as shown in FIG. 14, the oxide semiconductor layer forming processing is performed. In this example, the extension 70e of the oxide semiconductor layer 70 penetrates through the lower electrode 32 along the up-down direction. The lower end 70b of the oxide semiconductor layer 70 is located below the lower electrode 32. Furthermore, since the oxide semiconductor layer 70 is formed at the bottom portion of the transistor hole TH that is widened along the XY plane, the contact area between the oxide semiconductor layer 70 and the lower electrode 32 is further increased. This makes it possible to further reduce the contact resistance between the oxide semiconductor layer 70 and the lower electrode 32.

A fifth example of the method for manufacturing the semiconductor device 30 according to the first embodiment (hereinafter, may be referred to as a fifth example of the first embodiment) will be hereinafter described.

### (Fifth Example of First Embodiment)

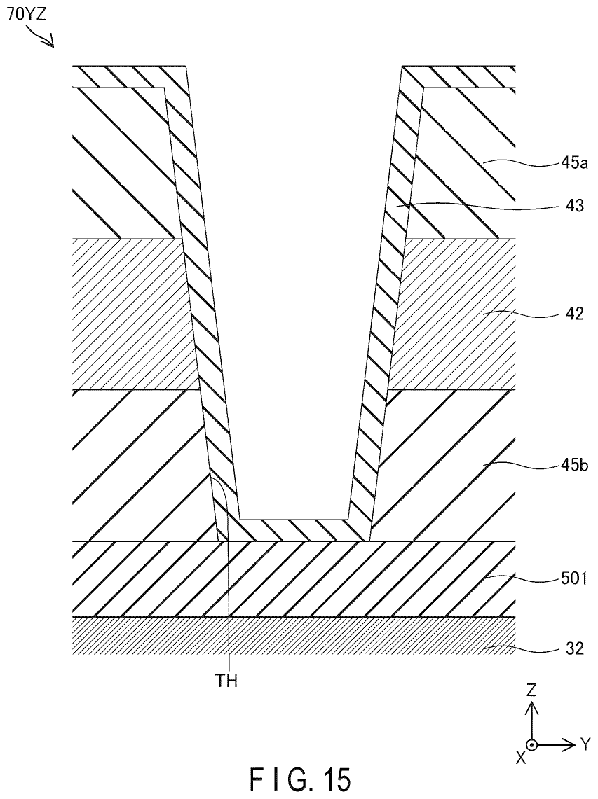

FIG. 15 to FIG. 20 are sectional views of a semiconductor device 30 according to a fifth example of the first embodiment. The sectional views are views of the cross-section 70YZ which is parallel to the YZ plane and included in the transistor hole TH.

As shown in FIG. 15 to FIG. 20, the fifth example of the first embodiment of the manufacturing method differs from the first example of the first embodiment of the manufacturing method shown in FIG. 3 to FIG. 8 in that a stopper film 501 (an example of the “first layer” and the “first insulating film”) is provided above the lower electrode 32.

The stopper film 501 is provided below the insulating film 45b. The stopper film 501 contains, for example, aluminum and oxygen. In this example, the stopper film 501 contains an oxide of aluminum (AlOx).

Note that the stopper film 501 may be configured to contain at least one element of silicon, hafnium, lanthanum, niobium, yttrium, tantalum, vanadium, magnesium, zinc, gallium, tin, antimony, tellurium, lead, bismuth, thallium, scandium, titanium, molybdenum, and tungsten, and oxygen. The etching rate of the stopper film 501 is higher than the etching rate of the insulating film 45b.

The stopper film 501 prevents the ITO contained in the lower electrode 32 from being damaged by a cleaning agent, for example, when residues inside the transistor hole TH are removed by dry or wet processing after the transistor hole TH is formed.

The stopper film 501 also prevents occurrence of whiskers such as tungsten whiskers by preventing the lower electrode 32 containing the ITO from being exposed when the gate insulating film 43 is formed.

First, as shown in FIG. 15, the transistor hole TH is formed. In this example, the upper surface of the stopper film 501 serves as the bottom portion of the transistor hole TH. Then, the gate insulating film 43 is formed, for example, by ALD so as to cover the upper surface of the insulating film 45a and the inside of the transistor hole TH.

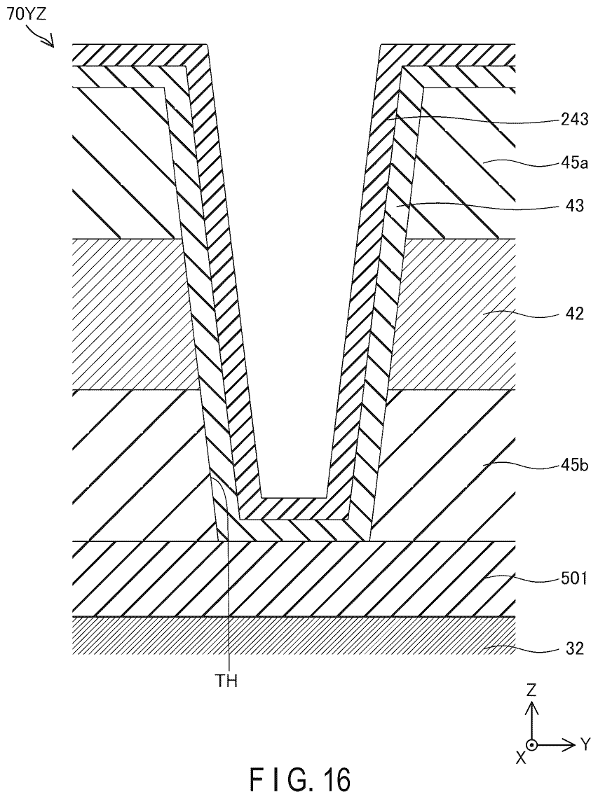

Next, as shown in FIG. 16, the gate protection film formation processing similar to the processing shown in FIG. 4 is performed.

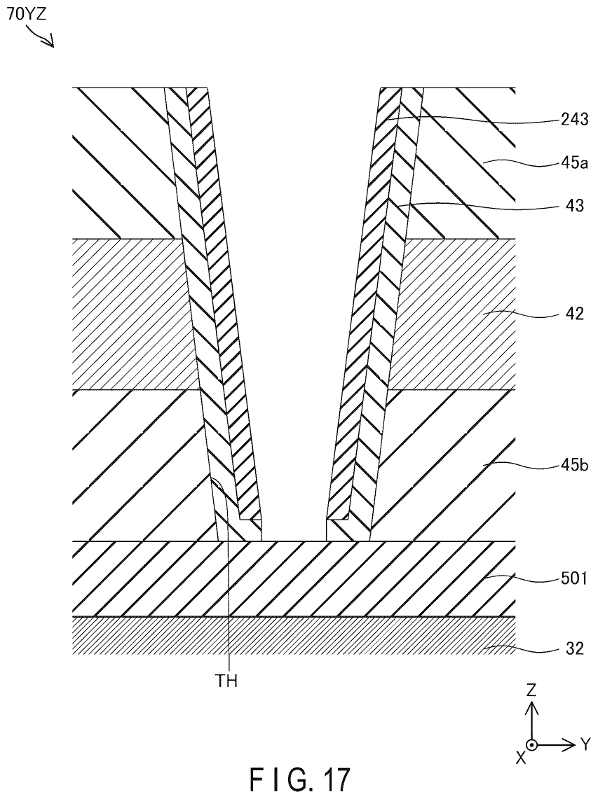

Next, as shown in FIG. 17, gate protection film etch-back processing similar to the processing shown in FIG. 5 is performed. In this example, since a stopper film 501 is provided, a lower part of the gate protection film 243 and a lower part of the gate insulating film 43 are removed by RIE such that the upper surface of the stopper film 501 is exposed.

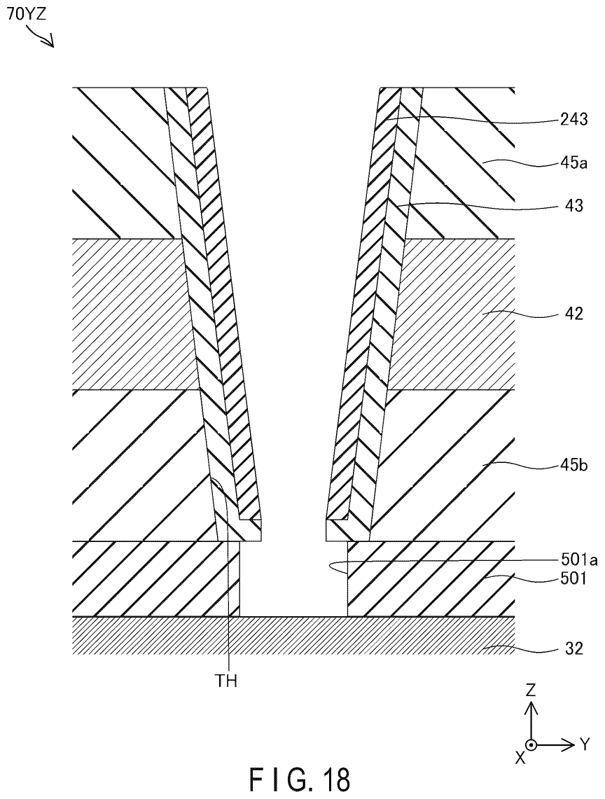

Next, as shown in FIG. 18, bottom punching processing similar to the processing shown in FIG. 6 is performed. In this example, a part of the stopper film 501 is removed through the bottom portion of the transistor hole TH by wet etching using the HF solution or the BHF solution. As a result, a hole portion 501a penetrating through the stopper film 501 in the up-down direction is formed in the stopper film 501. The upper surface of the lower electrode 32 is exposed through the hole portion 501a.

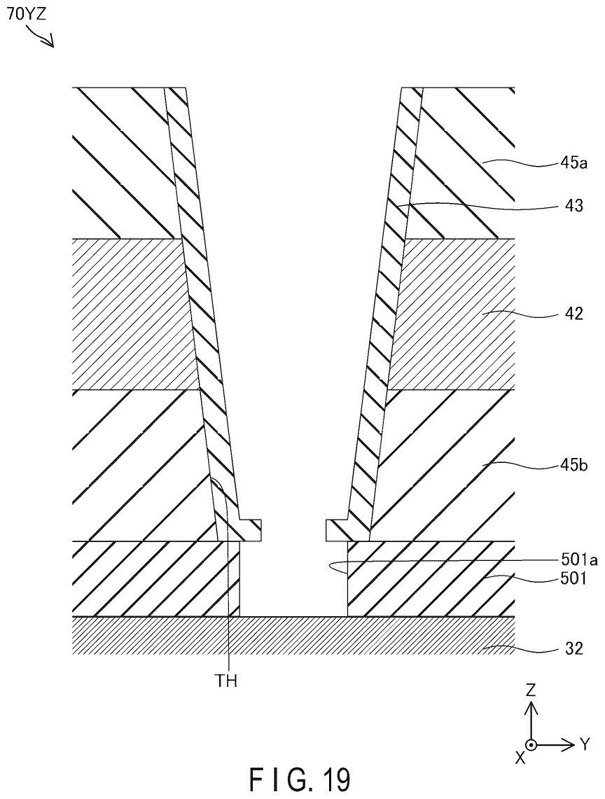

Next, as shown in FIG. 19, gate protection film peeling processing similar to the processing shown in FIG. 7 is performed.

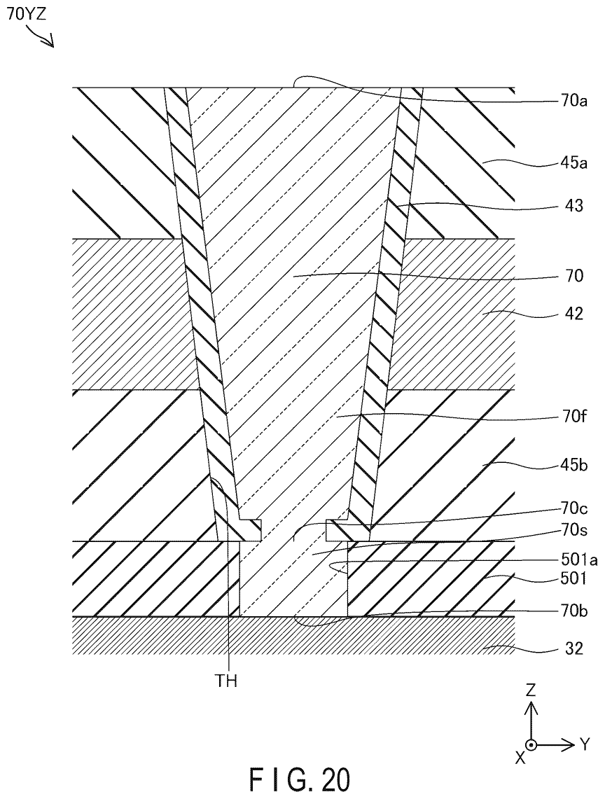

Next, as shown in FIG. 20, oxide semiconductor layer forming processing similar to the processing shown in FIG. 8 is performed.

A sixth example of the manufacturing method for the semiconductor device 30 according to the first embodiment (hereinafter, may be referred to as a sixth example of the first embodiment) will be hereinafter described.

### (Sixth Example of First Embodiment)

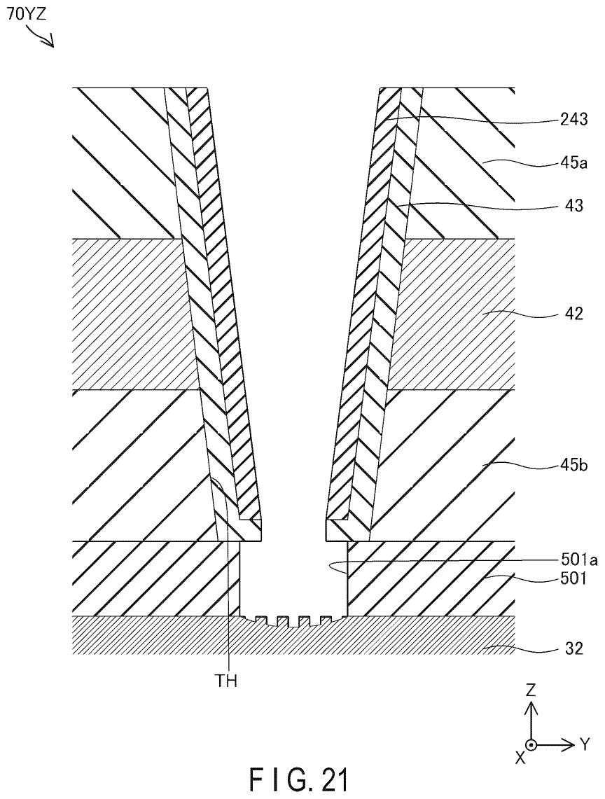

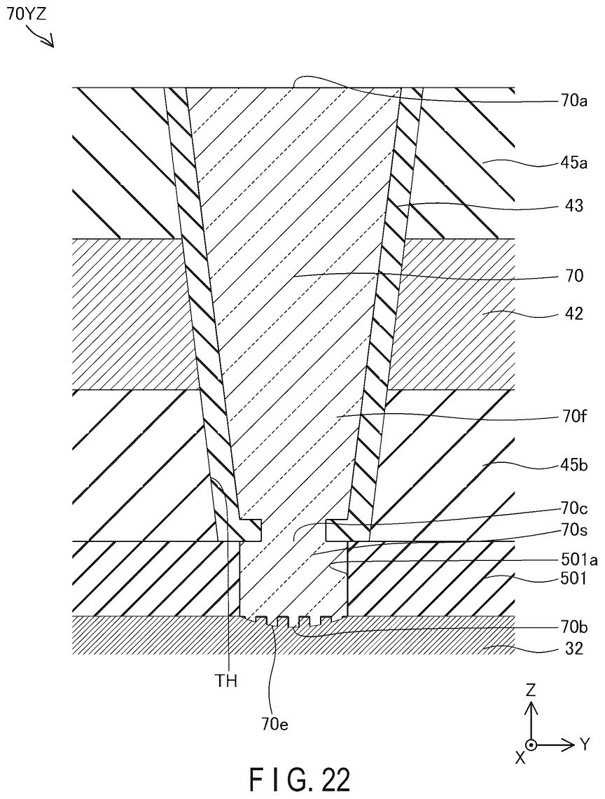

FIG. 21 and FIG. 22 are sectional views of a semiconductor device 30 according to a sixth example of the first embodiment. The sectional views are views of the cross-section 70YZ that is parallel to the YZ plane and included in the transistor hole TH.

As shown in FIG. 21 and FIG. 22, the sixth example of the first embodiment of the manufacturing method differs from the fifth example of the first embodiment of the manufacturing method shown in FIG. 15 to FIG. 20 in that the processing time for the bottom punching processing is longer.

As shown in FIG. 21, in this example, the bottom punching processing is performed by wet etching. Since the processing time for wet etching is longer than that in the case shown in FIG. 18, a part of the lower electrode 32 is also removed. For example, when the lower electrode 32 is crystalline, the HF solution or the BHF solution infiltrates into the grain interface, and the grain boundary in the lower electrode 32 spreads.

The gate protection film peeling processing subsequent to the bottom punching processing is the same as the processing shown in FIG. 19, and thus detailed description thereon is omitted.

Next, as shown in FIG. 22, oxide semiconductor layer forming processing is performed. In this example, the lower end 70b of the oxide semiconductor layer 70 is located inside the lower electrode 32.

A seventh example of the manufacturing method for the semiconductor device 30 according to the first embodiment (hereinafter, may be referred to as a seventh example of the first embodiment) will be hereinafter described.

### (Seventh Example of First Embodiment)

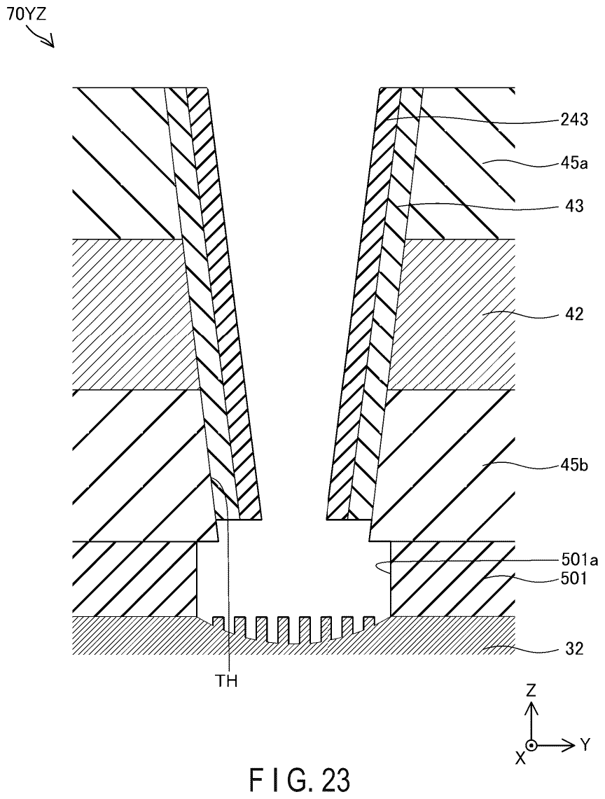

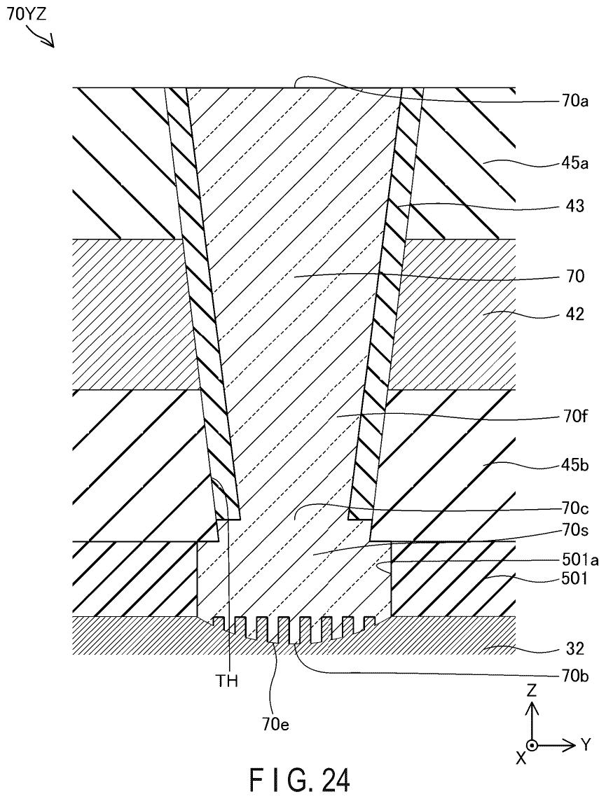

FIG. 23 and FIG. 24 are sectional views of a semiconductor device 30 according to a seventh example of the first embodiment. The sectional views are views of the cross-section 70YZ that is parallel to the YZ plane and included in the transistor hole TH.

As shown in FIG. 23 and FIG. 24, the seventh example of the first embodiment of the manufacturing method differs from the sixth example of the first embodiment of the manufacturing method shown in FIG. 21 and FIG. 22 in that the processing time for the bottom punching processing is longer.

As shown in FIG. 23, in this example, since the processing time for wet etching is longer than that in the case shown in FIG. 21, a lower part of the gate insulating film 43 is removed. The hole portion 501a of the stopper film 501 expands in diameter in a direction perpendicular to the up-down direction, that is, in the X-axis direction and the Y-axis direction. Furthermore, the grain boundaries in the lower electrode 32 expand more greatly along the XY plane than that in the case shown in FIG. 21, and extend downward.

Since the gate protection film peeling processing subsequent to the bottom punching processing is the same as the processing shown in FIG. 19, detailed description thereon will be omitted.

Next, as shown in FIG. 24, oxide semiconductor layer forming processing is performed. In this example, the lower end 70b of the oxide semiconductor layer 70 is located at a lower position inside the lower electrode 32 than that in the case shown in FIG. 22. Furthermore, since the oxide semiconductor layer 70 is formed in the hole portion 501a which expands in diameter in the direction perpendicular to the up-down direction, the contact area between the oxide semiconductor layer 70 and the lower electrode 32 is increased. This makes it possible to reduce the contact resistance between the oxide semiconductor layer 70 and the lower electrode 32.

An eighth example of the manufacturing method for the semiconductor device 30 according to the first embodiment (hereinafter, may be referred to as an eighth example of the first embodiment) will be hereinafter described.

### (Eighth Example of First Embodiment)

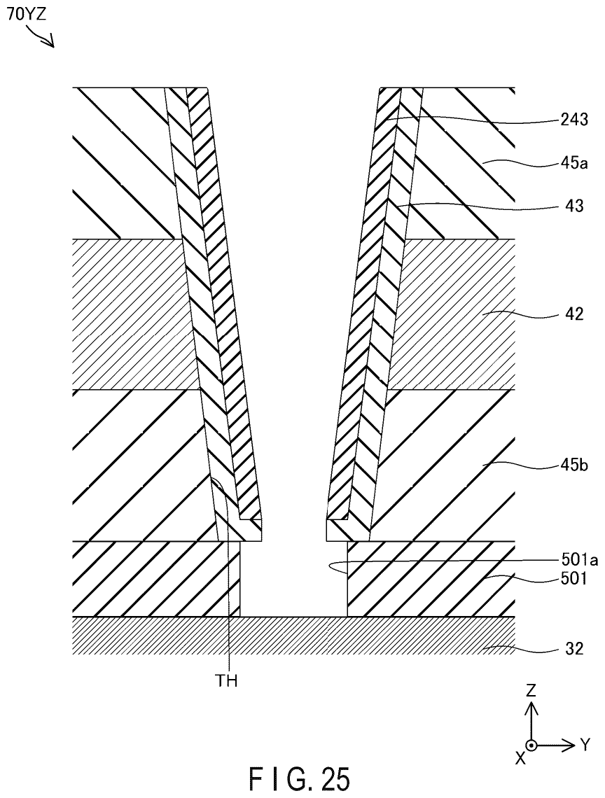

FIG. 25 to FIG. 27 are sectional views of a semiconductor device 30 according to an eighth example of the first embodiment. The sectional views are views of the cross-section 70YZ that is parallel to the YZ plane and included in the transistor hole TH.

As shown in FIG. 25 to FIG. 27, the eighth example of the first embodiment of the manufacturing method differs from the fifth example of the first embodiment of the manufacturing method shown in FIG. 15 to FIG. 20 in that an alkali treatment and diameter expansion processing are added between the bottom punching processing and the gate protection film peeling processing.

As shown in FIG. 25, the alkali treatment is performed after the bottom punching processing. In this example, a part of the stopper film 501 is removed by wet etching using an alkaline chemical solution. As a result, the bottom portion of the transistor hole TH expands along the XY plane. The hole portion 501a of the stopper film 501 expands in diameter in the direction perpendicular to the up-down direction.

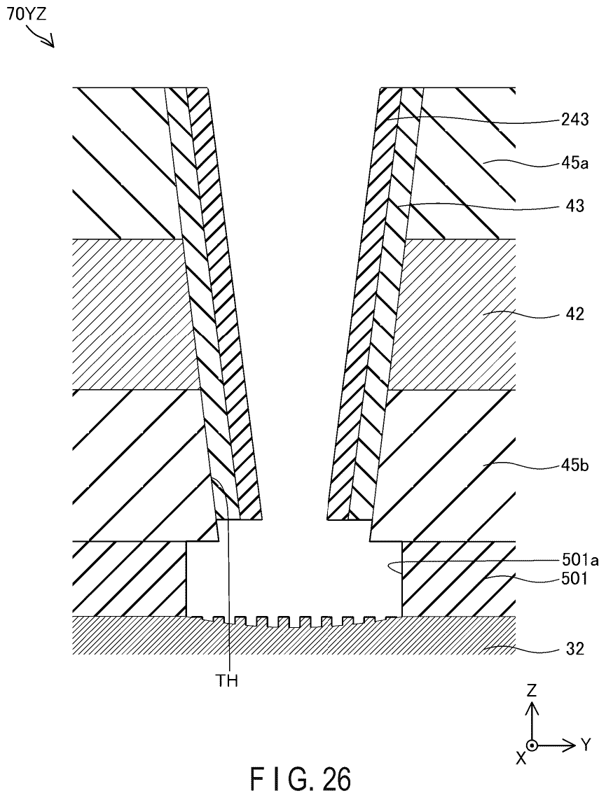

Next, as shown in FIG. 26, the diameter expansion processing is performed. In this example, a lower part of the gate insulating film 43, a part of the stopper film 501, and a part of the lower electrode 32 are removed by wet etching using the HF solution or the BHF solution. As a result, the bottom portion of the transistor hole TH expands along the XY plane. The hole portion 501a of the stopper film 501 expands in diameter in the direction perpendicular to the up-down direction. Furthermore, the HF solution or the BHF solution infiltrates into the grain interface, and the grain boundaries expand in the lower electrode 32.

The gate protection film peeling processing subsequent to the bottom punching processing is the same as the processing shown in FIG. 19, and thus detailed description thereon will be omitted.

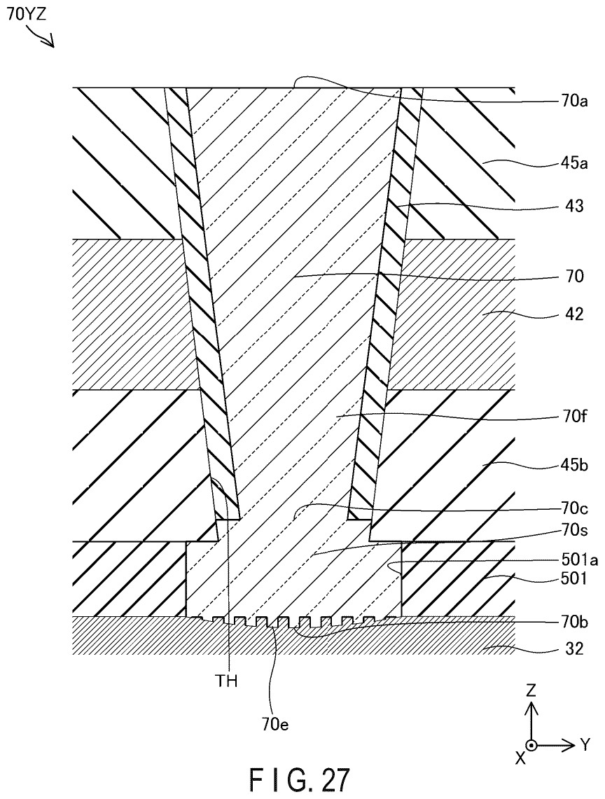

Next, as shown in FIG. 27, oxide semiconductor layer forming processing is performed. In this example, the lower end 70b of the oxide semiconductor layer 70 is located inside the lower electrode 32.

A ninth example of the manufacturing method for the semiconductor device 30 according to the first embodiment (hereinafter, may be referred to as a ninth example of the first embodiment) will be hereinafter described.

### (Ninth Example of First Embodiment)

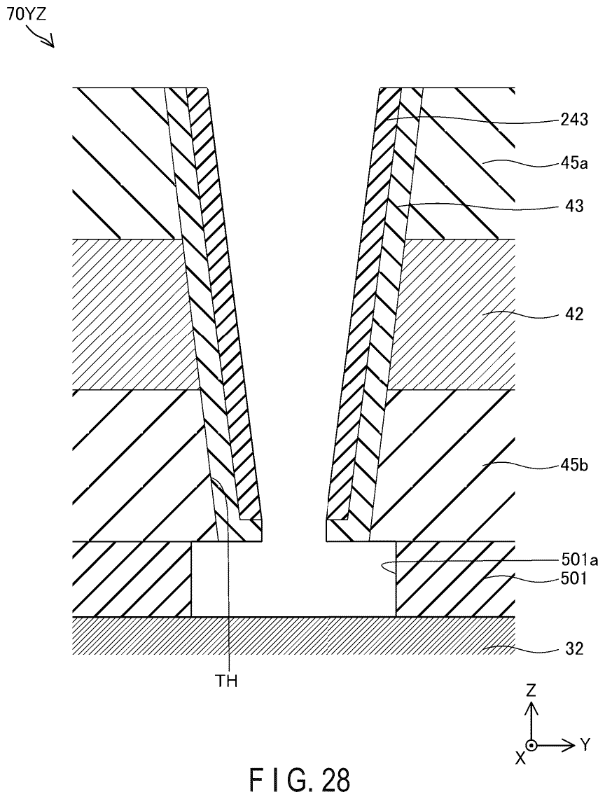

FIG. 28 to FIG. 30 are sectional views of a semiconductor device 30 according to a ninth example of the first embodiment. The sectional views are views of the cross-section 70YZ that is parallel to the YZ plane and included in the transistor hole TH.

As shown in FIG. 28 to FIG. 30, the ninth example of the first embodiment of the manufacturing method differs from the eighth example of the first embodiment of the manufacturing method shown in FIG. 25 to FIG. 27 in that the times required for the alkali treatment and the diameter expansion processing are longer.

As shown in FIG. 28, the alkali treatment is performed after the bottom punching processing. In this example, since the treatment time for the alkali treatment is longer than that in the case shown in FIG. 25, the hole portion 501a of the stopper film 501 expands in diameter in the direction perpendicular to the up-down direction.

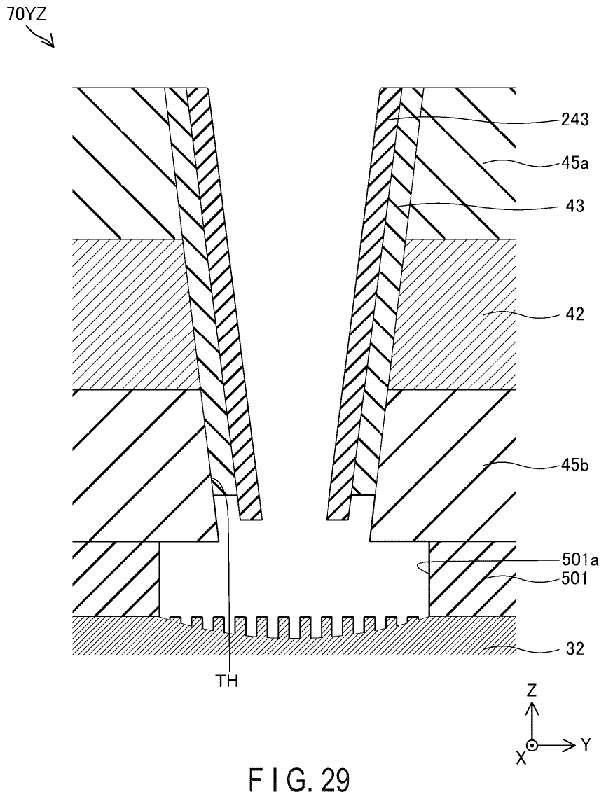

Next, as shown in FIG. 29, the diameter expansion processing is performed. In this example, since the processing time of the diameter expansion processing is longer than that in the case shown in FIG. 26, a lower part of the gate insulating film 43 is further removed as compared with the case shown in FIG. 26. The hole portion 501a of the stopper film 501 further expands in diameter in the direction perpendicular to the up-down direction. Also, the grain boundaries in the lower electrode 32 are further enlarged along the XY plane as compared with the case shown in FIG. 26, and extends downward.

The gate protection film peeling processing subsequent to the bottom punching processing is the same as the processing shown in FIG. 19, and thus detailed description thereon is omitted.

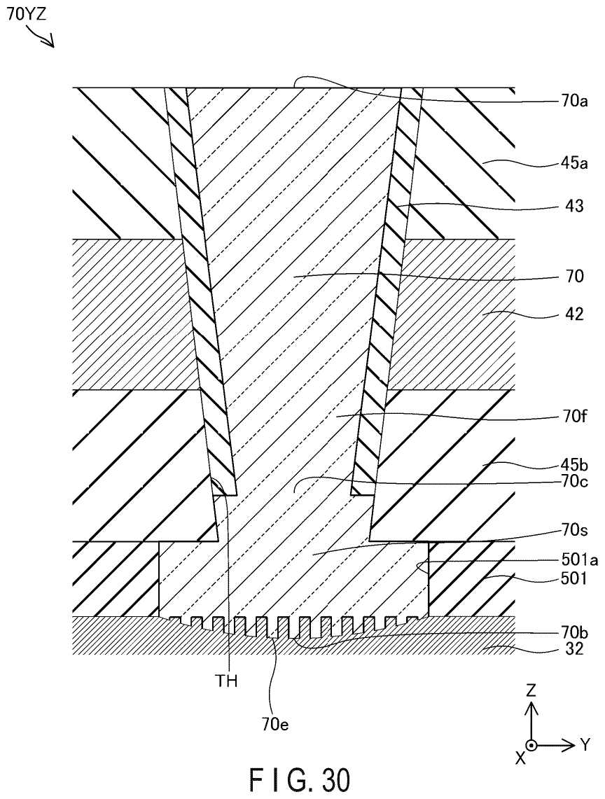

Next, as shown in FIG. 30, oxide semiconductor layer forming processing is performed. In this example, the lower end 70b of the oxide semiconductor layer 70 is located at a lower position inside the lower electrode 32 than that in the case shown in FIG. 27.

A tenth example of the manufacturing method for the semiconductor device 30 according to the first embodiment (hereinafter, may be referred to as a tenth example of the first embodiment) will be hereinafter described.

### (Tenth Example of First Embodiment)

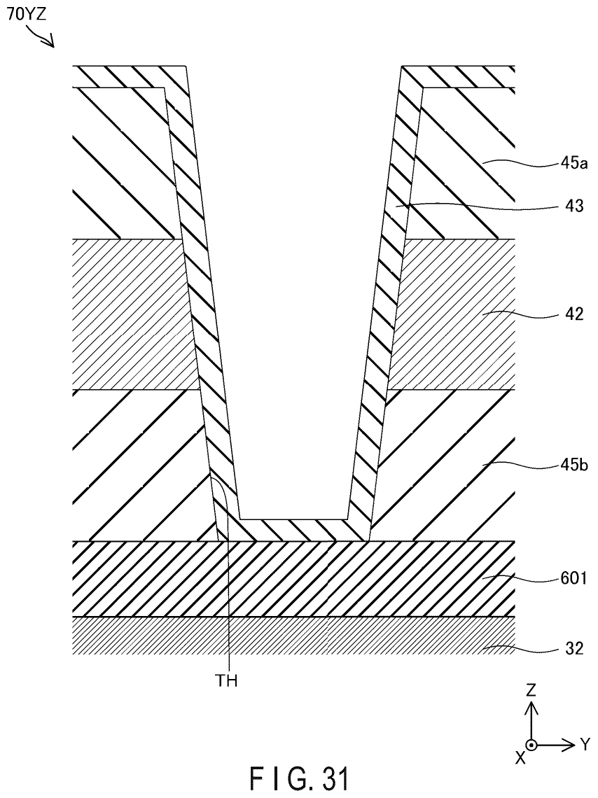

FIG. 31 to FIG. 36 are sectional views of a semiconductor device 30 according to a tenth example of the first embodiment. The sectional views are views of the cross-section 70YZ that is parallel to the YZ plane and included in the transistor hole TH.

As shown in FIG. 31 to FIG. 36, the tenth example of the first embodiment of the manufacturing method differs from the fifth example of the first embodiment of the manufacturing method shown in FIG. 15 to FIG. 20 in that a stopper film 601 (an example of the “first layer” and the “first insulating film”) is provided above the lower electrode 32 instead of the stopper film 501.

The stopper film 601 contains, for example, silicon and nitrogen. In this example, the stopper film 601 contains silicon nitride (SIN). Note that the stopper film 601 may be a configuration containing silicon, carbon, and nitrogen, for example, SiCN. Furthermore, the stopper film 601 may also be a configuration containing silicon, oxygen, and nitrogen, for example, SiON.

First, as shown in FIG. 31, the transistor hole TH and the gate insulating film 43 are formed in the same manner as in the processing shown in FIG. 3.

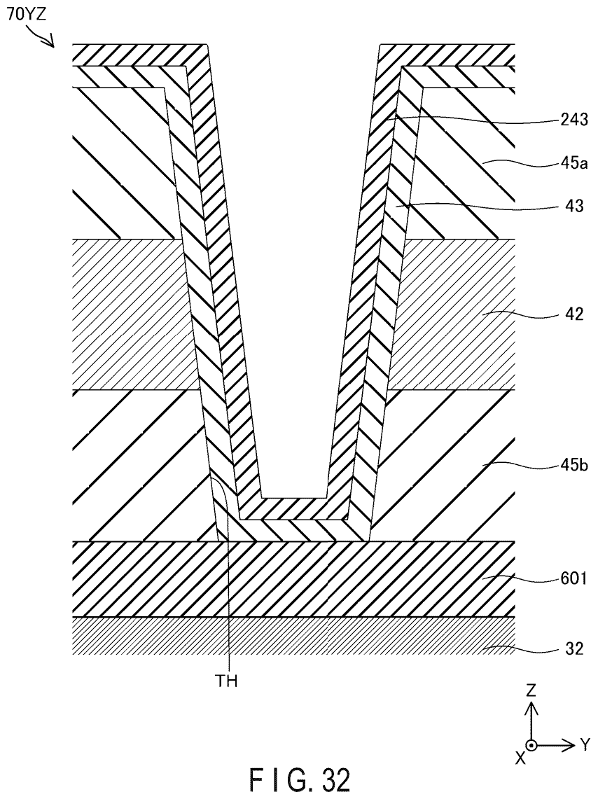

Next, as shown in FIG. 32, gate protection film forming processing similar to the processing shown in FIG. 4 is performed.

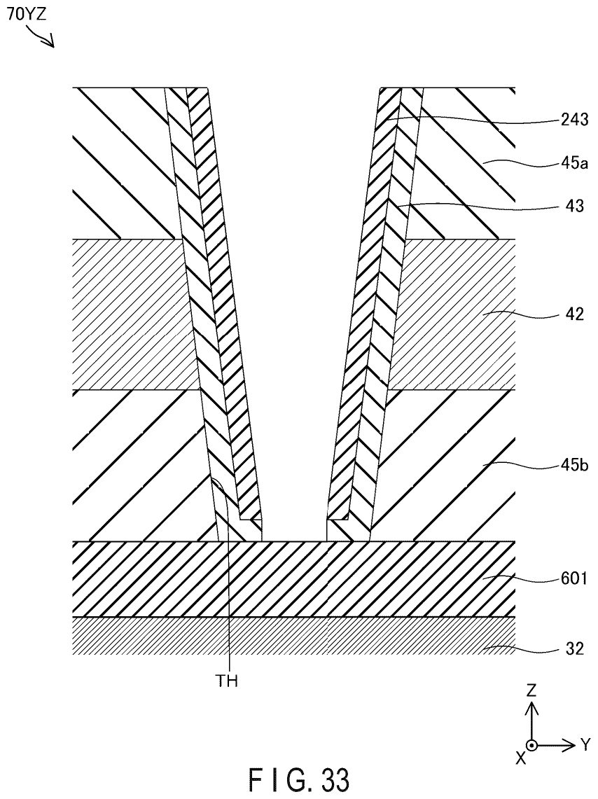

Next, as shown in FIG. 33, gate protection film etch-back processing similar to the processing shown in FIG. 5 is performed. In this example, since the stopper film 601 is provided, a part of the gate protection film 243 and a part of the gate insulating film 43 are removed by RIE such that the upper surface of the stopper film 601 is exposed.

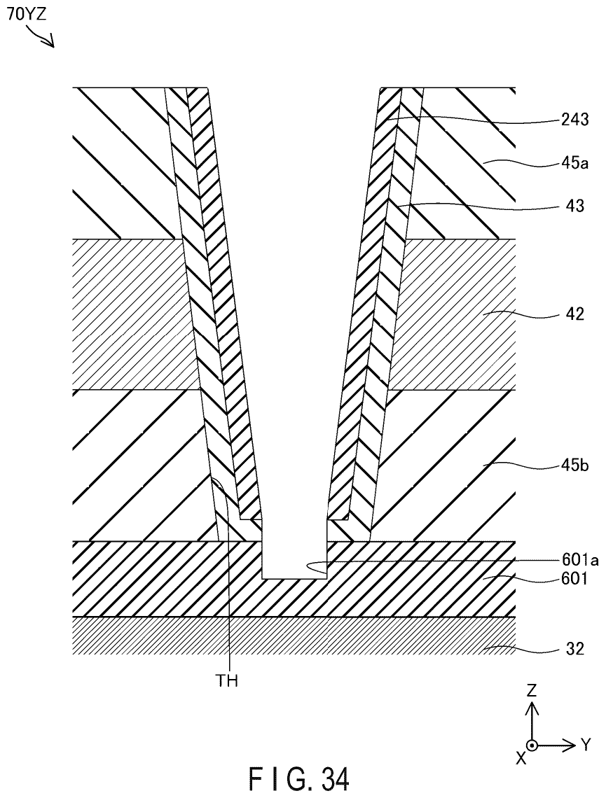

Next, as shown in FIG. 34, bottom punching processing similar to the processing shown in FIG. 6 is performed. In this example, a part of the stopper film 601 is removed through the bottom portion of the transistor hole TH by wet etching using the HF solution or the BHF solution, whereby a hole portion 601a is formed in the stopper film 601. In this example, the hole portion 601a does not penetrate through the stopper film 601 in the up-down direction.

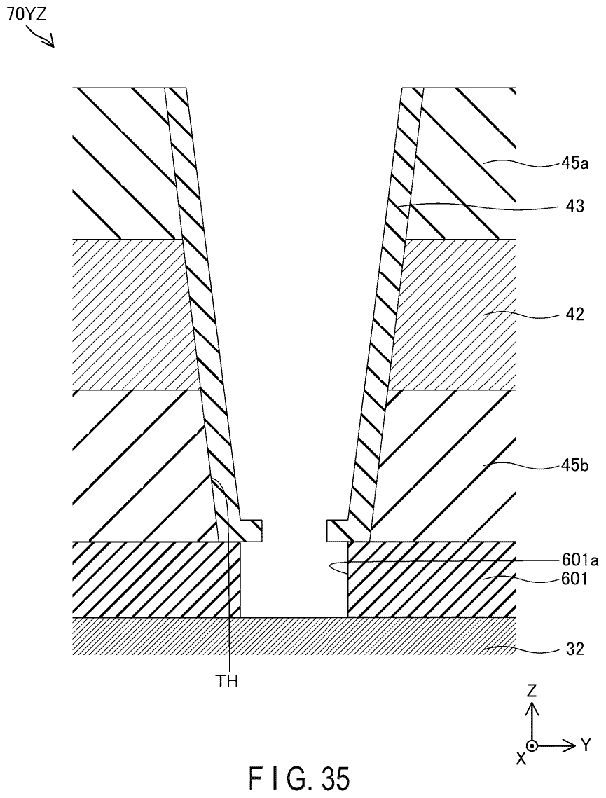

Next, as shown in FIG. 35, gate protection film peeling processing similar to the processing shown in FIG. 7 is performed. In this example, since the gate protection film 243 and the stopper film 601 contain SiN, the gate protection film 243 is peeled, and the hole portion 601a of the stopper film 601 expands in diameter in the direction perpendicular to the up-down direction and penetrates through the stopper film 601 in the up-down direction. As a result, the upper surface of the lower electrode 32 is exposed through the hole portion 601a.

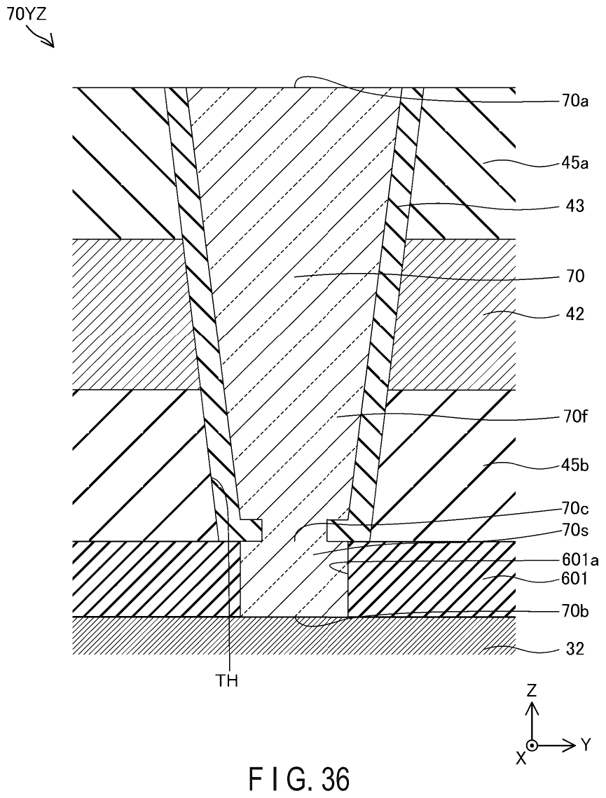

Next, as shown in FIG. 36, oxide semiconductor layer forming processing similar to the processing shown in FIG. 8 is performed.

An eleventh example of the manufacturing method for the semiconductor device 30 according to the first embodiment (hereinafter, may be referred to as an eleventh example of the first embodiment) will be hereinafter described.

### (Eleventh Example of First Embodiment)

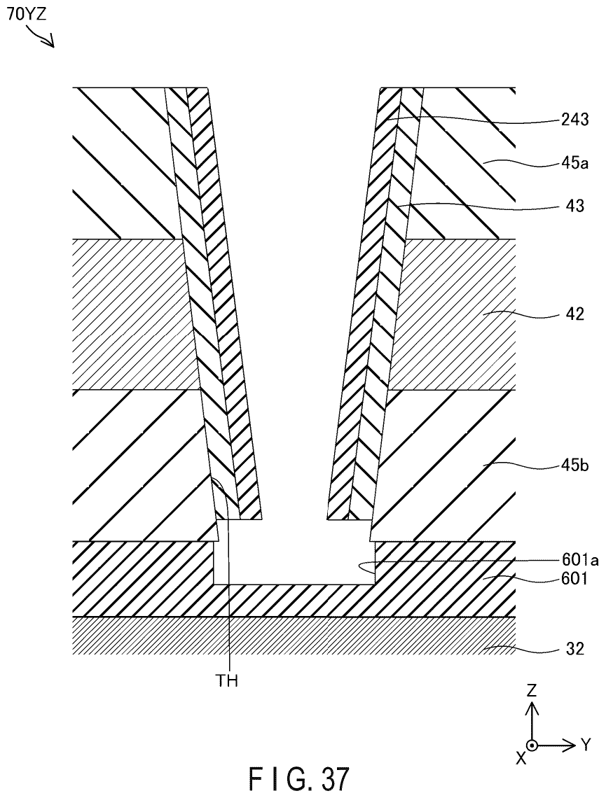

FIG. 37 to FIG. 39 are sectional views of a semiconductor device 30 according to an eleventh example of the first embodiment. The sectional views are views of the cross-section 70YZ that is parallel to the YZ plane and included in the transistor hole TH.

As shown in FIG. 37 to FIG. 39, the eleventh example of the first embodiment of the manufacturing method differs from the tenth example of the first embodiment of the manufacturing method shown in FIG. 34 to FIG. 36 in that the processing time for the bottom punching processing is longer.

As shown in FIG. 37, bottom punching processing similar to the processing as shown in FIG. 34 is performed. In this example, since the processing time of wet etching is longer than that in the case of FIG. 34, a lower part of the gate insulating film 43 is removed. The hole portion 601a of the stopper film 601 expands in diameter in the direction perpendicular to the up-down direction, and the bottom deepens.

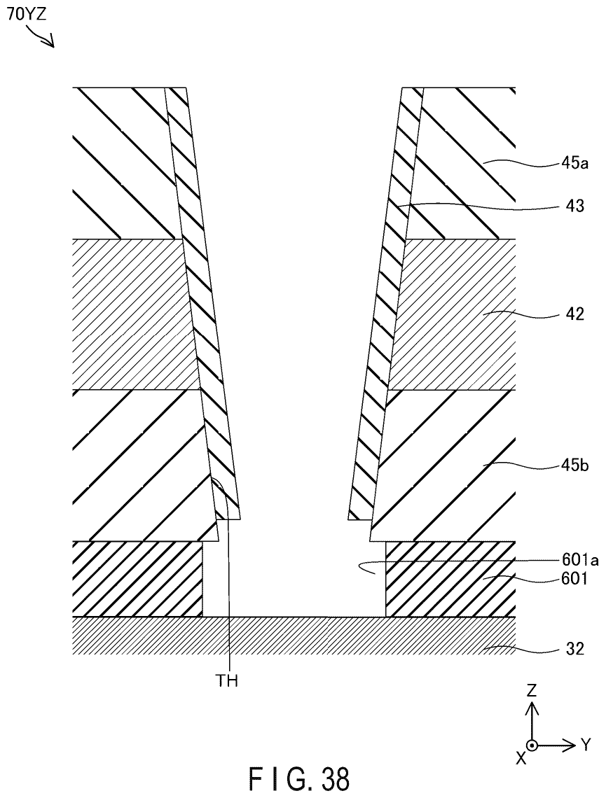

Next, as shown in FIG. 38, gate protection film peeling processing similar to the processing shown in FIG. 35 is performed. In this example, since the processing time for wet etching is longer than that in the case shown in FIG. 35, the hole portion 601a of the stopper film 601 expands in diameter in the direction perpendicular to the up-down direction and penetrates through the stopper film 601 in the up-down direction as compared with the case shown in FIG. 35.

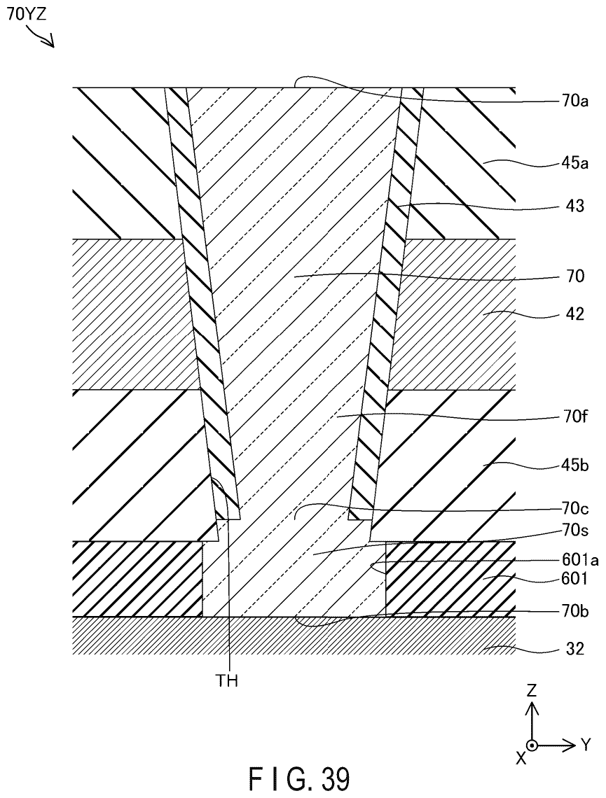

Next, as shown in FIG. 39, oxide semiconductor layer forming processing similar to the processing shown in FIG. 8 is performed.

A twelfth example of the manufacturing method for the semiconductor device 30 according to the first embodiment (hereinafter, may be referred to as a twelfth example of the first embodiment) will be hereinafter described.

### (Twelfth Example of First Embodiment)

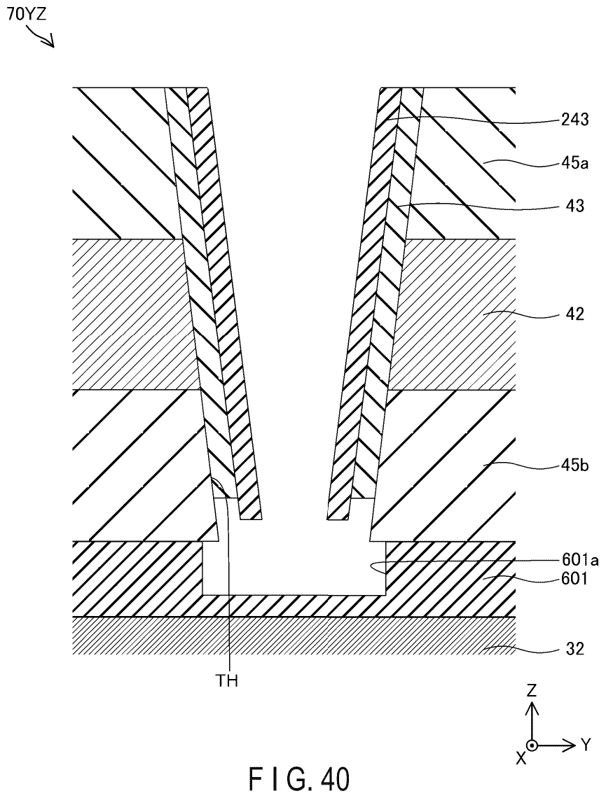

FIG. 40 to FIG. 42 are sectional views of a semiconductor device 30 according to a twelfth example of the first embodiment. The sectional views are views of the cross-section 70YZ that is parallel to the YZ plane and included in the transistor hole TH.

As shown in FIG. 40 to FIG. 42, the twelfth example of the first embodiment of the manufacturing method differs from the eleventh example of the first embodiment of the manufacturing method shown in FIG. 37 to FIG. 39 in that the processing time for the bottom punching processing is longer.

As shown in FIG. 40, bottom punching processing similar to the processing shown in FIG. 37 is performed. In this example, since the processing time for wet etching is longer than that in the case shown in FIG. 37, a lower part of the gate insulating film 43 is further removed as compared with the case shown in FIG. 37. The hole portion 601a of the stopper film 601 further expands in diameter in the direction perpendicular to the up-down direction and the bottom deepens.

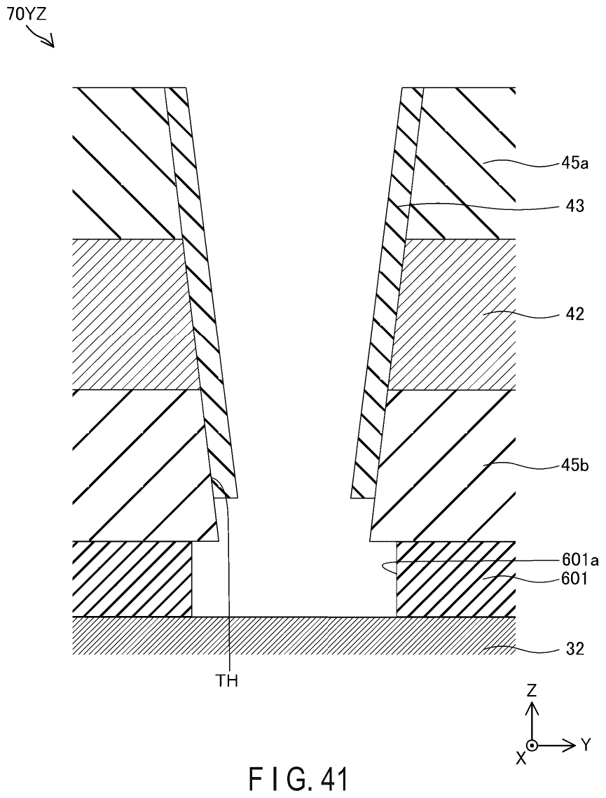

Next, as shown in FIG. 41, gate protection film peeling processing similar to the processing shown in FIG. 38 is performed. In this example, since the processing time for wet etching is longer than that in the case shown in FIG. 38, the hole portion 601a of the stopper film 601 expands in diameter in the direction perpendicular to the up-down direction and penetrates through the stopper film 601 in the up-down direction as compared with the case shown in FIG. 38.

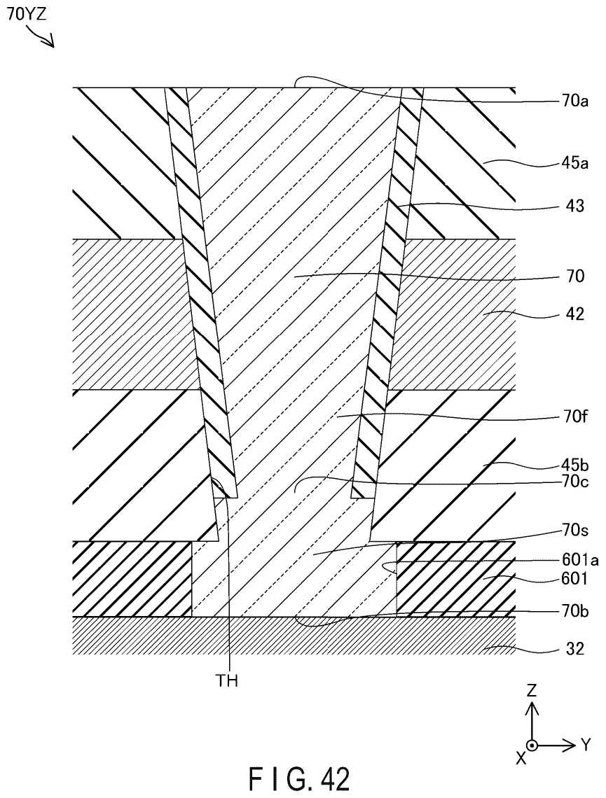

Next, as shown in FIG. 42, oxide semiconductor layer forming processing similar to the processing shown in FIG. 8 is performed.

A thirteenth example of the manufacturing method of the semiconductor device 30 according to the first embodiment (hereinafter, may be referred to as a thirteenth example of the first embodiment) will be hereinafter described.

### (Thirteenth Example of First Embodiment)

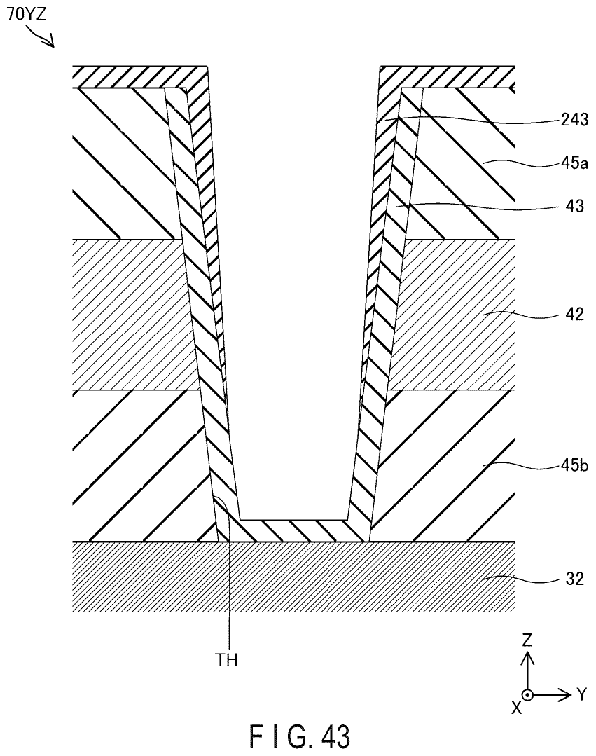

FIG. 43 to FIG. 46 are sectional views of a semiconductor device 30 according to a thirteenth example of the first embodiment. The sectional views are views of the cross-section 70YZ that is parallel to the YZ plane and included in the transistor hole TH.

As shown in FIG. 43 to FIG. 46, the thirteenth example of the manufacturing method according to the first embodiment differs from the first example of the first embodiment of the manufacturing method shown in FIG. 4, FIG. 6, FIG. 7, and FIG. 8 in that the gate protection film 243 is formed by plasma chemical vapor deposition (CVD).

As shown in FIG. 43, the gate protection film forming processing is performed. In this example, the gate protection film 243 is formed by plasma CVD so as to cover the upper surface of the gate insulating film 43. In this example, the gate protection film 243 contains SiN.

Note that, unlike the film formation by ALD shown in FIG. 4, the film thickness of the gate protection film 243 in the transistor hole TH may not be uniform in the film formation by plasma CVD. In this example, the film thickness of the gate protection film 243 is reduced as it approaches from the opening portion of the transistor hole TH to the bottom portion. The position of the lower end portion of the gate protection film 243 in the Z-axis direction is lower than the position of the conductive layer 42, but it does not reach the bottom portion of the transistor hole TH. Therefore, the gate protection film 243 is not formed at the bottom portion of the transistor hole TH. For this reason, the gate protection film etch-back processing is not performed.

The gate protection film 243 may be amorphous silicon, germanium, titanium oxide (TiO), titanium nitride (TiN), aluminum oxide (Al₂O₃), gallium oxide (GaO), zinc oxide (ZnO), or a carbon film.

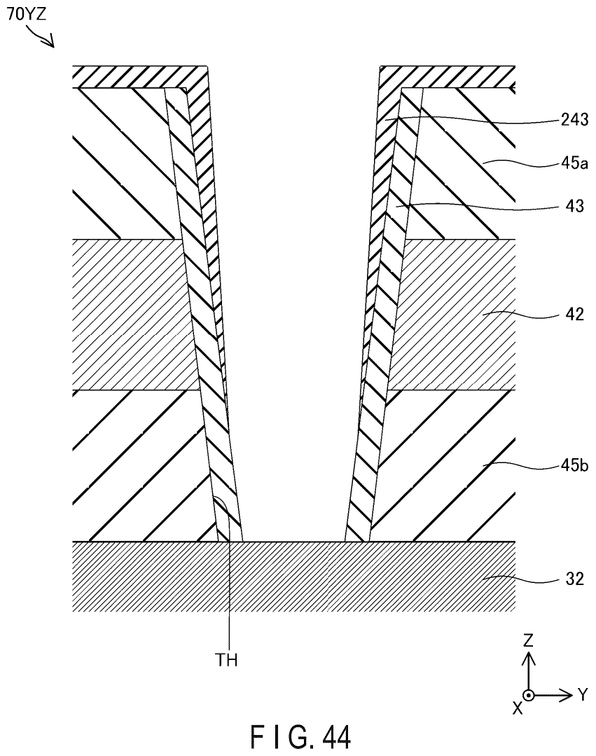

Next, as shown in FIG. 44, bottom punching processing similar to the processing shown in FIG. 6 is performed.

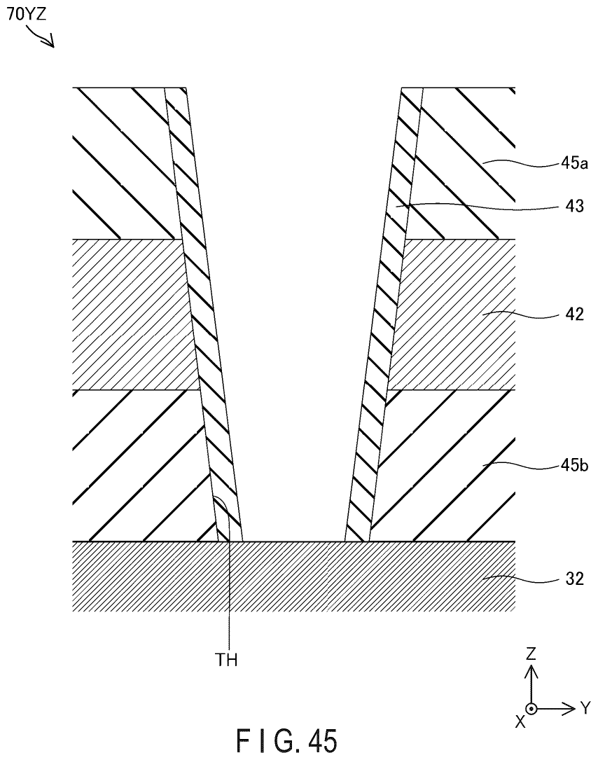

Next, as shown in FIG. 45, gate protection film peeling processing similar to the processing shown in FIG. 7 is performed.

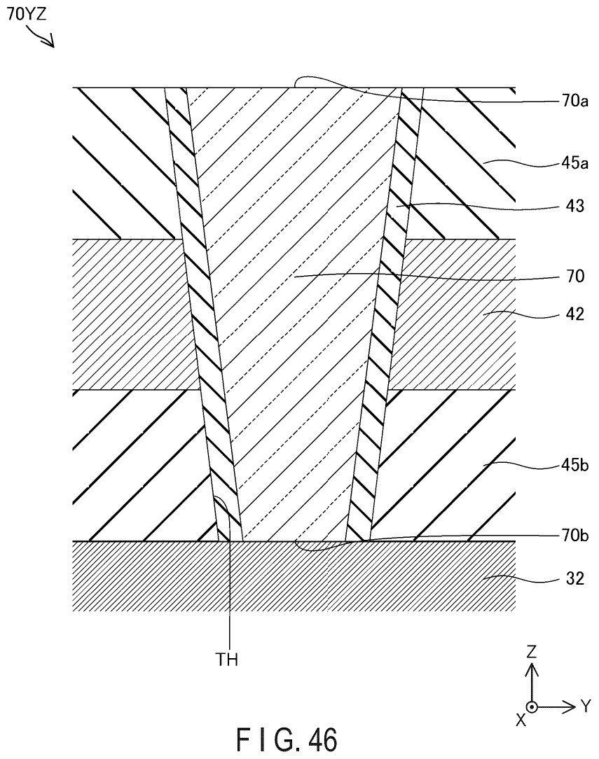

Next, as shown in FIG. 46, oxide semiconductor layer forming processing similar to the processing shown in FIG. 8 is performed.

### [Problem]

A method for manufacturing a semiconductor device 30 according to a comparative example will be hereinafter described.

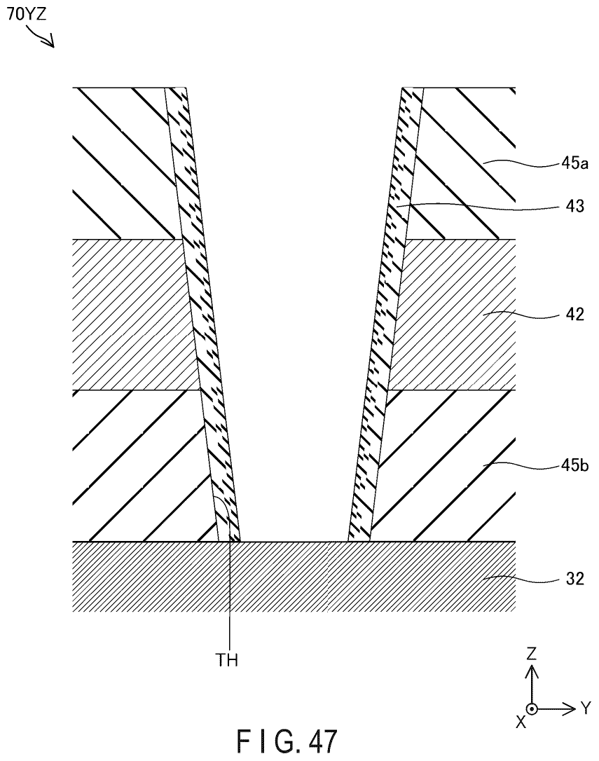

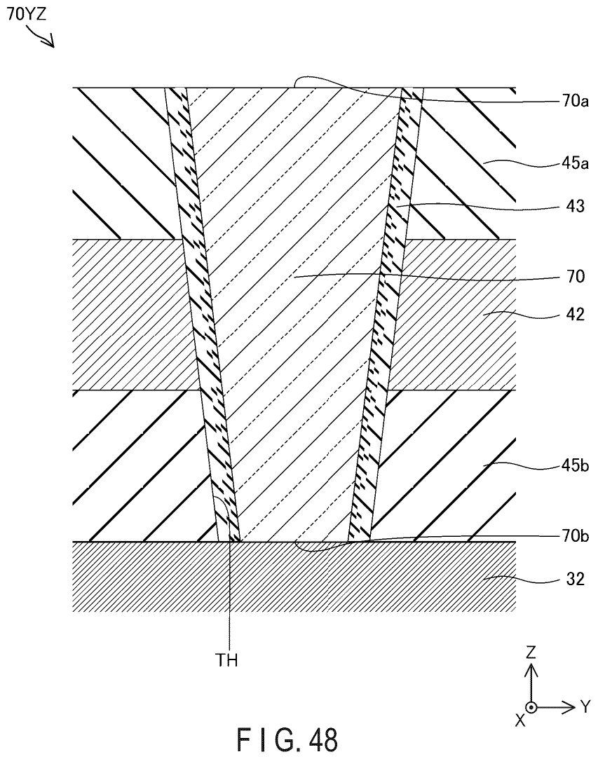

FIG. 47 and FIG. 48 are sectional views of the semiconductor device 30 according to the comparative example. The sectional views are views of a cross-section 70YZ that is parallel to the YZ plane and included in the transistor hole TH.

As shown in FIG. 47 and FIG. 48, in the comparative example of the manufacturing method, the gate protection film 243 is not formed.

For this reason, as shown in FIG. 47, when the bottom punching processing is performed after the gate insulating film 43 is formed in the transistor hole TH, ions colliding against the gate insulating film 43 due to RIE may penetrate into the gate insulating film 43 as impurities. Furthermore, since the gate insulating film 43 is exposed to etching processing, the film thickness of the gate insulating film 43 may be reduced, or scratches may be formed in the film.

Next, as shown in FIG. 48, the oxide semiconductor layer forming processing is performed. In the comparative example, when the semiconductor device 30 is operated for a long time, the electrical breakdown voltage of the gate insulating film 43 may decrease due to impurities in the gate insulating film 43, a small film thickness, or physical damage such as scratches.

### [Effect of Present Embodiment on Problem]

As shown in FIG. 6, FIG. 18, and FIG. 34, the gate insulating film 43 is physically protected by the gate protection film 243 during the bottom punching processing.

As a result, it is possible to prevent impurities from penetrating into the gate insulating film 43 and also prevent the gate insulating film 43 from being physically damaged, thereby preventing the breakdown voltage of the gate insulating film 43 from decreasing and allowing the semiconductor device 30 to operate stably for a long period of time.

### Second Embodiment

A method for manufacturing a semiconductor device 30 according to a second embodiment will be described. In the second embodiment and later, descriptions of matters common to the first embodiment will be omitted, and only differences will be described. In particular, similar actions and effects caused by similar configurations will not be mentioned in each embodiment.

The method for manufacturing the semiconductor device 30 according to the second embodiment differs from the method for manufacturing the semiconductor device 30 according to the first embodiment in that a self-assembled monolayer (hereinafter, may be referred to as a SAM) (an example of a “monolayer”) is selectively adsorbed.

### [Method for Manufacturing Semiconductor Device]

A first example of a method for manufacturing the semiconductor device 30 according to the second embodiment (hereinafter, may be referred to as a first example of the second embodiment) will be hereinafter described.

### (First Example of Second Embodiment)

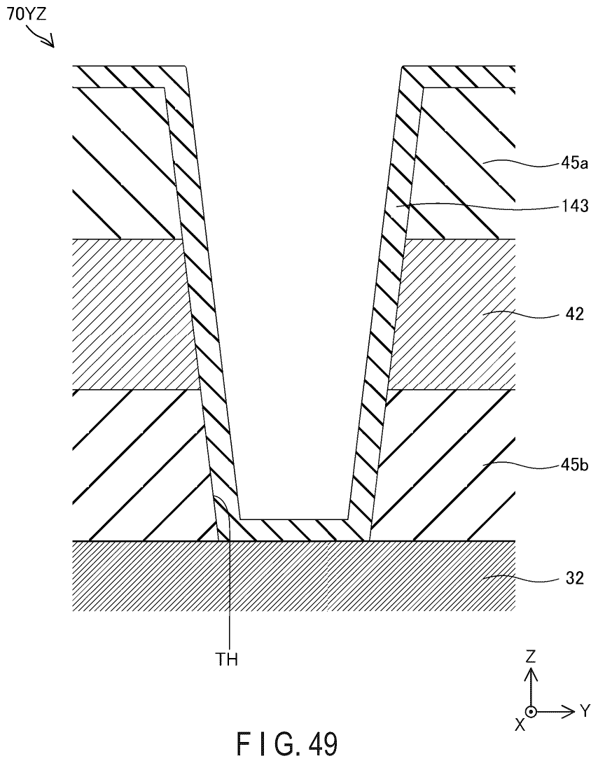

FIG. 49 to FIG. 55 are sectional views of a semiconductor device 30 according to a first example of the second embodiment. The sectional views are views of a cross-section 70YZ that is parallel to the YZ plane and included in the transistor hole TH.

First, as shown in FIG. 49, the transistor hole TH is formed. In this example, the upper surface of the lower electrode 32 serves as the bottom portion of the transistor hole TH. A sacrificial gate insulating film 143 is formed, for example, by ALD so as to cover the upper surface of the insulating film 45a and the inside of the transistor hole TH. The composition of the sacrificial gate insulating film 143 is, for example, the same as the composition of the gate insulating film 43. In other words, the sacrificial gate insulating film 143 contains silicon oxide. The composition of the sacrificial gate insulating film 143 may be different from the composition of the gate insulating film 43.

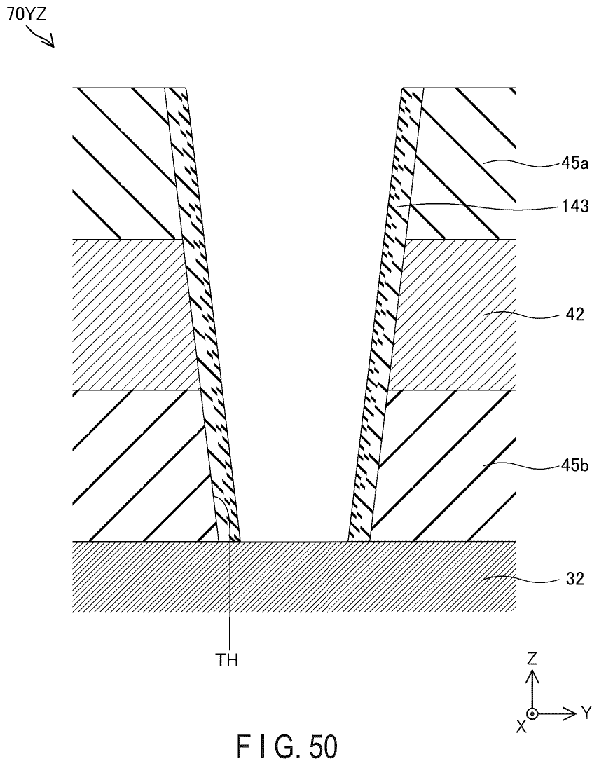

Next, as shown in FIG. 50, dry etch-back processing is performed. In this example, a part of the sacrificial gate insulating film 143 covering the lower electrode 32 is removed to expose the upper surface of the lower electrode 32. In detail, a part of the sacrificial gate insulating film 143 covering the lower electrode 32 is removed by RIE, which causes the upper surface of the insulating film 45a to be exposed. Furthermore, the lower electrode 32 is exposed at the bottom portion of the transistor hole TH. Note that RIE may cause impurities to enter the sacrificial gate insulating film 143 or may physically damage the sacrificial gate insulating film 143.

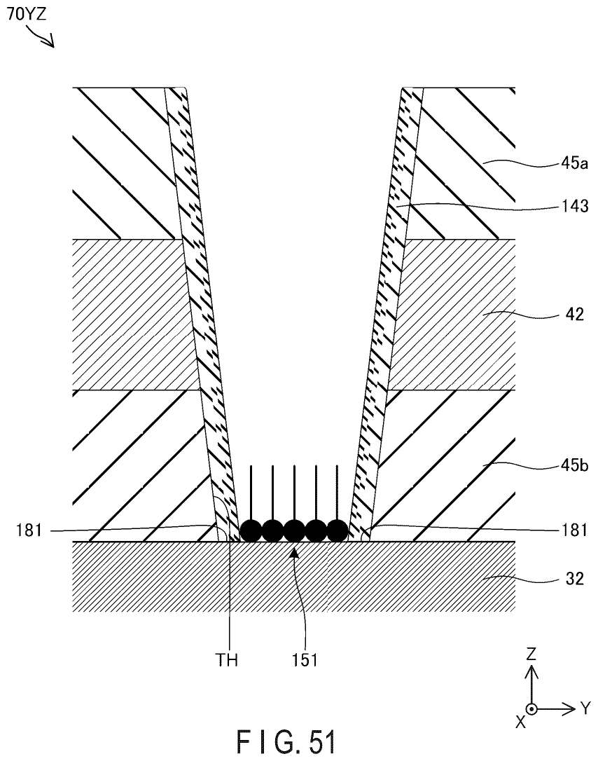

Next, as shown in FIG. 51, SAM processing is performed on metal oxide. In this example, an SAM 151 is formed on the upper surface of the exposed lower electrode 32. In detail, the SAM 151 is selectively adsorbed onto the upper surface of the lower electrode 32 exposed from the sacrificial gate insulating film 143 at the bottom portion of the transistor hole TH. The SAM 151 is not adsorbed onto the contact portion between the lower end of the sacrificial gate insulating film 143 and the lower electrode 32 (hereinafter, may be referred to as a non-adsorbed portion 181) because there is a physical obstacle. The details of the processing of causing the SAM 151 to be selectively adsorbed onto the metal oxide will be described later.

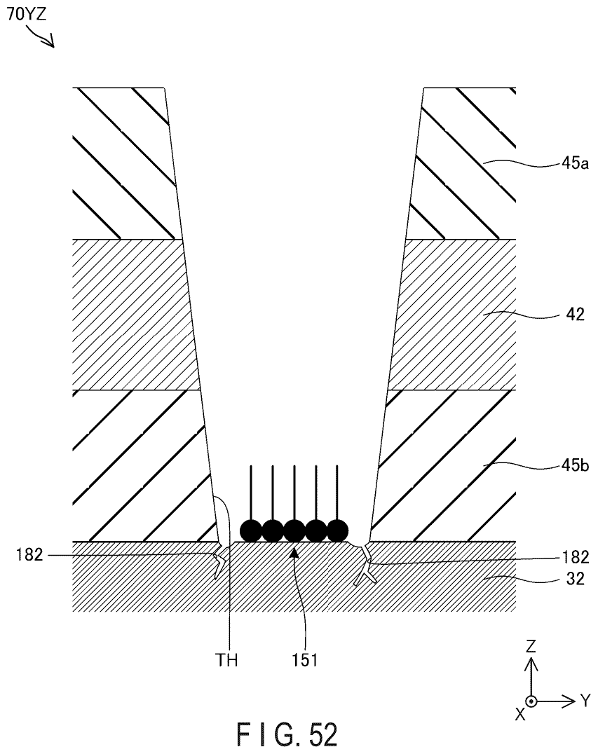

Next, as shown in FIG. 52, wet etch-back processing is performed. In this example, the sacrificial gate insulating film 143 is removed by wet etching using the HF solution or the BHF solution. A part of the lower electrode 32 covered by the SAM 151 is not removed at the bottom portion of the transistor hole TH.

On the other hand, the non-adsorbed portion 181 at the bottom portion of the transistor hole TH comes into contact with the HF solution or the BHF solution after the sacrificial gate insulating film 143 is removed. As a result, a removed portion 182 including a space extending downward from the non-adsorbed portion 181 is formed in the lower electrode 32.

For example, when the ITO contained in the lower electrode 32 is crystalline, the removed portion 182 is a grain boundary that has expanded in the lower electrode 32, and has a cracked shape. When the crystals of the ITO are pillar-shaped and aligned along a direction that intersects with the up-down direction, the size of each pillar-shaped crystal is reduced by dissolving, and the gaps formed between the crystals serve as the removed portion 182. Furthermore, for example, when the ITO contained in the lower electrode 32 is amorphous, the removed portion 182 becomes a rounded depression.

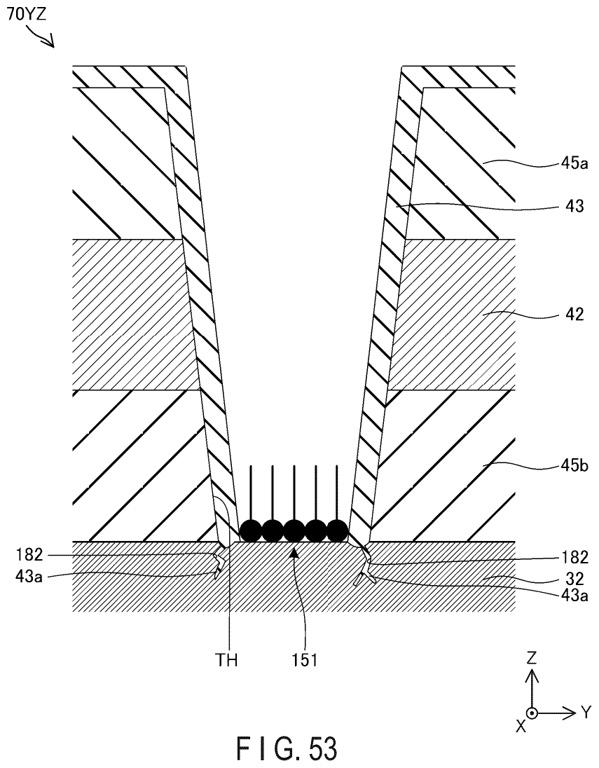

Next, as shown in FIG. 53, the gate insulating film forming processing is performed. In this example, the gate insulating film 43 is formed on a surface which is an inner surface of the transistor hole TH and is not covered with the SAM 151. In detail, the gate insulating film 43 is formed, for example by ALD so as to cover the upper surface of the insulating film 45a, the inside of the transistor hole TH except for a portion covered by the SAM 151, and the space included in the removed portion 182. The gate insulating film 43 is connected to the lower electrode 32. Hereinafter, the gate insulating film 43 formed in the space included in the removed portion 182 may be referred to as an extended insulating film 43a. The extended insulating film 43a extends downward in the lower electrode 32.

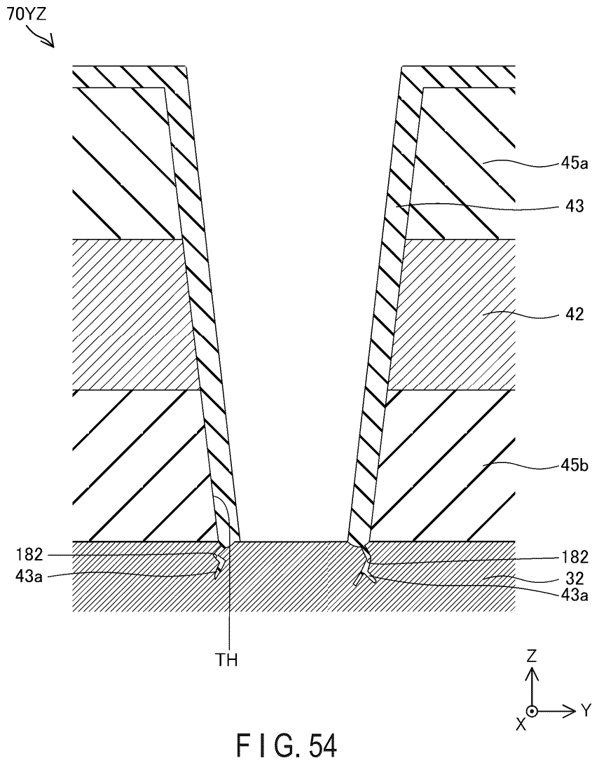

Next, as shown in FIG. 54, SAM removal processing is performed. In this example, the removal of the SAM 151 is performed without etching using gas ion collisions. Specifically, the SAM 151 is oxidized by ashing in which the SAM 151 is heated to about 200° C. in an oxygen atmosphere. As a result, the SAM 151 is removed. Note that the removal of the SAM 151 may be performed, for example, by thermally decomposing the SAM 151 with a heat treatment in which the SAM 151 is heated to 400° C. or more in a nitrogen atmosphere. Furthermore, the removal of the SAM 151 may also be performed by hydrolyzing the SAM 151 with a treatment using a strongly acidic or strongly basic chemical solution.

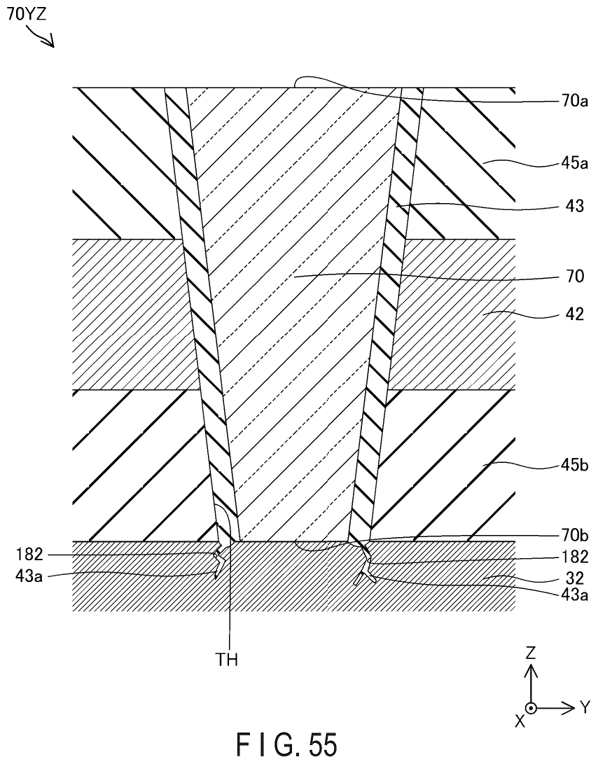

Next, as shown in FIG. 55, oxide semiconductor layer forming processing is performed. In this example, the oxide semiconductor layer 70 is formed on the upper surface of the gate insulating film 43 and the lower electrode 32 exposed at the bottom portion of the transistor hole TH. The oxide semiconductor layer 70 contacts the upper surface of the lower electrode 32 exposed at the bottom portion of the transistor hole TH. As a result, the transistor hole TH is filled with the oxide semiconductor layer 70. Then, the gate insulating film 43 and the oxide semiconductor layer 70 deposited above the insulating film 45a are chemically mechanically polished to expose the upper surface of the insulating film 45a. At this time, the surface of the upper end 70a of the oxide semiconductor layer 70 is aligned in the Z-axis direction with the upper surface of the insulating film 45a.

The details of the process of causing the SAM 151 to be selectively adsorbed onto the metal oxide shown in FIG. 51 will be described below.

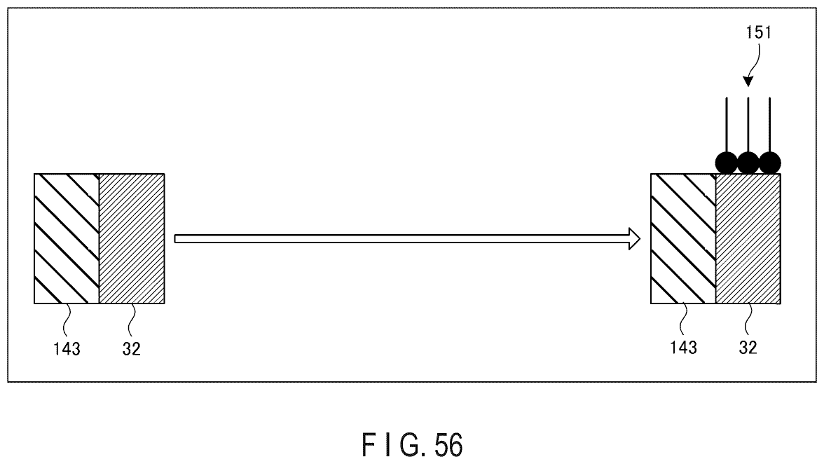

FIG. 56 is a diagram showing an example of the process of causing the SAM 151 to be selectively adsorbed onto the lower electrode 32 when the sacrificial gate insulating film 143 and the lower electrode 32 are exposed.

As shown in FIG. 56, the SAM 151 is first supplied to the sacrificial gate insulating film 143 and the lower electrode 32. The SAM 151 may be liquid or gas. The SAM 151 is, for example, a phosphonic-acid-based compound, a phosphate-based compound, or an amine-based compound.

The phosphonic-acid-based compound includes, for example, compounds in which phosphonic acid is bonded to an alkyl group having 3 to 30 carbon atoms. The alkyl group is not limited to a structure which partially includes a linear hydrocarbon, and may have a structure in which it is partially substituted with other elements.

The phosphate-based compound includes, for example, compounds in which phosphoric acid is bonded to an alkyl group with 3 to 30 carbon atoms and an ester bond. The alkyl group is not limited to a structure which partially includes a linear hydrocarbon, and may have a structure in which it is partially substituted with other elements.

The amine-based compound includes, for example, compounds each having an alkyl group with 3 to 30 carbon atoms and an amine bond. The alkyl group is not limited to a structure which partially includes a linear hydrocarbon, and may have a structure in which it is partially substituted with other elements.

The SAM 151 is selectively adsorbed onto the lower electrode 32 without being adsorbed onto the sacrificial gate insulating film 143. As a result, the surface of the lower electrode 32 is not exposed.

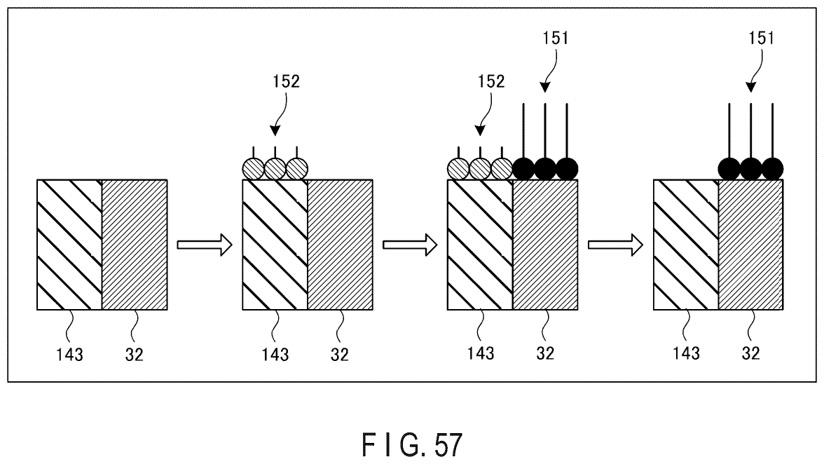

FIG. 57 is a diagram showing another example of the process for causing the SAM 151 to be selectively adsorbed onto the lower electrode 32 when the sacrificial gate insulating film 143 and the lower electrode 32 are exposed.

As shown in FIG. 57, first, an SAM 152 is supplied to the sacrificial gate insulating film 143 and the lower electrode 32. The SAM 152 may be liquid or gas. The SAM 152 is, for example, an organic silane-based compound or an alcohol-based compound.

The organic silane-based compound includes, for example, compounds each having an alkyl group with 3 to 30 carbon atoms and an Si—C bond. The alkyl group is not limited to a structure which partially includes a linear hydrocarbon, and may have a structure in which it is partially substituted with other elements.

The alcohol-based compound includes, for example, compounds each having an alkyl group with 5 to 30 carbon atoms and an alcohol group. The alkyl group is not limited to a structure which partially includes a linear hydrocarbon, and may have a structure in which it is partially substituted with other elements.

The SAM 152 is selectively adsorbed onto the sacrificial gate insulating film 143 without being adsorbed onto the lower electrode 32. As a result, the surface of the sacrificial gate insulating film 143 is not exposed.

Next, the SAM 151 is supplied. In this example, the SAM 151 is, for example, a phosphonic-acid-based compound, a phosphate-based compound, an amine-based compound, or an organic silane-based compound. Since the surface of the sacrificial gate insulating film 143 is not exposed, the SAM 151 is selectively adsorbed onto the lower electrode 32. For example, the adsorption force of the SAM 152 to the sacrificial gate insulating film 143 is weaker than the adsorption force of the SAM 151 to the lower electrode 32.

Next, the temperature of the sacrificial gate insulating film 143 and the lower electrode 32 is increased by a heat treatment. As a result, the SAM 152 which has a weak adsorption force to the sacrificial gate insulating film 143 is removed from the surface of the sacrificial gate insulating film 143. On the other hand, the SAM 151 remains on the surface of the lower electrode 32.

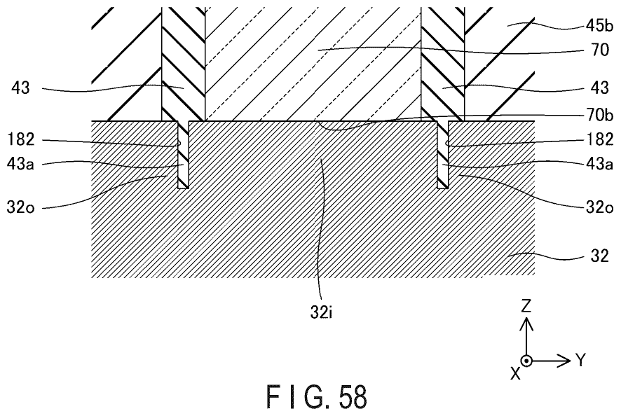

FIG. 58 is a diagram showing the effect of the extended insulating film 43a. As shown in FIG. 58, the extended insulating film 43a is formed on the lower electrode 32 so as to extend downward from the lower end portion of a part of the gate insulating film 43 surrounding the oxide semiconductor layer 70 (see FIG. 53).

Since the extended insulating film 43a is continuous with the gate insulating film 43 above the lower electrode 32, the extended insulating film 43a divides the lower electrode 32 into a lower electrode 32i and a lower electrode 320. Here, the extended insulating film 43a is not located between the oxide semiconductor layer 70 and the lower electrode 32i. On the other hand, the extended insulating film 43a is located between the oxide semiconductor layer 70 and the lower electrode 320.

The carriers of IGZO contained in the oxide semiconductor layer 70 are oxygen deficiencies (hereinafter, may be referred to as Vo). The concentration of Vo in the oxide semiconductor layer 70 is approximately 10¹⁷ to 10¹⁸ atm/cm³. On the other hand, the concentration of Vo in ITO contained in the lower electrode 32 is approximately 10¹⁹ to 10²¹ atm/cm³.

When the concentration of Vo contained in the oxide semiconductor layer 70 changes, the characteristics of the semiconductor device 30 change, so that it is desirable to prevent the movement of Vo from the lower electrode 32 to the oxide semiconductor layer 70.

By reducing the contact area between the oxide semiconductor layer 70 and the lower electrode 32, it is possible to prevent the movement of Vo from the lower electrode 32 to the oxide semiconductor layer 70. However, this increases the contact resistance between the oxide semiconductor layer 70 and the lower electrode 32, which is not preferable.

In contrast, in the semiconductor device 30 according to the first example of the second embodiment, the extended insulating film 43a is provided, which prevents the movement of Vo from the lower electrode 320 to the oxide semiconductor layer 70. As a result, it is possible to prevent changes in the characteristics of the semiconductor device 30.

Furthermore, by the configuration that the extended insulating film 43a extends downward from a lower end portion of a part of the gate insulating film 43 surrounding the oxide semiconductor layer 70, it is possible to provide the extended insulating film 43a without reducing the contact area between the oxide semiconductor layer 70 and the lower electrode 32. This makes it possible to prevent an increase in the contact resistance between the oxide semiconductor layer 70 and the lower electrode 32.

The extended insulating film 43a is formed in the space included in the removed portion 182 extending downward from the non-adsorbed portion 181 which is the connection portion between the sacrificial gate insulating film 143 and the lower electrode 32. The gate insulating film 43 is provided at the position where the sacrificial gate insulating film 143 was provided. Therefore, even if the formation position of the sacrificial gate insulating film 143 deviates from a design value because the formation position of the transistor hole TH deviates from a design value, the extended insulating film 43a and the gate insulating film 43 are formed to be likewise deviated in the same manner, that is, they are continuous with each other, so that the above-mentioned effect can be achieved.

A second example of the manufacturing method of the semiconductor device 30 according to the second embodiment (hereinafter, may be referred to as a second example of the second embodiment) will be hereinafter described.

### (Second Example of First Embodiment)

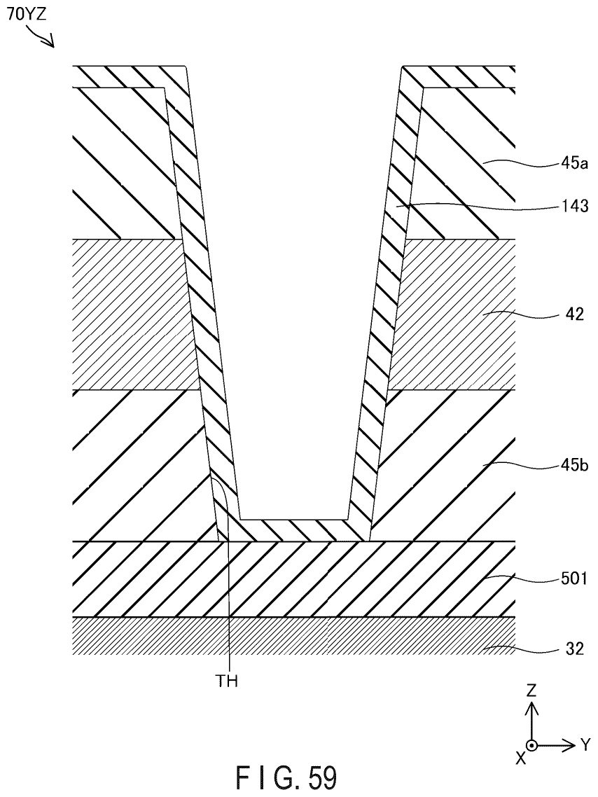

FIG. 59 to FIG. 66 are sectional views of a semiconductor device 30 according to a second example of the second embodiment. The sectional views are views of a cross-section 70YZ that is parallel to the YZ plane and included in the transistor hole TH.

As shown in FIG. 59 to FIG. 66, the second example of the second embodiment of the manufacturing method differs from the first example of the second embodiment of the manufacturing method shown in FIG. 49 to FIG. 55 in that the stopper film 501 is provided above the lower electrode 32.

First, as shown in FIG. 59, the transistor hole TH is formed. In this example, the upper surface of the stopper film 501 serves as the bottom portion of the transistor hole TH. The sacrificial gate insulating film 143 is formed, for example, by ALD so as to cover the upper surface of the insulating film 45a and the inside of the transistor hole TH.

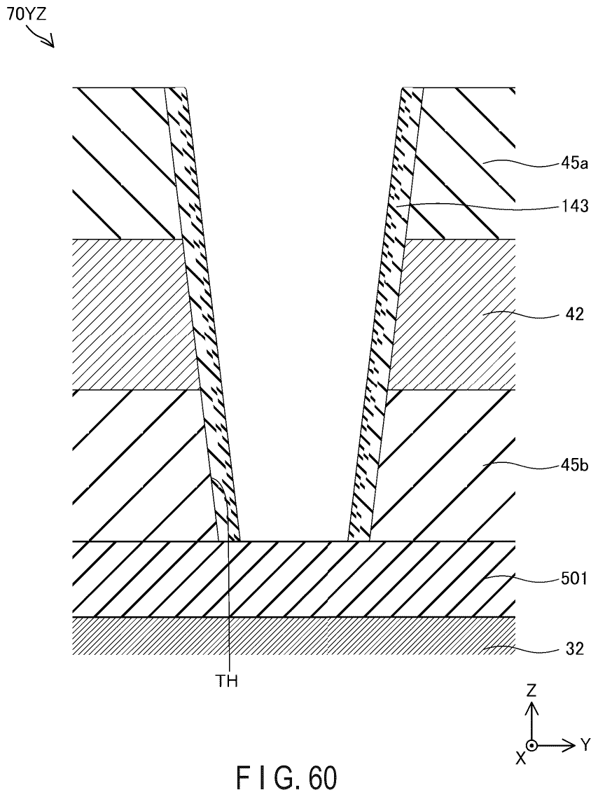

Next, as shown in FIG. 60, dry etch-back processing similar to the processing shown in FIG. 50 is performed.

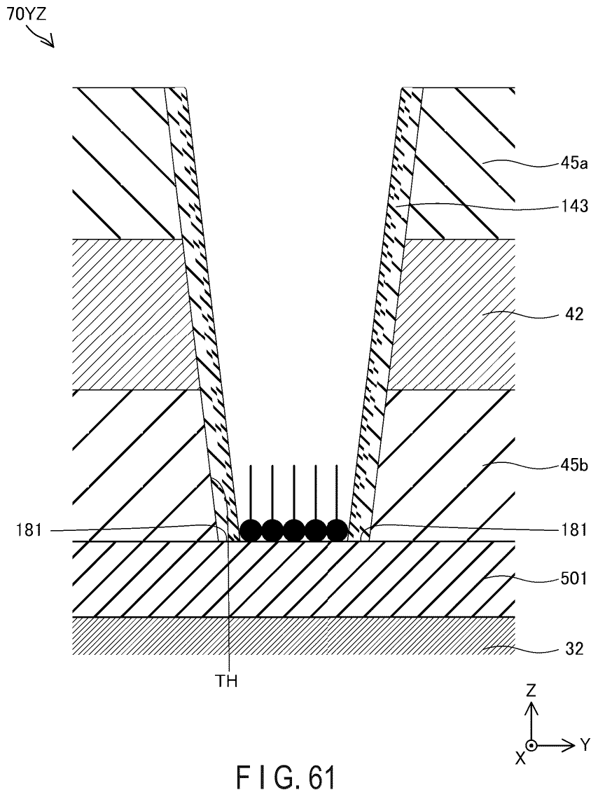

Next, as shown in FIG. 61, SAM processing for metal oxide which is similar to the processing shown in FIG. 51 is performed.

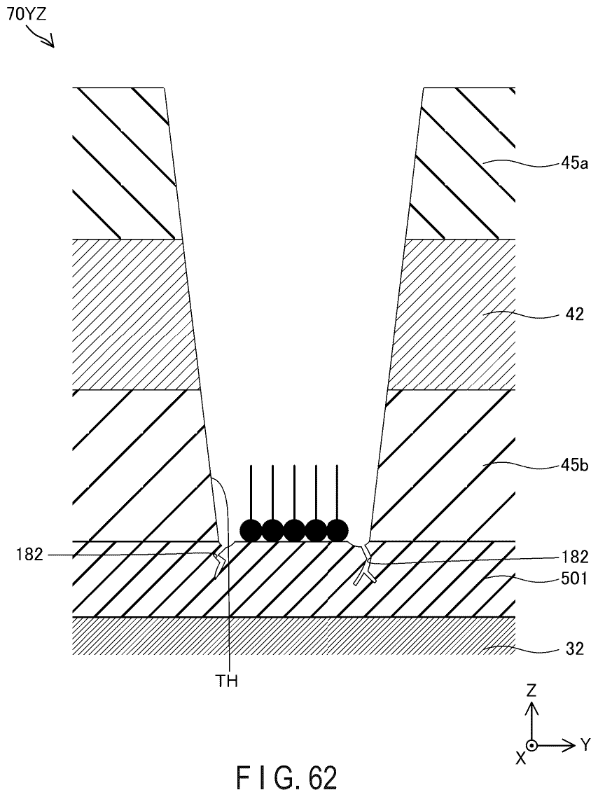

Next, as shown in FIG. 62, wet etch-back processing similar to the processing shown in FIG. 52 is performed.

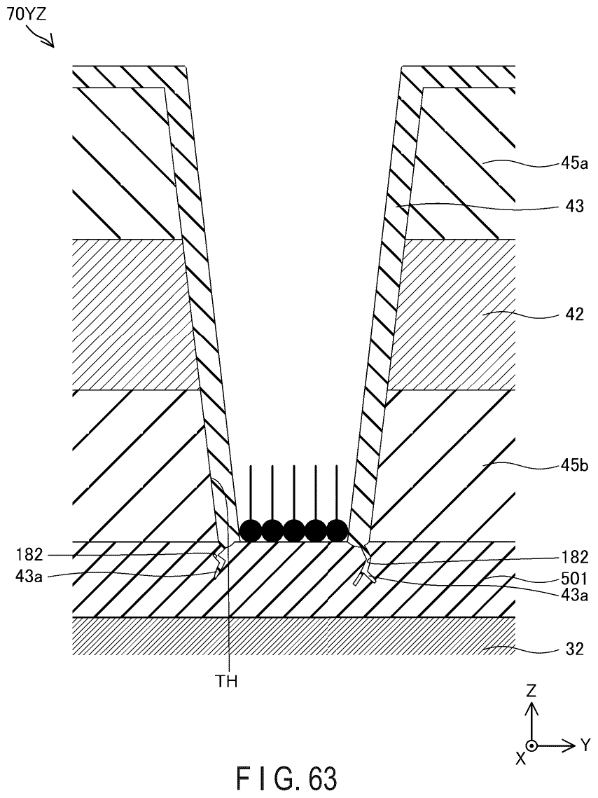

Next, as shown in FIG. 63, gate insulating film forming processing similar to the processing shown in FIG. 53 is performed.

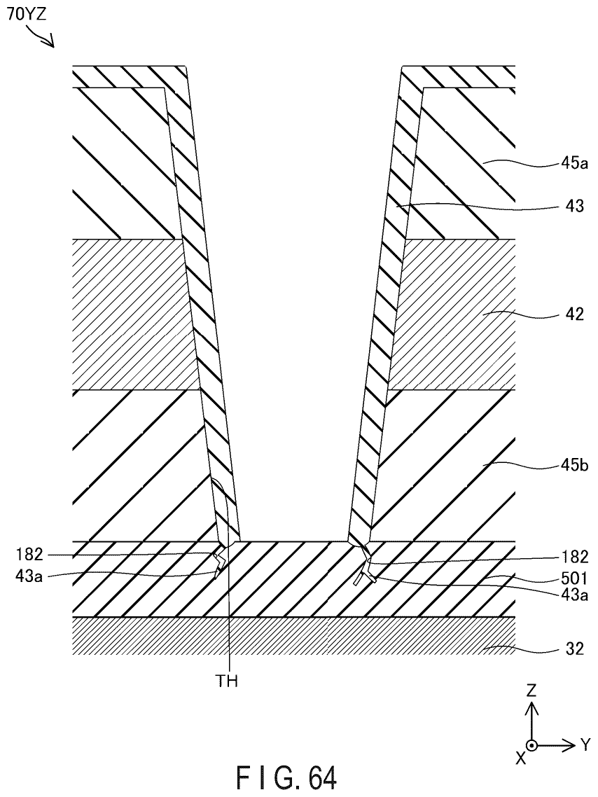

Next, as shown in FIG. 64, SAM removal processing similar to the processing shown in FIG. 54 is performed.

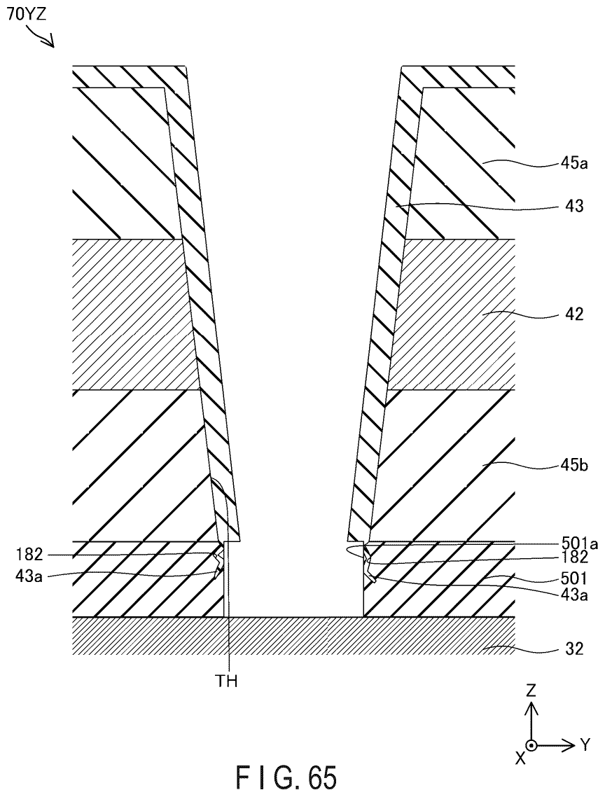

Next, as shown in FIG. 65, an alkaline treatment using warm water is performed. In this example, a part of the stopper film 501 is removed through the bottom portion of the transistor hole TH by wet etching using alkaline warm water. As a result, the hole portion 501a penetrating through the stopper film 501 in the up-down direction is formed in the stopper film 501. The upper surface of the lower electrode 32 is exposed through the hole portion 501a.

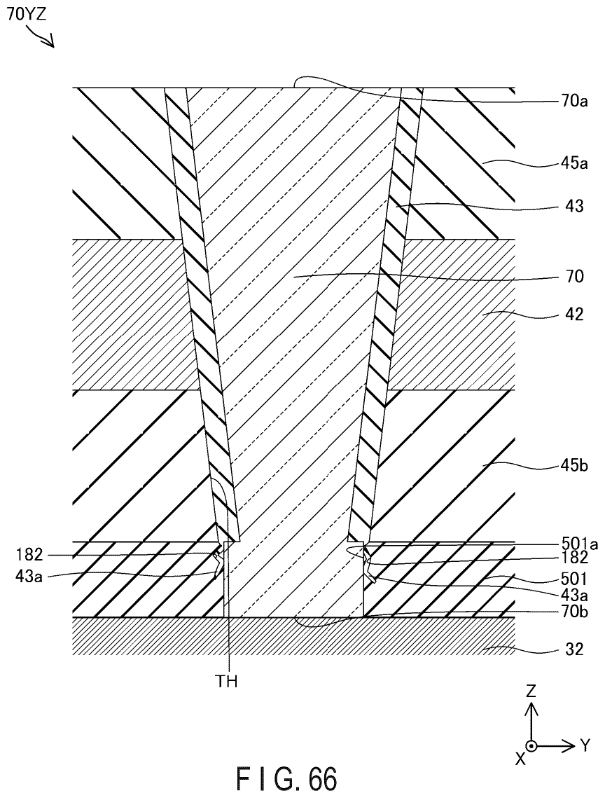

Next, as shown in FIG. 66, oxide semiconductor layer forming processing similar to the processing shown in FIG. 55 is performed.

Furthermore, the stopper film 601 may be provided instead of the stopper film 501.

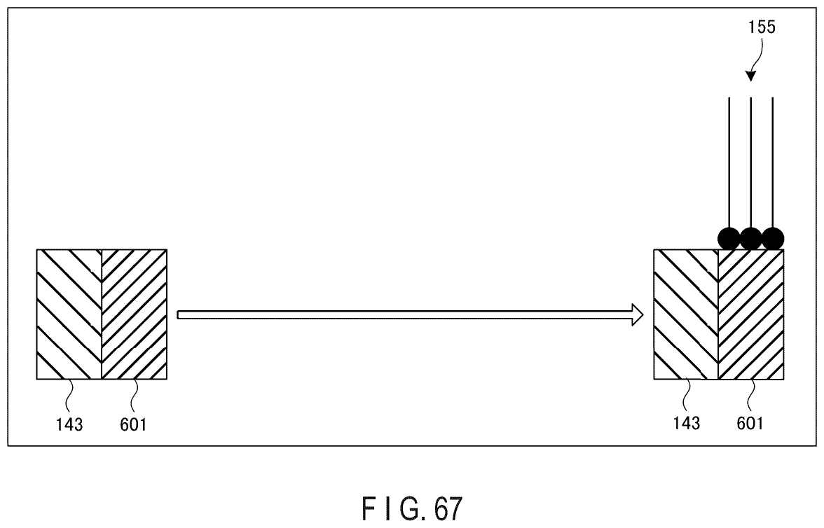

FIG. 67 is a diagram showing an example of the processing for causing an SAM 155 to be selectively adsorbed onto the stopper film 601 when the sacrificial gate insulating film 143 and the stopper film 601 are exposed.

As shown in FIG. 67, first, the SAM 155 is supplied to the sacrificial gate insulating film 143 and the stopper film 601. The SAM 155 may be liquid or gas. The SAM 155 includes, for example, an alkyl-bromide-based compound or an unsaturated-hydrocarbon-based compound.

The alkyl-bromide-based compound includes, for example, Br-R. Here, R represents a compound having an alkyl group with 5 to 30 carbon atoms. The alkyl group is not limited to a structure which partially includes a linear hydrocarbon, and may have a structure in which it is partially substituted with other elements.

The unsaturated-hydrocarbon-based compound is, for example, a compound having a C—C double bond or triple bond which is classified as an alkene or alkyne having 5 to 30 carbon atoms. The compound is mainly composed of carbon and hydrogen, but may have an ether bond in addition to the C—C double or triple bond, or some of the hydrogen may be replaced by fluorine, chlorine, bromine, or iodine.

The SAM 155 is selectively adsorbed onto the stopper film 601 without being adsorbed onto the sacrificial gate insulating film 143. As a result, the surface of the stopper film 601 is not exposed.

A third example of the manufacturing method for the semiconductor device 30 according to the second embodiment (hereinafter, may be referred to as a third example of the second embodiment) will be described below.

### (Third Example of Second Embodiment)

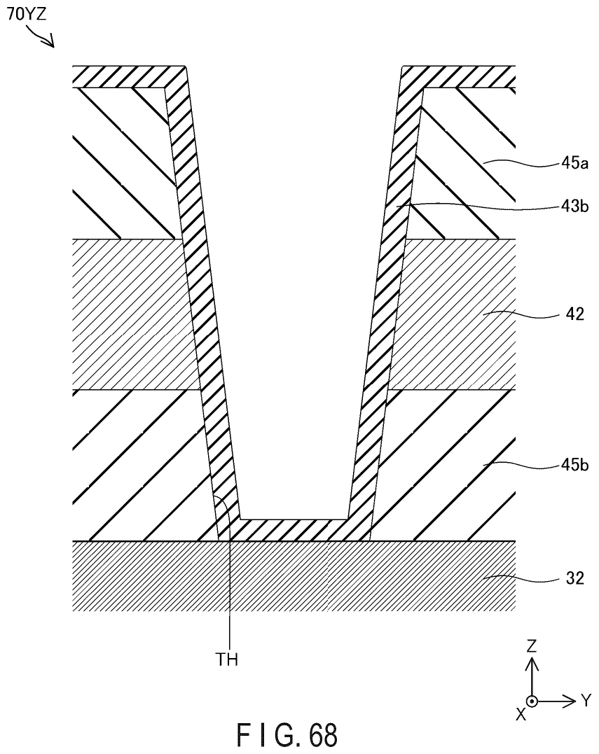

FIG. 68 to FIG. 75 are sectional views of a semiconductor device 30 according to a third example of the second embodiment. The sectional views are views of a cross-section 70YZ that is parallel to the YZ plane and included in a transistor hole TH.

As shown in FIG. 68 to FIG. 75, the third example of the second embodiment of the manufacturing method differs from the first example of the second embodiment of the manufacturing method shown in FIG. 49 to FIG. 55 in that the sacrificial gate insulating film 143 is not replaced by the gate insulating film 43.

First, as shown in FIG. 68, the transistor hole TH is formed. In this example, the upper surface of the lower electrode 32 serves as the bottom portion of the transistor hole TH. Then, the gate insulating film 43b is formed, for example, by ALD so as to cover the upper surface of the insulating film 45a and the inside of the transistor hole TH. The gate insulating film 43b contains, for example, silicon and nitrogen. In this example, the gate insulating film 43b contains SiN. Furthermore, a stopper film 501, 601, or 701 may be provided between the lower electrode 32 and the insulating film 45b. In this case, the upper surface of the stopper film 501, 601, or 701 serves as the bottom portion of the transistor hole TH.

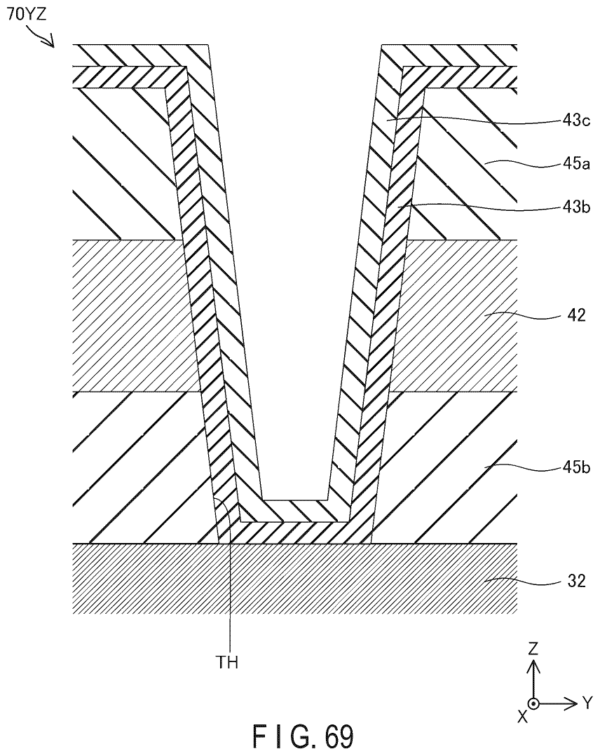

Next, as shown in FIG. 69, gate insulating film forming processing is performed. In this example, the gate insulating film 43c is formed by ALD so as to cover the upper surface of the gate insulating film 43b. In this example, the gate insulating film 43c contains SiO.

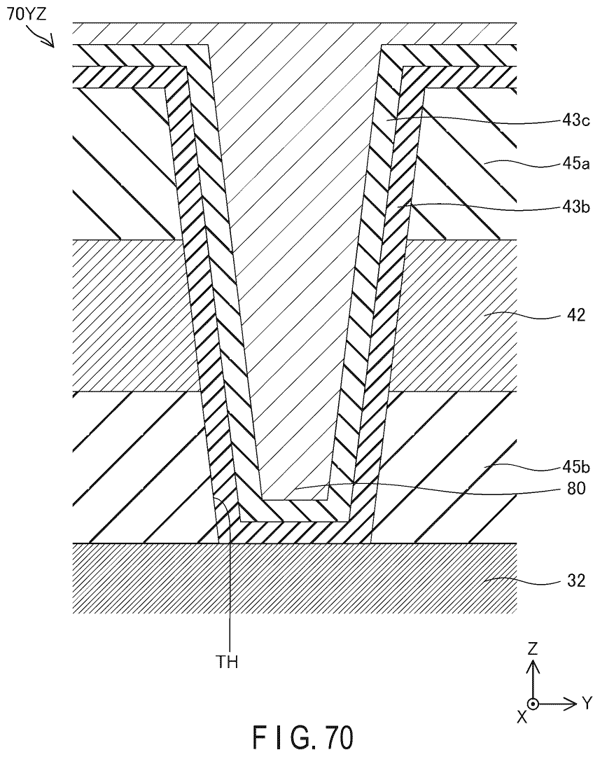

Next, as shown in FIG. 70, sacrificial film forming processing is performed. In this example, a sacrificial film 80 is formed by ALD so as to cover the upper surface of the gate insulating film 43c and fill the transistor hole TH. In this example, the sacrificial film 80 contains TiN. Note that the sacrificial film 80 may contain zinc oxide (ZnO), aluminum oxide (Al₂O₃), IGZO, titanium nitride (TiN), molybdenum (Mo), or the like.

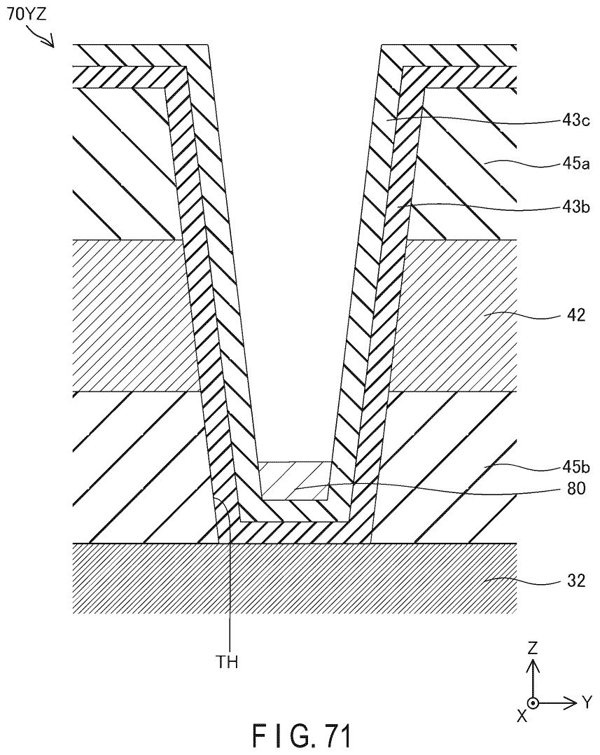

Next, as shown in FIG. 71, sacrificial film etch-back processing is performed. In this example, a part of the sacrificial film 80 is removed by wet etching. This leaves the sacrificial film 80 below the transistor hole TH. The gate insulating film 43c is exposed on the side surface of the transistor hole TH.

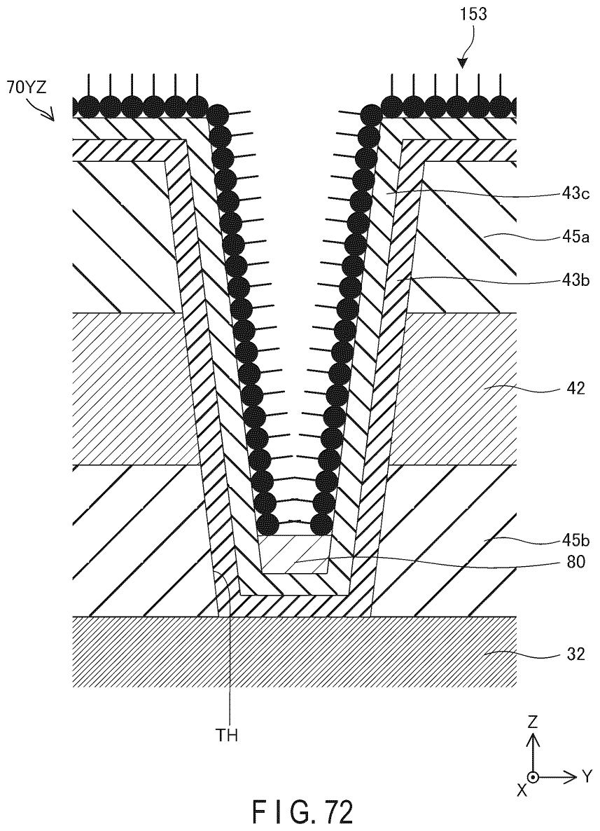

Next, as shown in FIG. 72, SAM processing is performed on silicon oxide. In this example, an SAM 153 is selectively adsorbed onto the surface of the gate insulating film 43c that is exposed above the gate insulating film 43c and inside the transistor hole TH. The SAM 153 is not adsorbed onto the sacrificial film 80 located below the transistor hole TH. The SAM 153 contains, for example, an organic-silane-based compound or an alcohol-based compound.

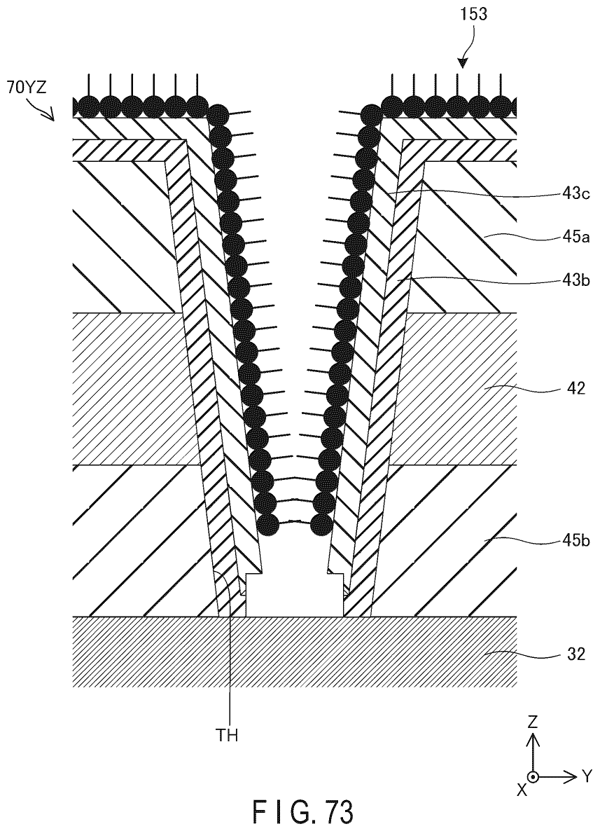

Next, as shown in FIG. 73, bottom punching processing is performed. In this example, the sacrificial film 80 remaining below the transistor hole TH is removed by wet etching using heated hydrogen peroxide (H₂O₂) solution, ozone, a solution in which ozone and carbon dioxide are dissolved (hereinafter, may be referred to as O3W), or a solution in which an acidic chemical is added to O3W, such as ozone-added hydrochloric acid or a dilute HF (dilute hydrogen fluoride) solution (hereinafter, may be referred to as a DHF solution). Then, a part of the gate insulating film 43c and a part of the gate insulating film 43b that are exposed by removing the sacrificial film 80 and cover the bottom portion of the transistor hole TH are removed. As a result, the upper surface of the lower electrode 32 is exposed at the bottom portion of the transistor hole TH.

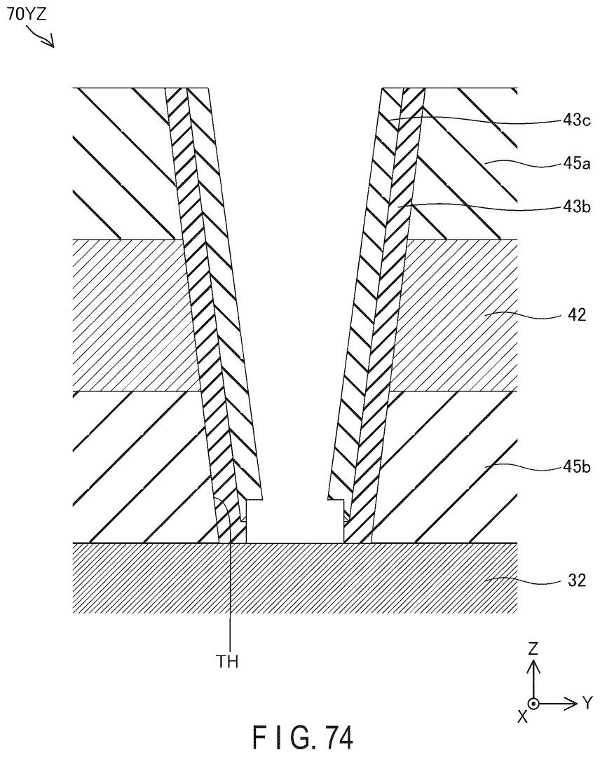

Next, as shown in FIG. 74, SAM removal processing is performed. In this example, the SAM 153 is oxidized by ashing or oxidation processing using oxygen. As a result, the SAM 153 is removed.

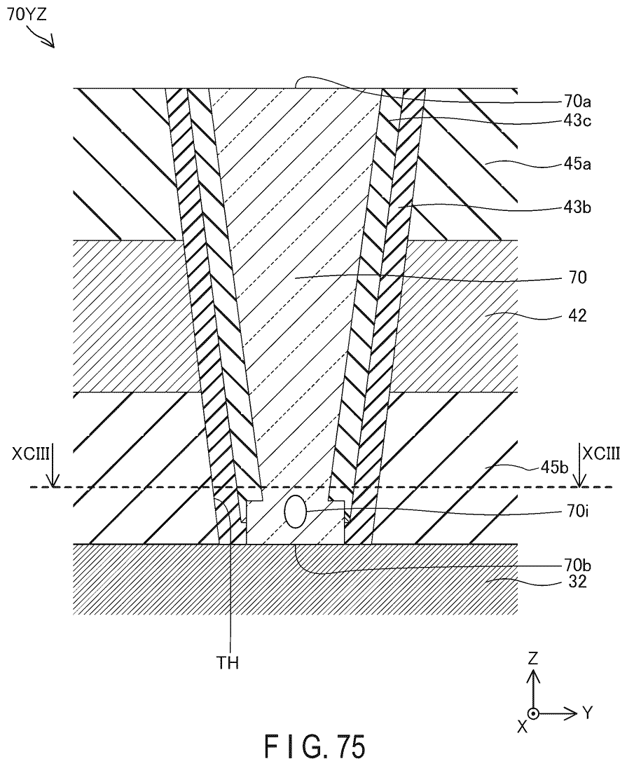

Next, as shown in FIG. 75, oxide semiconductor layer forming processing similar to the processing shown in FIG. 66 is performed. In this example, a void 70i that is not filled with the oxide semiconductor layer 70 is formed inside the oxide semiconductor layer 70.

A fourth example of the manufacturing method for the semiconductor device 30 according to the second embodiment (hereinafter, may be referred to as a fourth example of the second embodiment) will be described below.

### (Fourth Example of Second Embodiment)

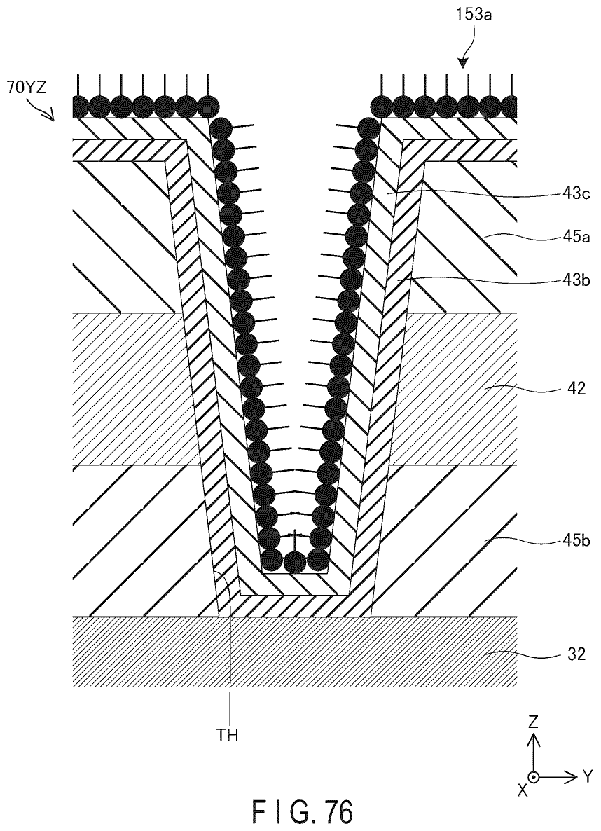

FIG. 76 to FIG. 79 are sectional views of a semiconductor device 30 according to a fourth example of the second embodiment. The sectional views are views of a cross-section 70YZ that is parallel to the YZ plane and included in the transistor hole TH.

As shown in FIG. 76 to FIG. 79, the fourth example of the second embodiment of the manufacturing method differs from the third example of the second embodiment of the manufacturing method shown in FIG. 68 to FIG. 75 in that the method for forming the sacrificial film differs.

First, although not shown, processing for forming the gate insulating film 43b (see FIG. 68) and processing for forming the gate insulating film 43c (see FIG. 69) are performed.

Next, as shown in FIG. 76, SAM processing is performed on silicon oxide. In this example, an SAM 153a is selectively adsorbed on the surface of the gate insulating film 43c that is exposed above the gate insulating film 43c and inside the transistor hole TH. The SAM 153a is, for example, an organic-silane-based compound or an alcohol-based compound. In this example, the composition of the SAM 153a is the same as the composition of the SAM 153 shown in FIG. 72.

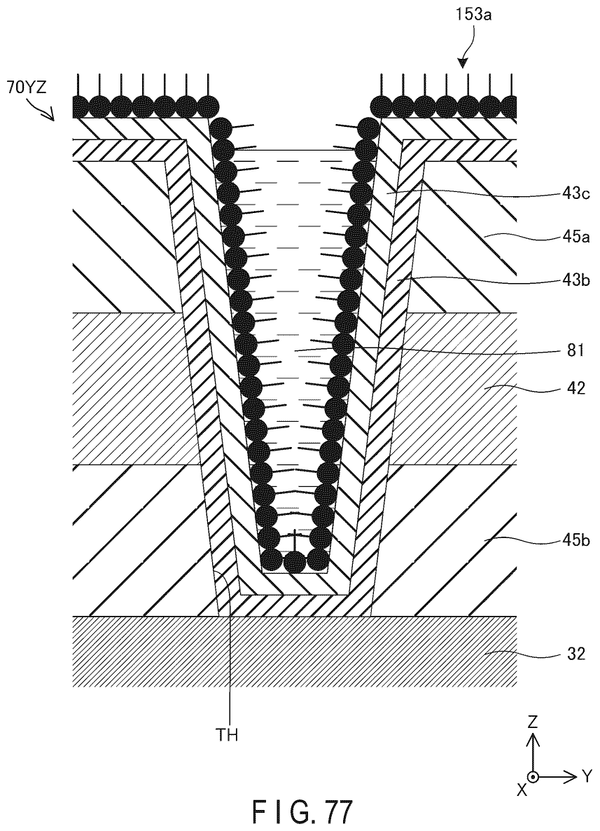

Next, as shown in FIG. 77, precursor coating processing is performed. In this example, a precursor 81 is coated to the inside of the transistor hole TH by a sol-gel method. The precursor 81 is, for example, an alcohol solution containing an organometallic compound. Specifically, the precursor 81 is a methanol or ethanol solution containing zinc acetate, or an aqueous solution thereof.

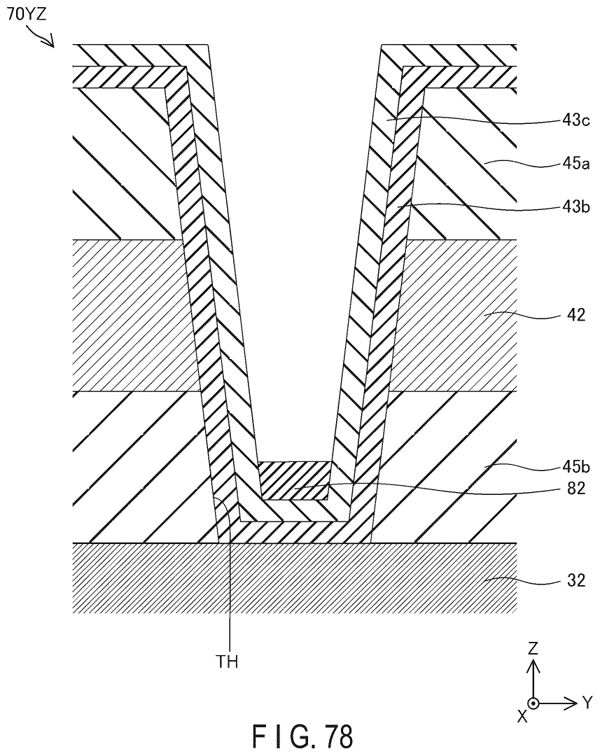

Next, as shown in FIG. 78, SAM removal processing and solvent removal processing are performed. In this example, the SAM 153 and the precursor 81 are heated to 200° C. or more to remove the SAM 153 and the alcohol solution contained in the precursor 81. The organic metal compound contained in the precursor 81 is then transformed into a sacrificial film 82. The sacrificial film 82 contains, for example, metal oxide or hydroxide.

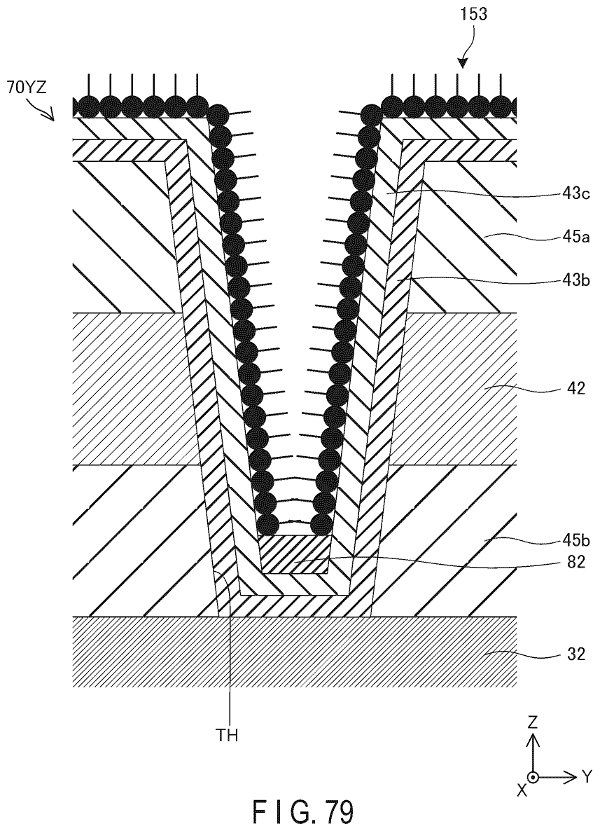

Next, as shown in FIG. 79, SAM processing for silicon oxide that is similar to the processing shown in FIG. 72 is performed. In this example, the SAM 153 is selectively adsorbed onto the surface of the gate insulating film 43c that is exposed above the gate insulating film 43c and inside the transistor hole TH. The SAM 153 is not adsorbed onto the sacrificial film 82 located below the transistor hole TH.

Next, although not shown, bottom punching processing (see FIG. 73), SAM removal processing (see FIG. 74), and oxide semiconductor layer forming processing (see FIG. 75) are performed.

A fifth example of the manufacturing method for the semiconductor device 30 according to the second embodiment (hereinafter, may be referred to as a fifth example of the second embodiment) will be hereinafter described.

### (Fifth Example of First Embodiment)

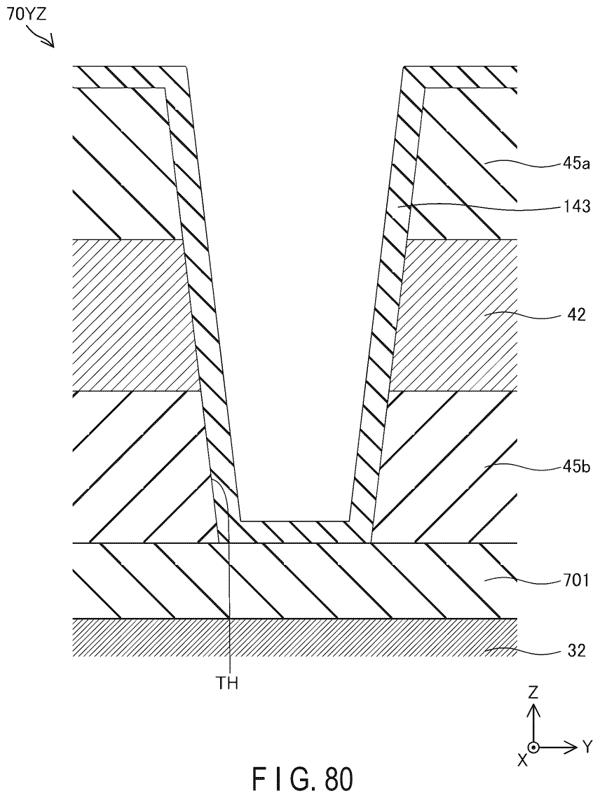

FIG. 80 to FIG. 90 are sectional views of a semiconductor device 30 according to a fifth example of the second embodiment. The sectional views are views of a cross-section 70YZ that is parallel to the YZ plane and included in a transistor hole TH.

As shown in FIG. 80 to FIG. 90, the fifth example of the second embodiment of the manufacturing method differs from the second example of the second embodiment of the manufacturing method shown in FIG. 59 to FIG. 66 in that the stopper film 701 (an example of the “first layer” and the “first insulating film”) is provided instead of the stopper film 501 above the lower electrode 32.

The stopper film 701 contains, for example, silicon and oxygen. In this example, the stopper film 701 contains silicon oxide (SiO). The stopper film 701 is, for example, a thermal oxide film.

First, as shown in FIG. 80, the transistor hole TH is formed. In this example, the upper surface of the stopper film 701 serves as the bottom portion of the transistor hole TH. Then, the sacrificial gate insulating film 143 is formed, for example, by ALD so as to cover the upper surface of the insulating film 45a and the inside of the transistor hole TH.

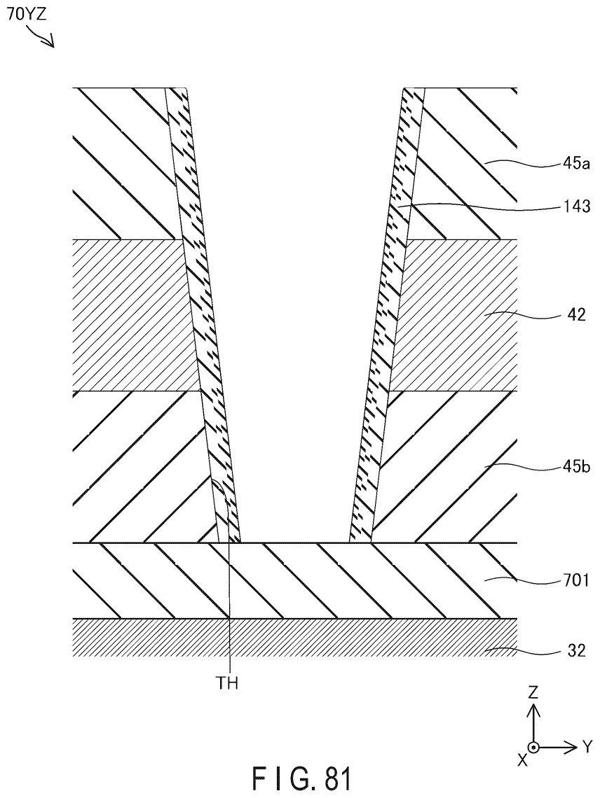

Next, as shown in FIG. 81, dry etch-back processing similar to the processing shown in FIG. 50 is performed.

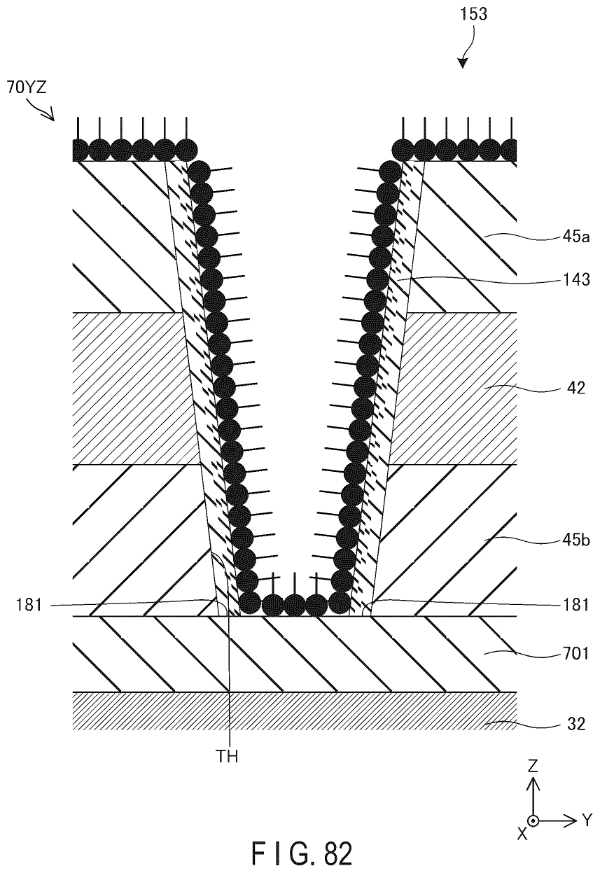

Next, as shown in FIG. 82, SAM processing is performed on silicon oxide. In this example, the SAM 153 is selectively adsorbed onto the upper surface of the insulating film 45a and the surfaces of the sacrificial gate insulating film 143 and the stopper film 701 that are exposed inside the transistor hole TH.

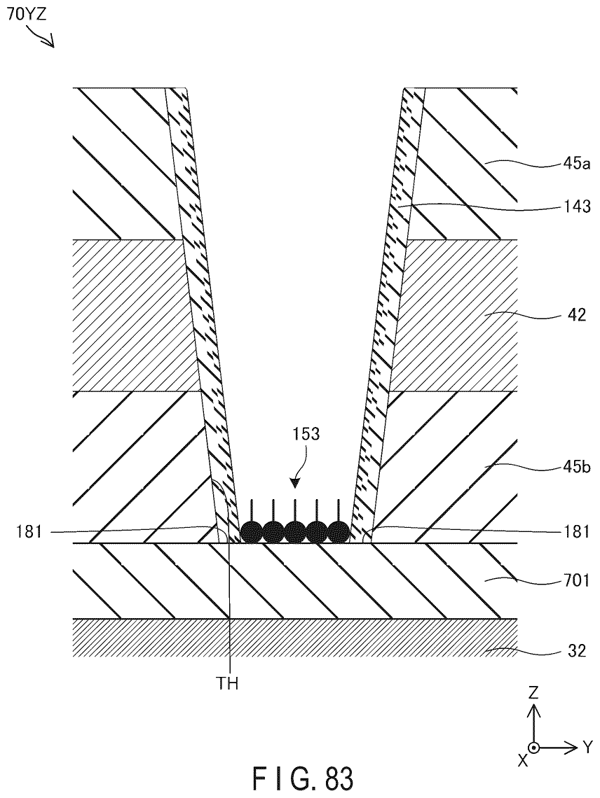

Next, as shown in FIG. 83, first selective SAM removal processing is performed. In this example, the SAM 153 which has been adsorbed on the upper surface of the insulating film 45a and the sacrificial gate insulating film 143 is removed. On the other hand, the SAM 153 which has been adsorbed on the stopper film 701 remains. Details of the first selective SAM removal processing will be described later.

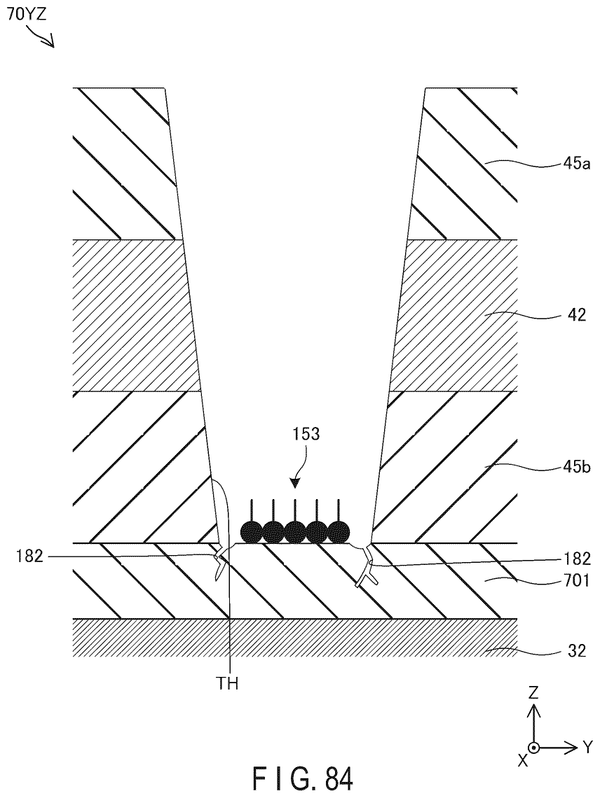

Next, as shown in FIG. 84, wet etch-back processing similar to the processing shown in FIG. 52 is performed.

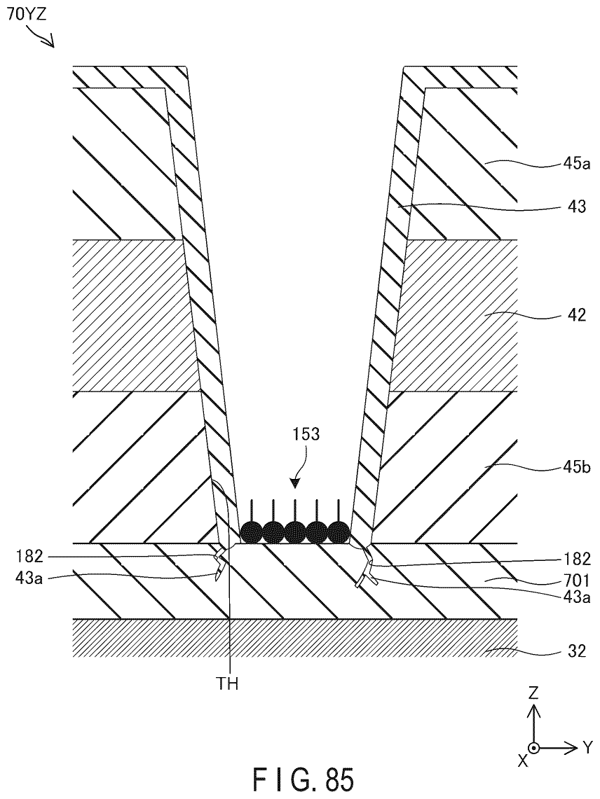

Next, as shown in FIG. 85, gate insulating film forming processing similar to that shown in FIG. 53 is performed.

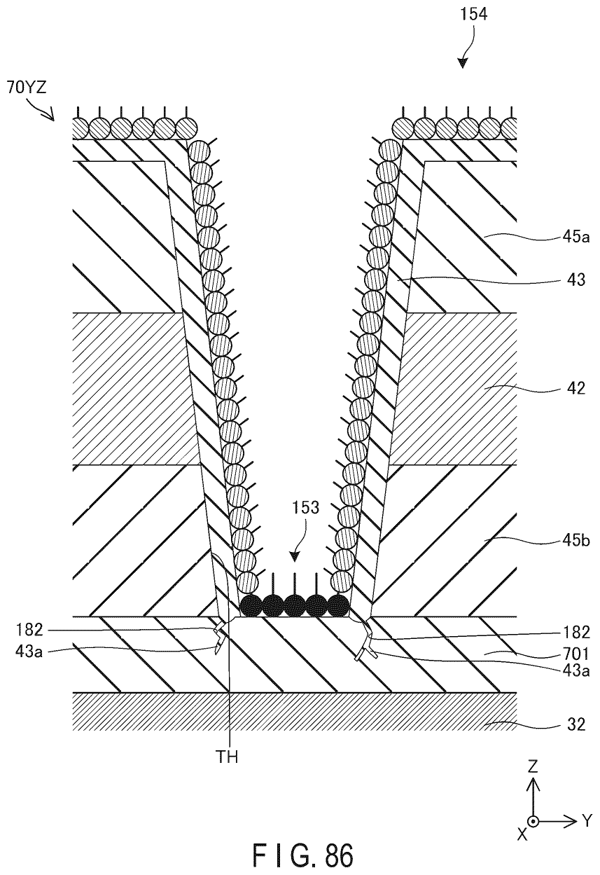

Next, as shown in FIG. 86, SAM processing is performed on silicon oxide. In this example, the SAM 154 is selectively adsorbed onto the surface of the gate insulating film 43 that is exposed above the gate insulating film 43 and inside the transistor hole TH. The SAM 154 is not adsorbed onto the bottom portion of the transistor hole TH where the SAM 153 has been adsorbed.

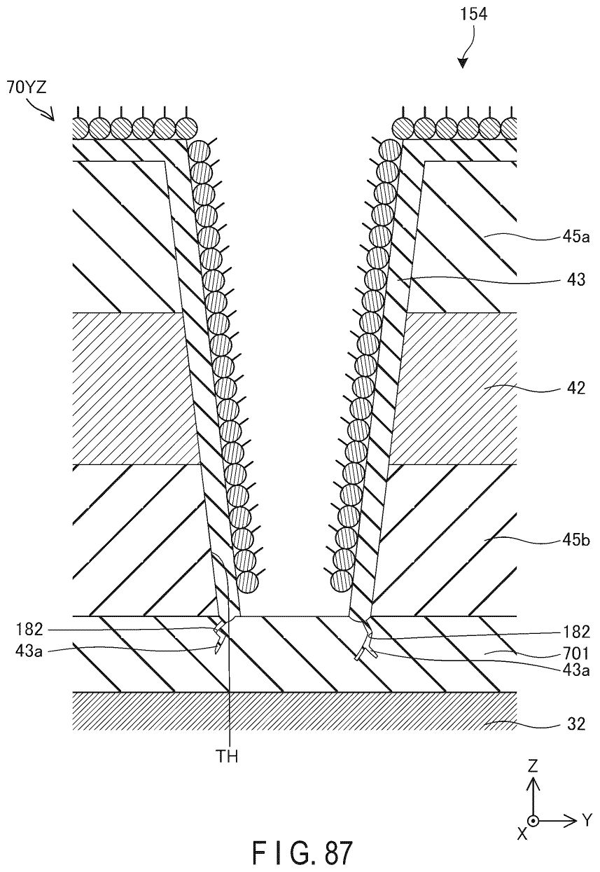

Next, as shown in FIG. 87, second selective SAM removal processing is performed. In this example, the SAM 153 which has been adsorbed onto the stopper film 701 at the bottom portion of the transistor hole TH is removed. On the other hand, the SAM 153 which has been adsorbed onto the gate insulating film 43 remains. Details of the second selective SAM removal processing will be described later.

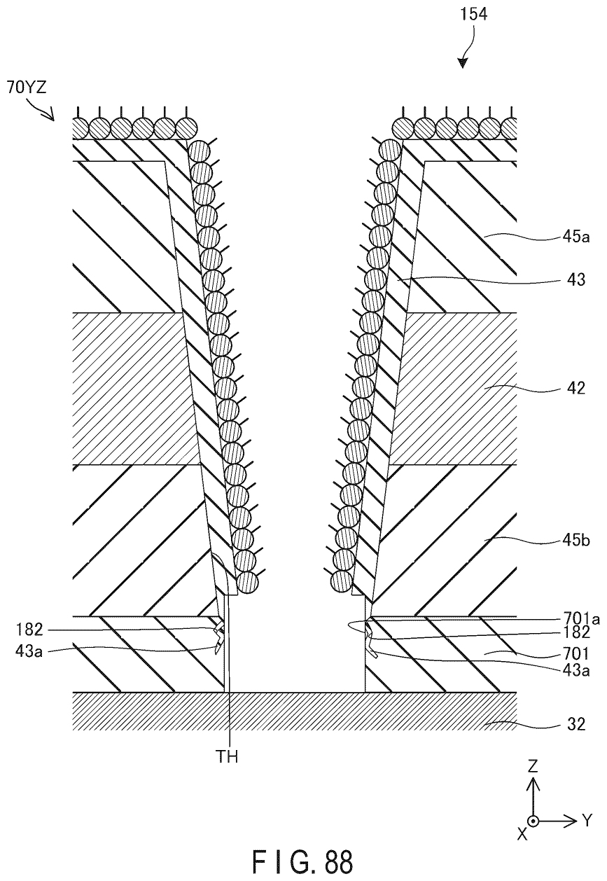

Next, as shown in FIG. 88, bottom punching processing is performed. In this example, a part of the gate insulating film 43 onto which the SAM 154 hat not been selectively adsorbed and a part of the stopper film 701 exposed at the bottom portion of the transistor hole TH are removed by wet etching using the BHF solution or the DHF solution. As a result, a hole portion 701a penetrating through the stopper film 701 in the up-down direction is formed in the stopper film 701. The upper surface of the lower electrode 32 is exposed through the hole portion 701a.

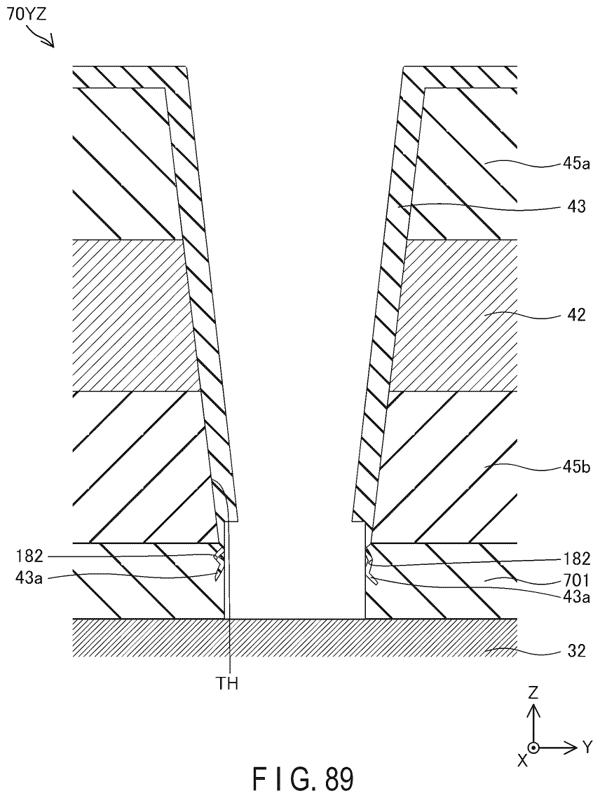

Next, as shown in FIG. 89, SAM removal processing similar to the processing shown in FIG. 54 is performed.

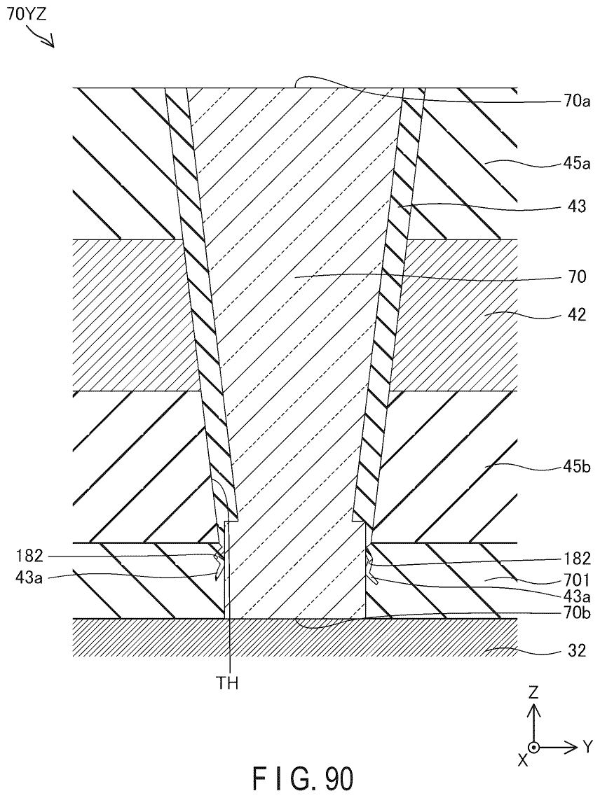

Next, as shown in FIG. 90, oxide semiconductor layer forming processing similar to the processing shown in FIG. 55 is performed.

Details of the first selective SAM removal processing shown in FIG. 83 will be described below.

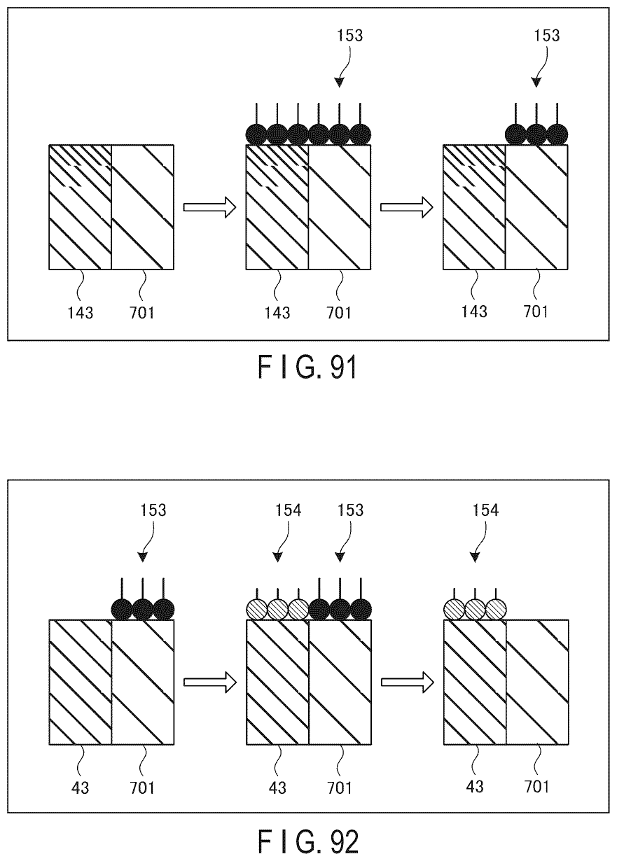

FIG. 91 is a diagram showing an example of the process for selectively removing the SAM 153 which has been adsorbed on the sacrificial gate insulating film 143 when the SAM 153 has been adsorbed on the sacrificial gate insulating film 143 and the stopper film 701.

As shown in FIG. 91, first, the sacrificial gate insulating film 143 and the stopper film 701 are exposed. As described above, the sacrificial gate insulating film 143 and the stopper film 701 contain silicon oxide.

On the other hand, the sacrificial gate insulating film 143 and the stopper film 701 is different from each other in film quality. In detail, the sacrificial gate insulating film 143 is formed by ALD. The sacrificial gate insulating film 143 may contain organic matter derived from a source gas used in ALD.

The stopper film 701 is a thermal oxide film formed by heating silicon in an oxygen atmosphere. In the stopper film 701, oxygen atoms and silicon atoms are strongly chemically bonded to each other. For this reason, the SAM 153 is more likely to detach from the sacrificial gate insulating film 143 than from the stopper film 701.

Next, the SAM 153 is supplied. The SAM 153 is adsorbed onto each of the surfaces of the sacrificial gate insulating film 143 and the stopper film 701. As described above, the adsorption force of the SAM 153 to the sacrificial gate insulating film 143 is weaker than the adsorption force of the SAM 153 to the stopper film 701.

Next, the SAM 153 adsorbed onto the sacrificial gate insulating film 143 is removed by a heat treatment or a chemical treatment because its adsorption force is weak. On the other hand, the SAM 153 adsorbed onto the stopper film 701 remains because its adsorption force is strong.

The details of the second selective SAM removal processing shown in FIG. 87 will be described in detail below.

FIG. 92 is a diagram showing an example of the process for causing SAM 154 to be selectively adsorbed onto the gate insulating film 43 when the gate insulating film 43 and the stopper film 701 are exposed.

As shown in FIG. 92, first, when the SAM 153 is adsorbed onto the stopper film 701, SAM 154 is supplied to the gate insulating film 43 and the stopper film 701. The SAM 154 may be liquid or gas.

The SAM 154 is, for example, an organic-silane-based compound or an alcohol-based compound similar to the SAM 153. The SAM 153 and the SAM 154 differ from each other in at least one of the functional group and the alkyl group that bind to a film to be adsorbed. In detail, the alkyl group differs between the SAM 153 and the SAM 154 in at least one of the number of carbon atoms, the number of strands, and the branched structure.

Since the surface of the gate insulating film 43 is not exposed, the SAM 154 is selectively adsorbed onto the stopper film 701. For example, the adsorption force of the SAM 153 to the stopper film 701 is weaker than the adsorption force of the SAM 154 to the gate insulating film 43.

This can be implemented by adjusting at least one of the alkyl group and the functional group of the SAM 154.

Next, the SAM 153 adsorbed onto the stopper film 701 is removed by a heat treatment or a chemical treatment because its adsorption force is weak. On the other hand, the SAM 154 adsorbed onto the gate insulating film 43 remains because its adsorption force is strong.

### (Section of Semiconductor Device 30)

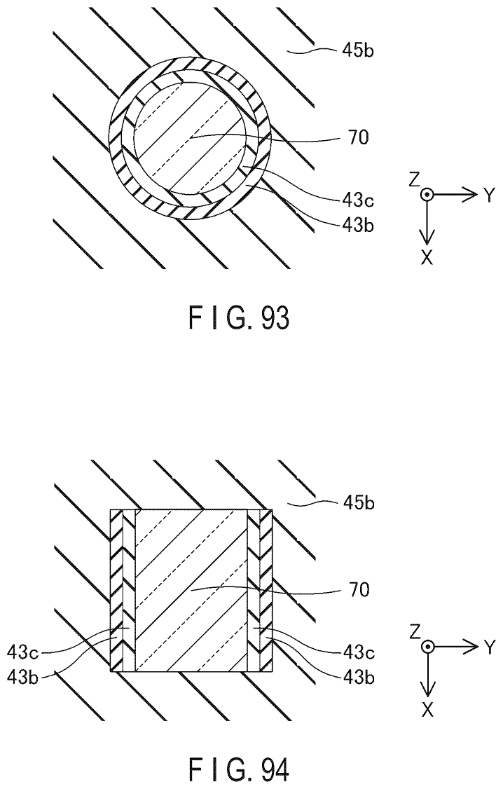

FIG. 93 is a sectional view taken along a line XCIII-XCIII shown in FIG. 75. As shown in FIG. 93, the section of the oxide semiconductor layer 70 has a substantially circular shape. The gate insulating film 43c surrounds the oxide semiconductor layer 70. The gate insulating film 43b surrounds the gate insulating film 43c. The sections of the gate insulating films 43b and 43c have an annular shape.

The section of the oxide semiconductor layer 70 may be elliptical or rectangular. Furthermore, the gate insulating film 43 may be provided instead of the gate insulating films 43b and 43c. Moreover, the section shown in FIG. 75 is not limited to the section of the semiconductor device 30 according to the third example of the second embodiment shown in FIG. 75, but may be the sections of the semiconductor device 30 according to other embodiments.

FIG. 94 is a diagram showing a modification of the section shown in FIG. 93. As shown in FIG. 94, the section of the oxide semiconductor layer 70 has a substantially rectangular shape (see, for example, U.S. Pat. No. 10,347,637).

The gate insulating film 43c is provided in the Y-axis + direction and the Y-axis-direction of the oxide semiconductor layer 70, but is not provided in the X-axis + direction and the X-axis − direction of the oxide semiconductor layer 70. In other words, the gate insulating film 43c does not surround the oxide semiconductor layer 70, but sandwiches the oxide semiconductor layer 70.

The gate insulating film 43b is provided such that the gate insulating film 43c is located between the gate insulating film 43b and the oxide semiconductor layer 70. In detail, in the Y-axis + direction of the oxide semiconductor layer 70, the gate insulating films 43c and 43b are provided in this order toward the Y-axis + direction. In the Y-axis − direction of the oxide semiconductor layer 70, the gate insulating films 43c and 43b are provided in this order toward the Y-axis − direction.

The surfaces in the X-axis + direction and the X-axis − direction of the oxide semiconductor layer 70 are not in contact with either the gate insulating film 43c or 43b, but are in contact with the insulating film 45b.

In the conductive layer 42, the gate insulating films 43b and 43c may surround the oxide semiconductor layer 70.

The present embodiments have been described above with reference to specific examples. However, the present disclosure is not limited to these specific examples. Any design modifications made as appropriate by a person skilled in the art to these specific examples are also included within the scope of the present disclosure as long as they have the features of the present disclosure. The elements of each of the above-mentioned specific examples and their arrangements, conditions, shapes, etc., are not limited to those exemplified and can be changed as appropriate. The combination of the elements of each of the above-mentioned specific examples can be changed as appropriate as long as no technical contradictions arise.

What is claimed is:

1. A semiconductor device comprising:
an upper electrode;
a lower electrode;
an oxide semiconductor including a first portion connected to and in contact with the upper electrode, a connection portion, and a second portion that is connected to a lower end portion of the first portion through the connection portion, has a diameter larger than a diameter of the lower end portion of the first portion, and is connected to and in contact with the lower electrode;
a gate insulating film surrounding a side surface of the first portion;
a first insulating layer through which the first portion penetrates;
a gate electrode that is provided below the first insulating layer and faces the first portion via the gate insulating film, the first portion penetrating through the gate electrode; and
a second insulating layer that is provided below the gate electrode, wherein the connection portion is surrounded by the second insulating layer.

2. The semiconductor device of claim 1, wherein
the oxide semiconductor includes a plurality of extensions extending downwardly from an upper end portion of the lower electrode.

3. The semiconductor device of claim 2, wherein
the extensions penetrate through the lower electrode.

4. The semiconductor device of claim 1, wherein
a lower end portion of the gate insulating film has an outer diameter that is equal to or less than a diameter of the second portion.

5. The semiconductor device of claim 1, further comprising
a first insulating film provided below the second insulating layer, wherein
the second portion penetrates through the first insulating film and reaches the lower electrode to be in contact therewith.

6. A semiconductor device comprising:
an upper electrode;
an oxide semiconductor that has an upper end connected to and in contact with the upper electrode and a lower end, and extends in an up-down direction;
a gate insulating film provided on a side surface of the oxide semiconductor;
a gate electrode facing the side surface of the oxide semiconductor via the gate insulating film; and
a first layer that is provided below the gate electrode and connected to the gate insulating film, wherein
the gate insulating film includes an extended insulating portion extending downwardly into the first layer.

7. The semiconductor device of claim 6, wherein
the first layer is a lower electrode connected to and in contact with the lower end of the oxide semiconductor.

8. The semiconductor device of claim 6, further comprising
a lower electrode connected to and in contact with the lower end of the oxide semiconductor, wherein
the first layer is an insulating layer that is provided above the lower electrode and through which the oxide semiconductor penetrates.

9. A semiconductor storage device comprising:
the semiconductor device of claim 1; and
a capacitor that is electrically connected to the upper electrode through the oxide semiconductor, wherein
the capacitor includes a first capacitor electrode, a second capacitor electrode, and a dielectric film provided between the first capacitor electrode and the second capacitor electrode.

10. A method for manufacturing a semiconductor device comprising:
forming a hole portion that penetrates through a first insulating layer, a gate electrode provided below the first insulating layer, and a second insulating layer provided below the gate electrode to expose a first layer provided below the second insulating layer;
forming a gate insulating film covering the hole portion;
forming a protection film covering the gate insulating film;
removing a part of the protection film covering the first layer;
removing a part of the gate insulating film covering the first layer;
removing the protection film; and
forming a semiconductor inside the hole portion.

11. The method for manufacturing a semiconductor device of claim 10, wherein
the removing the part of the protection film covering the first layer is performed by etching using gas ion collisions.

12. The method for manufacturing a semiconductor device of claim 10, wherein the removing the part of the gate insulating film covering the first layer is performed by wet etching.

13. The method for manufacturing a semiconductor device of claim 10, wherein the removing the protection film is removed by wet etching.

14. A method for manufacturing a semiconductor device, comprising:
forming a hole portion that penetrates through a first insulating layer, a gate electrode provided below the first insulating layer, and a second insulating layer provided below the gate electrode to expose a first layer provided below the second insulating layer;
forming a sacrificial film covering the hole portion;
removing a part of the sacrificial film covering the first layer to expose an upper surface of the first layer;
forming a monolayer on the exposed upper surface of the first layer, the monolayer not covering a surface of an inner surface of the hole portion;
removing the sacrificial film;
forming a gate insulating film on the surface of the inner surface of the hole portion;
removing the monolayer; and
forming a semiconductor inside the hole portion.

15. The method for manufacturing a semiconductor device of claim 14, wherein
when the first layer contains metal or metal oxide, the monolayer contains a phosphonic-acid-based compound, a phosphate-based compound, an amine-based compound, or an organic-silane-based compound.

16. The method for manufacturing a semiconductor device of claim 14, wherein
when the first layer contains silicon and nitrogen, the monolayer contains an alkyl-bromide-based compound or an unsaturated-hydrocarbon-based compound.

17. The method for manufacturing a semiconductor device of claim 14, wherein
when the first layer contains silicon and oxygen, the monolayer contains an organic-silane-based compound.

18. The method for manufacturing a semiconductor device of claim 14, wherein
the removing the monolayer is performed without etching by using gas ion collisions.

19. A method for manufacturing a semiconductor device, comprising:
forming a hole portion that penetrates through a first insulating layer, a gate electrode provided below the first insulating layer, and a second insulating layer provided below the gate electrode to expose a first layer provided below the second insulating layer;
forming a gate insulating film covering the hole portion;
forming a sacrificial film covering the gate insulating film below the hole portion;
forming a monolayer covering a part of the gate insulating film that is left uncovered by the sacrificial film in the hole portion;
removing the sacrificial film to expose a part of the gate insulating film that has been covered by the sacrificial film;
removing a part of the gate insulating film covering the first layer in the hole portion to expose the first layer;
removing the monolayer; and
forming a semiconductor inside the hole portion.

20. The method for manufacturing a semiconductor device of claim 19, wherein the semiconductor is an oxide semiconductor.

21. The method for manufacturing a semiconductor device of claim 19, wherein:
the first layer is a lower electrode or a first insulating film provided below the second insulating layer.
